(19) United States
(12) Patent Application Publication
(10) Pub. No.: US 2019/0140129 A1
(43) Pub. Date: May 9, 2019

(54) DETECTOR FOR AN OPTICAL DETECTION OF AT LEAST ONE OBJECT

(71) Applicant: trinamiX GmbH, Ludwighsafen am Rhein (DE)

(72) Inventors: Sebastian VALOUCH, Ludwigshafen (DE); Christoph LUNGENSCHMIED, Ludwigshafen (DE); Wilfried HERMES, Ludwigshafen (DE); Robert SEND, Ludwigshafen (DE); Ingmar BRUDER, Ludwigshafen (DE)

(73) Assignee: trinamiX GmbH, Ludwighsafen am Rhein (DE)

(21) Appl. No.: 16/090,990

(22) PCT Filed: Apr. 3, 2017
(86) PCT No.: PCT/EP2017/057825

§ 371 Date: Oct. 3, 2018

(30) Foreign Application Priority Data
Apr. 6, 2016 (EP) 16164113.9

(51) Int. Cl. H01L 31/101; G01S 7/481; H01L 27/30; H01L 31/0368; H01L 31/0376; H01L 51/42; H01L 27/146

(52) U.S. Cl. CPC H01L 31/1013; G01S 7/4816; H01L 27/307; H01L 27/14669; H01L 31/03765; H01L 31/1016; H01L 51/4293; H01L 31/03685

(57) ABSTRACT

A simple and still reliable detector for an accurate determination of a position of at least one object in space is provided. The detector comprises a longitudinal optical sensor (114) having a stack of at least two individual pin diodes (130, 130′) arranged between at least two electrodes (132, 132′). Upon illumination of the sensor region by an incident light beam (136), a longitudinal sensor signal is generated. The longitudinal sensor signal, given the same power of illumination, is dependent on a beam cross-section of the light beam (136). The at last two individual pin diodes (130, 130′) have different spectral sensitivities in order to enable the determination of a distance between the object and the detector by light beams in different spectral ranges, e.g. by light beams in the visible spectral range and in the infrared spectral range.

### FIELD OF THE INVENTION

The invention relates to a detector for an optical detection of at least one object, in particular, for determining a position of at least one object, specifically with regard to a depth or both to the depth and a width of the at least one object. Furthermore, the invention relates to a human-machine interface, an entertainment device, a scanning system, a tracking system, a stereoscopic system; and a camera. Further, the invention relates to a method for optical detection of at least one object and to various uses of the detector. Such devices, methods and uses can be employed for example in various areas of daily life, gaming, traffic technology, mapping of spaces, production technology, security technology, medical technology or in the sciences. However, further applications are possible.

### PRIOR ART

Various detectors for optically detecting at least one object are known on the basis of optical sensors. WO 2012/110924 A1 discloses a detector comprising at least one optical sensor, wherein the optical sensor exhibits at least one sensor region. Herein, the optical sensor is designed to generate at least one sensor signal in a manner dependent on an illumination of the sensor region. According to the so-called “FiP effect”, the sensor signal, given the same total power of the illumination, is hereby dependent on a geometry of the illumination, in particular on a beam cross-section of the illumination on the sensor region. The detector furthermore has at least one evaluation device designated to generate at least one item of geometrical information from the sensor signal, in particular at least one item of geometrical information about the illumination and/or the object.

WO 2014/097181 A1 discloses a method and a detector for determining a position of at least one object, by using at least one transversal optical sensor and at least one longitudinal optical sensor. Preferably, a stack of longitudinal optical sensors is employed, in particular to determine a longitudinal position of the object with a high degree of accuracy and without ambiguity. Further, WO 2014/097181 A1 discloses a human-machine interface, an entertainment device, a tracking system, and a camera, each comprising at least one such detector for determining a position of at least one object.

Further, WO 2016/120392 A1 and PCT patent application No. PCT/EP2016/051817, filed Jan. 28, 2016, discloses an optical sensor comprising a photoconductive material, which may be an inorganic photoconductive material, preferably selected from the group consisting of selenium, a metal oxide, a group IV element or compound, a III-V compound, a II-VI compound, and a chalcogenide, or an organic photoconductive material. Further, a pin diode which comprises a layer of a semiconducting material selected from amorphous silicon (a-Si), hydrogenated amorphous silicon (a-Si:H), hydrogenated microcrystalline silicon (μc-Si:H), hydrogenated amorphous silicon carbon alloy (a-SiC:H), or hydrogenated amorphous germanium silicon alloy (a-GeSi:H) is disclosed. Herein, the pin diode could be employed as optical sensor for an incident beam having a wavelength within one or more of the ultra-violet, visual, or infrared spectral ranges.

W. Hermes, D. Waldmann, M. Agari, K. Schierle-Arndt, and P. Erk, Emerging Thin-Film Photovoltaic Technologies, Chem. Ing. Tech. 2015, 87, No. 4, 376-389, provide an overview over thin-film photovoltaic technologies. Herein, an organics-based solar cell, in particular in a dye-sensitized solar cell (DSSC), a kesterite solar cell which, in particular, may comprise a thin film of copper zinc tin sulfide (CZTS), and a hybrid solar cell based on organic-inorganic halide perovskite absorbers, especially on methylammonium lead iodide (CH₃NH₃PbI₃), are presented as promising candidates for high solar efficiency.

W. Fuhs, Hydrogenated Amorphous Silicon—Material Properties and Device Applications, in S. Baranovski, Charge Transport in Disordered Solids, Wiley, p. 97-147, 2006, provides an overview about the preparation and structural properties of amorphous silicon (a-Si), hydrogenated amorphous silicon (a-Si:H), and hydrogenated microcrystalline silicon (μc-Si:H). Further, devices comprising amorphous silicon, in particular Schottky barrier diodes, pin diodes, and thin-film solar cells, are presented. As a particular example, a tandem solar cell comprising a stack of two pin diodes is disclosed, wherein photovoltaic materials with different bandgaps are employed in order to increase the total absorption of the solar spectrum. As a further example, a triple junction cell comprising a stack of three pin diodes is disclosed there, wherein a single pin diode comprises an intrinsic a-Si alloy while the two other pin diodes comprise an intrinsic a-SiGe alloy.

Further, WO 2011/091967 A2 discloses a photovoltaic multi-junction thin-film solar cell comprising a carrier substrate, at least one upper sub-cell and at least one lower sub-cell, wherein each of the sub-cells is arranged as a pin structure comprising a p-conducting layer, an n-conducting layer and an intrinsic layer located between the p-conducting layer and the n-conducting layer. The upper sub-cell being adapted for light incidence, in which the intrinsic layer comprises hydrogenated amorphous silicon, is located on the carrier substrate and/or on one or more further layers, whereas the lower sub-cell is located below the upper sub-cell optionally on one or more further intermediate layers. In each sub-cell, the p-conducting layer is located facing towards the incident light. Further, the intrinsic layer in the lower sub-cell requires comprising microcrystalline germanium.

Despite the advantages implied by the above-mentioned devices and detectors, there still is a need for improvements with respect to a simple, cost-efficient and, still, reliable spatial detector.

### Problem Adressed by the Invention

Therefore, a problem addressed by the present invention is that of specifying a device and a method for optically detecting at least one object which at least substantially avoid the disadvantages of known devices and methods of this type. In particular, an improved simple, cost-efficient and, still, reliable spatial detector for determining the position of an object in space not only by using light beams in the visible spectral range but also in the infrared spectral range, in particular in the near-infrared spectral range, would be desirable.

### SUMMARY OF THE INVENTION

This problem is solved by the invention with the features of the independent patent claims. Advantageous developments of the invention, which can be realized individually or in combination, are presented in the dependent claims and/or in the following specification and detailed embodiments.

As used herein, the expressions “have”, “comprise” and “contain” as well as grammatical variations thereof are used in a non-exclusive way. Thus, the expression “A has B” as well as the expression “A comprises B” or “A contains B” may both refer to the fact that, besides B, A contains one or more further components and/or constituents, and to the case in which, besides B, no other components, constituents or elements are present in A.

In a first aspect of the present invention, a detector for optical detection, in particular, for determining a position of at least one object, specifically with regard to a depth or to both the depth and a width of the at least one object is disclosed.

The “object” generally may be an arbitrary object, chosen from a living object and a non-living object. Thus, as an example, the at least one object may comprise one or more articles and/or one or more parts of an article. Additionally or alternatively, the object may be or may comprise one or more living beings and/or one or more parts thereof, such as one or more body parts of a human being, e.g. a user, and/or an animal.

As used herein, a “position” generally refers to an arbitrary item of information on a location and/or orientation of the object in space. For this purpose, as an example, one or more coordinate systems may be used, and the position of the object may be determined by using one, two, three or more coordinates. As an example, one or more Cartesian coordinate systems and/or other types of coordinate systems may be used. In one example, the coordinate system may be a coordinate system of the detector in which the detector has a predetermined position and/or orientation. As will be outlined in further detail below, the detector may have an optical axis, which may constitute a main direction of view of the detector. The optical axis may form an axis of the coordinate system, such as a z-axis. Further, one or more additional axes may be provided, preferably perpendicular to the z-axis.

Thus, as an example, the detector may constitute a coordinate system in which the optical axis forms the z-axis and in which, additionally, an x-axis and a y-axis may be provided which are perpendicular to the z-axis and which are perpendicular to each other. As an example, the detector and/or a part of the detector may rest at a specific point in this coordinate system, such as at the origin of this coordinate system. In this coordinate system, a direction parallel or antiparallel to the z-axis may be regarded as a longitudinal direction, and a coordinate along the z-axis may be considered a longitudinal coordinate. An arbitrary direction perpendicular to the longitudinal direction may be considered a transversal direction, and an x- and/or y-coordinate may be considered a transversal coordinate.

Alternatively, other types of coordinate systems may be used. Thus, as an example, a polar coordinate system may be used in which the optical axis forms a z-axis and in which a distance from the z-axis and a polar angle may be used as additional coordinates. Again, a direction parallel or antiparallel to the z-axis may be considered a longitudinal direction, and a coordinate along the z-axis may be considered a longitudinal coordinate. Any direction perpendicular to the z-axis may be considered a transversal direction, and the polar coordinate and/or the polar angle may be considered a transversal coordinate.

As used herein, the detector for optical detection generally is a device which is adapted for providing at least one item of information on the position of the at least one object. The detector may be a stationary device or a mobile device. Further, the detector may be a stand-alone device or may form part of another device, such as a computer, a vehicle or any other device. Further, the detector may be a hand-held device. Other embodiments of the detector are feasible.

The detector may be adapted to provide the at least one item of information on the position of the at least one object in any feasible way. Thus, the information may e.g. be provided electronically, visually, acoustically or in any arbitrary combination thereof. The information may further be stored in a data storage of the detector or a separate device and/or may be provided via at least one interface, such as a wireless interface and/or a wire-bound interface.

The detector for an optical detection of at least one object according to the present invention comprises:
at least one longitudinal optical sensor, the longitudinal optical sensor having at least two individual pin diodes arranged between at least two electrodes, wherein at least one of the pin diodes is designated as a sensor region for an incident light beam, wherein the sensor region is designated to generate at least one longitudinal sensor signal in a manner dependent on an illumination of the sensor region by the light beam, wherein the longitudinal sensor signal, given the same total power of the illumination, is dependent on a beam cross-section of the light beam in the sensor region, and
at least one evaluation device, wherein the evaluation device is designated to generate at least one item of information on a longitudinal position of the object by evaluating the longitudinal sensor signal.

Herein, the components listed above may be separate components. Alternatively, two or more of the components as listed above may be integrated into one component. Further, the at least one evaluation device may be formed as a separate evaluation device independent from the transfer device and the longitudinal optical sensors, but may preferably be connected to the longitudinal optical sensors in order to receive the longitudinal sensor signal. Alternatively, the at least one evaluation device may fully or partially be integrated into the longitudinal optical sensors.

As used herein, the “longitudinal optical sensor” is generally a device which is designed to generate at least one longitudinal sensor signal in a manner dependent on an illumination of the sensor region by the light beam, wherein the longitudinal sensor signal, given the same total power of the illumination, is dependent, according to the so-called “FiP effect” on a beam cross-section of the light beam in the sensor region. The longitudinal sensor signal may generally be an arbitrary signal indicative of the longitudinal position, which may also be denoted as a depth. As an example, the longitudinal sensor signal may be or may comprise a digital and/or an analog signal. As an example, the longitudinal sensor signal may be or may comprise a voltage signal and/or a current signal. Additionally or alternatively, the longitudinal sensor signal may be or may comprise digital data. The longitudinal sensor signal may comprise a single signal value and/or a series of signal values. The longitudinal sensor signal may further comprise an arbitrary signal which is derived by combining two or more individual signals, such as by averaging two or more signals and/or by forming a quotient of two or more signals. For potential embodiments of the longitudinal optical sensor and the longitudinal sensor signal, reference may be made to the optical sensor as disclosed in WO 2012/110924 A1.

According to the present invention, the at least one longitudinal optical sensor comprises at least two individual pin diodes which are arranged between at least two electrodes. Herein, the at least two individual pin diodes may commonly share the electrodes of the same polarity. As a result, no additional electrodes may be arranged between the individual pin diodes. In particular for a purpose of facilitating the light beam which may impinge the longitudinal optical sensor to arrive at at least one of the pin diodes, at least one of the electrodes, in particular the first electrode which may be located within the path of the incident light beam, may be selected to be at least partially optically transparent. Herein, the at least partially optically transparent electrode may comprise at least one transparent conductive oxide (TOO), in particular at least one of indium-doped tin oxide (ITO), fluorine-doped tin oxide (FTO), aluminum-doped zinc oxide (AZO), or a perovskite TCO, such as SrVO₃, or CaVO₃, or, alternatively, metal nanowires, in particular Ag or Cu nanowires. However, other kinds of optically transparent, semi-transparent or translucent materials which may be suited as electrode material may also be applicable. As a result, the second electrode, also denominated as “back electrode”, may also be optically intransparent, in particularly as long as they are located outside the path of the light beam within the longitudinal optical sensor. Herein, the at least one optically intransparent electrode may, preferably, comprise a metal electrode, in particular one or more of a silver (Ag) electrode, a platinum (Pt) electrode, an aluminum (Al) electrode, or a gold (Au) electrode, or, alternatively, a graphene electrode. Preferably, the optically intransparent electrode may comprise a uniform metal layer. Alternatively, the optically intransparent electrode may be a split electrode being arranged as a number of partial electrodes or in form of a metallic grid.

In particular, the longitudinal optical sensor may exhibit an arrangement in a stack-like fashion. For this purpose, each of the electrodes and each of the pin diodes may, preferably, exhibit a layered structure, thus, allowing the pin diodes being arranged one above the other being sandwiched between the two electrode layers. As a result, a stack of layers may be obtained, wherein the stack may have a first electrode, on which a first pin diode may be placed, on which a second pin diode may be placed, on which a second electrode may be placed. If applicable, at least one further pin diode may be placed on any location between the first electrode and the second electrode. Further, the stack may comprise additional layers, in particular, at least one insulating substrate and/or at least one recombination layer, as will be described below in more detail. Hereby, the first electrode layer could, for example, be placed on a first substrate. As used herein, the term “be placed on” does, however, not refer to a specific geometric orientation of the final stack in the pin diode with respect to a direction of a gravitational force but rather indicates a way of manufacturing the stack, which, after manufacturing, could, in general, be placed in any geometric orientation, also such as turned upside down.

According to the present invention, at least one of the pin diodes is designed as a sensor region for an incident light beam. Consequently, all pin diodes as comprised within the stack-like arrangement of the longitudinal optical sensor might be employed as the sensor region. However, the present invention may exhibit a particular advantage that the pin diodes, in particular the two pin diodes as present in the longitudinal optical sensor, may exhibit different optical properties with respect to each other. As will be described below in more detail, the individual pin diodes could exhibit different optical sensitivities, in particular different external quantum efficiencies, with respect to different wavelength ranges of the incident light beam. Further, the individual pin diodes could exhibit different types of the FiP effect, i.e. different longitudinal sensor signals depending on the illumination of the sensor region by the incident light beam, whereby each pin diode may show the positive FiP effect, the negative FiP, or no FiP effect at all as long as at least one of the pin diodes actually exhibits the FiP effect, irrespective whether it may be the positive FiP effect or the negative FiP effect. Alternatively or in addition, other kinds of differences between the at least two pin diodes in the longitudinal optical sensor may also be feasible.

For the purpose of the present invention, the sensor region of the longitudinal optical sensor is illuminated by at the least one light beam. Given the same total power of the illumination, an electrically detectable property of the sensor region, therefore, depends on a beam cross-section of the light beam in the sensor region, which may also be denominated as a “spot size” generated by the incident light beam within the sensor region. Thus, the electrically detectable property which depends on an extent of the illumination of the sensor region by an incident light beam particularly accomplishes that two light beams comprising the same total power but generating different spot sizes on the sensor region provide different values for the electrically detectable property in the sensor region and are, consequently, distinguishable with respect to each other.

Further, since the longitudinal sensor signal may, preferably, be determined by applying an electrical signal, such as a voltage signal and/or a current signal, the electrically detectable property of a material as comprised in the sensor region which is traversed by the electrical signal is, therefore, taken into account when determining the longitudinal sensor signal. As a result, the longitudinal optical sensor comprising the sensor region, thus, principally allows determining the beam cross-section of the light beam in the sensor region from a recording of the longitudinal sensor signal, such as by comparing at least two longitudinal sensor signals, at least one item of information on the beam cross-section, specifically on the beam diameter. For this purpose, an electrical current may be guided via at least one first electrode through the material to at least one second electrode, wherein the first electrode is isolated from the second electrode while both the first electrode and the second electrode are in direct connection with the material at respective contact zones. Alternatively, a voltage may be applied across the material by using the first electrical contact and the second electrical contact. Thus, a direct connection may be provided by any known measure known from the state of the art, such as plating, welding, soldering, or depositing electrically highly conductive substances at the contact zones.

Further, since the beam cross-section of the light beam in the sensor region, according to the above-mentioned FiP effect, given the same total power of the illumination, depends on the longitudinal position or depth of an object which emits or reflects the light beam that impinges on the sensor region, the longitudinal optical sensor may, therefore, be applied to determining a longitudinal position of the respective object.

As already known from WO 2012/110924 A1, the longitudinal optical sensor is designed to generate at least one longitudinal sensor signal in a manner dependent on an illumination of the sensor region, wherein the sensor signal, given the same total power of the illumination depends on a beam cross-section of the illumination on the sensor region. As an example, a measurement of a photocurrent I as a function of a position of a lens is provided there, wherein the lens is configured for focusing electromagnetic radiation onto the sensor region of the longitudinal optical sensor. During the measurement, the lens is displaced relative to the longitudinal optical sensor in a direction perpendicular to the sensor region in a manner that, as a result, the diameter of the light spot on the sensor region changes. In the present case in which at least one pin diode is designed as the sensor region, the signal of the longitudinal optical sensor, in particular a photocurrent, clearly depends on the geometry of the illumination such that, outside a maximum at the focus of the lens, the photocurrent falls to less than 10% of its maximum value.

This effect is particularly striking with respect to similar measurements performed by using optical sensors of a conventional type in which the sensor signal, given the same total power, is substantially independent of a geometry of the illumination of the sensor region. Thus, according to the FiP effect, the longitudinal sensor signal, given the same total power, may exhibit at least one pronounced maximum for one or a plurality of focusings and/or for one or a plurality of specific sizes of the light spot on the sensor region or within the sensor region. For purposes of comparison, an observation of a maximum of the longitudinal sensor signal in a condition in which the corresponding material is impinged by a light beam with the smallest possible cross-section, such as when the material may be located at or near a focal point as affected by an optical lens, may be denominated as a “positive FiP effect”. Alternatively, a “negative FiP effect” may be observable, which, in correspondence to the definition of the positive FiP effect, describes an observation of a minimum of the longitudinal sensor signal under a condition in which the corresponding material is impinged by a light beam with the smallest available beam cross-section, in particular, when the material may be located at or near a focal point as effected by an optical lens. As will be illustrated below, an appearance of the negative FiP effect may be observed in the longitudinal optical sensor according to the present invention.

As mentioned above, the longitudinal optical sensor has at least two individual pin diodes, preferably two individual pin diodes. As generally used, the terms “pin diode”, “PIN diode”, or “p-i-n diode” refer to an electronic device which comprises an i-type semiconductor layer that is located between an n-type semiconductor layer and a p-type semiconductor layer. Alternatively, the terms “nip diode”, “NIP diode”, or “n-i-p diode” may also be used here. As a further alternative, the term “bulk heterojunction” may also be used, in particular, in case organic materials are involved. As known from the state of the art, while in the n-type semiconducting layer charge carriers are predominantly provided by electrons, in the p-type semiconducting layer the charge carriers are predominantly provided by holes. In particular, in the longitudinal optical sensor according to the present invention, the i-type semiconductor layer may exhibit a thickness which may exceed the thickness of each of the n-type semiconductor layer and the p-type semiconductor layer, in particular by a factor of at least 2, preferably of at least 5, more preferred of at least 10 or more. As an example, the thickness of the i-type semiconducting layer may be from 100 nm to 3000 nm, in particular from 300 nm to 2000 nm, whereas the thickness of both the n-type and the p-type semiconductor layer may be from 5 nm to 100 nm, in particular from 10 nm to 60 nm.

In a preferred embodiment of the present invention, at least one of the pin diodes may comprise undoped intrinsic amorphous silicon, also abbreviated as “a-Si”. As generally used, the term “amorphous silicon” relates to a non-crystalline allotropic form of silicon. As further known from the state of the art, the amorphous silicon can be obtained by depositing it as a layer, especially as a thin film, onto an appropriate substrate. However, other methods may be applicable. Further, the amorphous silicon may, most preferably, be passivated by using hydrogen, by which application a number of dangling bonds within the amorphous silicon may be reduced by several orders of magnitude. As a result, hydrogenated amorphous silicon, usually abbreviated to “a-Si:H”, may exhibit a low amount of defects, thus, allowing using it for optical devices. However, as used herein, the term amorphous silicon may also refer to hydrogenated amorphous silicon, unless explicitly indicated.

Pin diodes comprising amorphous silicon are, generally, known to exhibit a non-linear frequency response. As a result, the positive and/or the negative FiP effect may be observable in the longitudinal sensor which may, moreover, be substantially frequency-independent in a range of a modulation frequency of the light beam of 0 Hz to 50 kHz. Experimental results which demonstrate an occurrence of the mentioned features have been presented in unpublished PCT patent application no. PCT/EP2016/051817, filed Jan. 28, 2016, in more detail. Further, the optical detector comprising the amorphous silicon may exhibits the particular advantages of abundance of the respective semiconducting material, of an easy production route, and of a considerably high signal-to-noise ratio compared to other known FiP devices.

Further, taking into account a behavior of an external quantum efficiency of the pin diode vs. the wavelength of the incident beam may provide insight into a wavelength range of the incident beam for which the pin diode may particularly be suitable. Herein, the term “external quantum efficiency” refers to a fraction of photon flux which may contribute to the photocurrent in the present sensor. As a result, the pin diode which comprises the amorphous silicon may exhibit a particularly high value for the external quantum efficiency within the wavelength range which may extend from 380 nm to 700 nm whereas the external quantum efficiency may be lower for wavelengths outside this range, in particular for wavelengths below 380 nm, i.e. within the UV range, and for wavelengths above 700 nm, in particular within the NIR range, thereby being vanishingly small above 800 nm. Consequently, the pin diode with the amorphous silicon may preferably be employed for the optical detection when the incident beam has a wavelength within a range which covers most of the visual spectral range, especially from 380 nm to 700 nm.

As already mentioned above, the at least two pin diodes which are present in the longitudinal optical sensor, may, however, exhibit different optical properties, preferably different optical sensitivities, in particular different external quantum efficiencies, with respect to each other within different spectral ranges. This embodiment may, particularly, be suitable to increase a wavelength detection range of the present detector.

Alternatively or in addition, other kinds of differences between the at least two pin diodes, such as an occurrence of different types of FiP effects, may also be feasible. Further embodiments may refer to setups of the longitudinal optical sensor, in which at least one of the pin diodes, such as a single pin diode, may comprise a sensor region designed to generate the at least one longitudinal sensor signal which depends on its illumination, at least one of the other pin diodes as comprised by the longitudinal optical sensor may accomplish a different function.

In a particularly preferred embodiment, a first pin diode may comprise amorphous silicon that exhibits, as described above, a high value for the external quantum efficiency within the spectral range from 380 nm to 700 nm, thus covering most of the visual spectrum. Although the external quantum efficiency of the amorphous silicon is known to be considerably lower for wavelengths outside this range, in particular for wavelengths below 380 nm, i.e. within the UV range, and for wavelengths above 700 nm, in particular within the NIR range, the amorphous silicon may still be employed in the first pin diode for incident lights beams that may exhibit at least one wavelength outside the spectral range from 380 nm to 700 nm. In this particularly preferred event, the first pin diode may, however, not be used as a sensor region in the manner as described above but it may, nevertheless, accomplish a different function within the longitudinal optical sensor, in particular, working as a trap holding semiconductor. Thus, the first pin diode may allow receiving positive charge carriers that may be generated in the at least one second pin diode which exhibit sufficient external quantum efficiency within the desired wavelength range.

Consequently, the second PIN diode that may be employed in the detector according to the present invention may exhibit sufficient external quantum efficiency within at least a partition of the NIR spectral range and may, thus, be capable of acting like an NIR absorber. As used herein, the term “NIR spectral range”, which may also abbreviated to “IR-A”, may cover a partition of the electromagnetic spectrum from 760 nm to 1400 nm as recommended by the ISO standard ISO-21348 in a valid version at the date of this application. For this purpose, the second pin diode may exhibit the same or a similar arrangement as the pin diode comprising the amorphous silicon as described above and/or below, wherein the amorphous silicon (a-Si) or the hydrogenated amorphous silicon (a-Si:H), respectively, may at least partially be replaced by one of: a microcrystalline silicon (μc-Si), preferably a hydrogenated microcrystalline silicon (μc-Si:H), or an amorphous alloy of germanium and silicon (a-GeSi), preferably a hydrogenated amorphous germanium silicon alloy (a-GeSi:H). The second pin diode may, thus, exhibit a high external quantum efficiency over a wavelength range which may at least partially cover the NIR wavelength range from 760 nm to 1400 nm, in particular at least from 760 nm to 1000 nm. By way of example, the pin diode comprising pc-Si has a non-negligible quantum efficiency over a wavelength range which approximately extends from 500 nm to 1100 nm.

As generally known, semiconductor materials with a three-dimensional crystal structure and an optical gap close to or below the spectral region of application are likely to be of interest if trap levels may be introduced either by doping with a further material or by obtaining a nanocrystalline, a microcrystalline, or an amorphous structure. Doping may, particularly, be achieved subject to a different position and/or concentration of traps and/or recombination centers by adding metal atoms or salts to the semiconductor in a manner that the band structure of the semiconductor, preferably the conduction band, may be augmented by energy levels of the doping material, preferably with energy levels which are energetically above or below the conduction band.

The hydrogenated microcrystalline silicon (μc-Si:H) may, preferably, be produced from a gaseous mixture of SiH₄ and CH₄. As a result, a two-phase material on a substrate comprising microcrystallites having a typical size of 5 nm to 30 nm and being located between ordered columns of the substrate material spaced apart 10 nm to 200 nm with respect to each other may be obtained. However, another production method for providing μc-Si:H may also be applicable which may, however not necessarily, lead to an alternative arrangement of the μc-Si:H. Further, the hydrogenated amorphous germanium silicon alloy (a-GeSi:H) may, preferably, be produced by using SiH₄, GeH₄, and H₂ as process gases within a common reactor. Also here, other production methods for providing a-GeSi:H may be feasible.

Comparing both μc-Si:H and a-GeSi:H to a-Si:H, the semiconductor layers comprising μc-Si:H and a-GeSi:H may have a similar or an increased disorder-induced localization of charge carriers, thus, exhibiting a considerably non-linear frequency response. This may constitute a basis for the occurrence of the FiP effect in the longitudinal sensor being equipped with a pin diode comprising these kinds of semiconductor layers. As a result, this kind of longitudinal sensors may, in particular, be used in applications in which a NIR response may be required, such as in night vision or fog vision, or suitable, such as when an active target emitting at least one wavelength within the NIR spectral range may be used, for example, in a case in which it might be advantageous when animals or human beings may be left undisturbed by using an NIR illumination source.

Alternatively, the second pin diode that may be provided for the detector according to the present invention may exhibit sufficient external quantum efficiency within at least a partition of the UV spectral range. As used herein, the term “UV spectral range” may cover a partition of the electromagnetic spectrum from 1 nm to 400 nm, in particular from 100 nm to 400 nm, and can be subdivided into a number of ranges as recommended by the ISO standard ISO-21348, wherein the second pin diode provided here may particularly be suitable for the Ultraviolet A range, abbreviated to “UVA”, from 400 nm to 315 nm, for the Ultraviolet B range, abbreviated to “UVB” from 315 nm to 280 nm, or for both. For this purpose, the second pin diode may exhibit the same or a similar arrangement as the pin diode comprising the amorphous silicon as described above and/or below, wherein the amorphous silicon (a-Si) or the hydrogenated amorphous silicon (a-Si:H), respectively, may at least partially be replaced by an amorphous alloy of silicon and carbon (a-SiC) or, preferably, by a hydrogenated amorphous silicon carbon alloy (a-SiC:H). The second pin diode may, thus, exhibit a high external quantum efficiency within the UV wavelength range, preferably, over the complete UVA and UVB wavelength range from 280 nm to 400 nm. Herein, the hydrogenated amorphous silicon carbon alloy (a-SiC:H) may, preferably, be produced in a plasma-enhanced deposition process, typically by using SiH₄ and CH₄ as process gases. However, other production methods for providing a-SiC:H may also be applicable.

As known from prior art, a layer comprising the hydrogenated amorphous silicon carbon alloy a-SiC:H may usually exhibit a hole mobility which may significantly be smaller compared to an electron mobility in a layer comprising the hydrogenated amorphous silicon a-Si:H. Thus, the layer comprising a-SiC:H may be employed as a p-doped hole extraction layer, particularly arranged on the side of the stack at which the light beam may enter the device. As a result of this arrangement, a distance over which holes might have to travel in order to be able to contribute to the longitudinal sensor signal can considerably reduced. In addition, this kind of thin layer may, further, allow electrons to traverse the layer and, thus, to enter into the adjacent i-type semiconductor layer of the pin diode. However, other kinds of pin diodes in which at least one of the semiconductor layers may comprise at least partially a-SiC:H may also be feasible.

Further kinds of materials that may be suitable for application in one or more setups of the present invention may be found in PCT patent application No. PCT/EP2016/051817, filed Jan. 28, 2016, the full content of both is incorporated herein by reference.

Thus, in a further embodiment, one or more of the at least one pin diode as comprised in this kind of FiP device can be arranged in form of having at least one absorber material as known from thin-film solar cells. Herein, the absorber material as being used for the purposes of the present invention may exhibit a diamond-like structure, thus, comprising a number of tetravalent atoms. As a result, the absorber material may be selected from one or more of diamond (C), silicon (Si), silicon carbide (SiC), silicon germanium (SiGe), or germanium (Ge). Alternatively, the absorber material may exhibit a modified diamond-like structure, wherein one or more of the tetravalent atoms of the diamond-like structure may be substituted by an atom combination which may, in particular, affect an average of four valence electrons within the modified structure. As an example, a III-V compound comprising one chemical element from each of the groups III and V of the periodic table may be suitable for this purpose since two tetravalent atoms which jointly comprise 2×4 =8 valence electrons may, accordingly, be replaced by 3+5=8 valence electrons. As a further example, a I-III-VI₂ compound comprising one chemical element from each of the groups I and III and two chemical elements from the group VI may also be used since four tetravalent atoms jointly comprising 4×4=16 valence electrons may, here, be replaced by 1+4+(2×6)=16 valence electrons. However, other kinds of combinations may also be feasible.

Thus, the absorber material may, preferably, be selected from the group comprising
a III-V compound, in particular indium antimonide (InSb), indium arsenide (InAs), gallium nitride (GaN), gallium arsenide (GaAs), indium gallium arsenide (InGaAs), or aluminum gallium phosphide (AlGaP);
a II-VI compound, in particular cadmium telluride (CdTe), or mercury cadmium telluride (HgCdTe, also abbreviated to “MCT”) which may be considered as II-VI ternary alloy of CdTe and HgTe;
a I-III-VI₂ compound, in particular copper indium sulfide (CuInS₂; CIS) and, more preferred, copper indium gallium selenide (CIGS), which may be considered as a solid solution of copper indium selenide (CIS) and copper gallium selenide (CuGaSe₂), thus, comprising a chemical formula of CuInₓGa₍₁₋ₓ₎Se₂, wherein x can vary from 0, i.e. pure CuGaSe₂, to 1, i.e. pure CIS;
a I₂-II-IV-VI₄ compound, in particular copper zinc tin sulfide (CZTS), copper zinc tin selenide (CZTSe), or a copper-zinc-tin sulfur-selenium chalcogenide (CZTSSe);
a halide perovskite compound, especially a compound comprising an alkaline cation, or, in particular, an organic-inorganic halide perovskite, such as a methylammonium metal halide (CH₃NH₃MX₃ with M being a divalent metal, such as Pb or Sn, and X═Cl, Br, or I), preferably methylammonium lead iodide (CH₃NH₃PbI₃); and
a solid solution and/or a doped variant thereof.

Hereby, compounds, such as CZTS, which neither comprise rare chemical elements, such as Indium (In), nor toxic chemical elements, such as cadmium (Cd), may especially be preferred. However, further types of compounds and/or additional examples may also be feasible.

In addition, further considerations may, however, concern a sensitivity of the addressed absorber material with particular respect to an absorption rate as a function of the wavelength of the incident light beam. Within this respect, the mentioned I-III-VI₂ compounds CIS and CIGS as well as the mentioned I₂-II-IV-VI₄ compounds CZTS, CZTSe, and CZTSSe may particularly be used for related purposes within both the visual spectral range and the NIR spectral range from 780 nm to 1300 nm. For longer wavelengths, in particular above 1300 nm, the II-VI compounds InSb, InAs and HgCdTe (MCT) can, however, be a preferred choice.

Further, a combination and/or a solid solution and/or a doped variant of the mentioned materials may also be used. As used herein, the term “solid solution” refers to a state of the respective material in which at least one solute may be comprised in a solvent, whereby a homogeneous phase may be formed and wherein the crystal structure of the solvent may, generally, be unaltered by the presence of the solute. By way of example, the first binary compound CdTe may be solved in the second binary compound ZnTe leading to Cd₁₋ₓZnₓTe, wherein x can vary from 0 to 1. As further used herein, the term “doped variant” may refer to a state of the material in which single atoms apart from the constituents of the material itself are introduced onto sites within the crystal which are occupied by intrinsic atoms in the undoped state. By way of example, a pure silicon crystal may be doped with one or more of boron, aluminum, gallium, indium, phosphorous, arsenic, antimony, germanium, or other atoms, particularly, in order to modify the chemical and/or physical properties of the silicon crystal.

Further, both the n-type semiconductor layer and the p-type semiconductor layer may comprise the same material as the i-type semiconductor layer, however, with different kinds of dopants in order to provide the respective doping of the layer. However, the n-type semiconductor layer may, alternatively, comprise cadmium sulfide (CdS) or, in particular, for avoiding toxic cadmium (Cd) one or more of zinc sulfide (ZnS), zinc oxide (ZnO), or zinc hydroxide (ZnOH).

Alternatively or in addition, an organic material, in particular an organic material as employed for organic solar cells, may also be used for one or more layers as comprised in one or more of the pin diodes. As a particular advantage of organic materials, it may be feasible to separate two kinds of processes, i.e. generating electrical charges, on one hand, from transporting electrical charges, on the other hand, by employing two different kinds of organic materials, which may be denoted as a donor-like “electron donor material” or “charge-generation material”, abbreviated to “CGM” and as an acceptor-like “electron acceptor material” or “charge-transport material”, abbreviated to “CTM”. As a particular example first presented by R. M. Schaffert, IBM J. Res. Develop., 1971, p. 75-89, polyvinylcarbazole (1) may be considered as the charge-generation material while trinitrofluorenone (2) may be regarded as the charge-transport material:

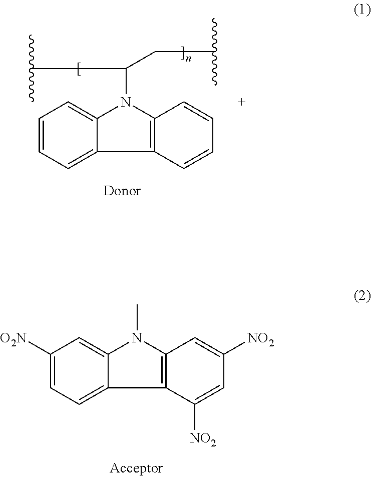

In a particularly preferred embodiment, the organic materials may, thus, comprise at least one conjugated aromatic molecule, preferably a highly conjugated aromatic molecule, in particular a dye or a pigment, preferably to be employed as the charge-generation material. In this respect, particularly preferred examples of conjugated aromatic molecules include phthalocyanines, such as metal phthalocyanines, in particular TiO-phthalocyanine; naphthalocyanines, such as metal-naphthalocyanines, in particular TiO-naphthalocyanine; subphthalocyanines, such as metal-subphthalocyanines; perylenes, anthracenes; pyrenes; oligo- and polythiophenes; fullerenes; indigoid dyes, such as thioindigos; bis-azo pigments; squarylium dyes; thiapyrilium dyes; azulenium dyes; dithioketo-pyrrolopyrroles; quinacridones; and other organic materials which may exhibit photoconductive properties, such as dibromoanthanthrone, or a derivative or a combination thereof. However, further conjugated aromatic molecules or, in addition, other kinds of organic materials, also in combination with inorganic materials, may also be feasible.

With regard to phthalocyanines, reference may be may made to Frank H. Moser and Arthur L. Thomas, Phthalocyanine Compounds, Reinhold Publishing, New York, 1963, p. 69-76, as well as to Arthur L. Thomas, Phthalocyanine Research and Applications, CRC Press, Boca Raton, 1990, p. 253-272. As presented there, dihydrogenphthalocyanine (3) or a metal phthalocyanine (4) may preferably be also used in the detector according to the present invention:

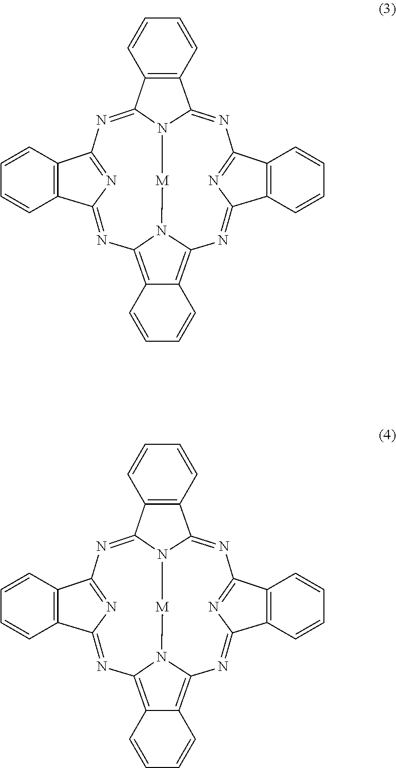

wherein the metal phthalocyanine (4) may, preferably, comprise a metal M selected from magnesium (Mg), copper (Cu), germanium (Ge), or zinc (Zn), or from a metal comprised in an inorganic compound, such as one of Al—Cl, Ga—Cl, In—Cl, TiOCl, VO, TiO, HGa, Si(OH)₂, Ge(OH)₂, Sn(OH)₂, or Ga(OH).

With respect to indigoid dyes, reference may be made to U.S. Pat. No. 4,952,472 A, in which the following three structures (5a, 5b, 5c), wherein X may equal O, S, or Se, are disclosed:

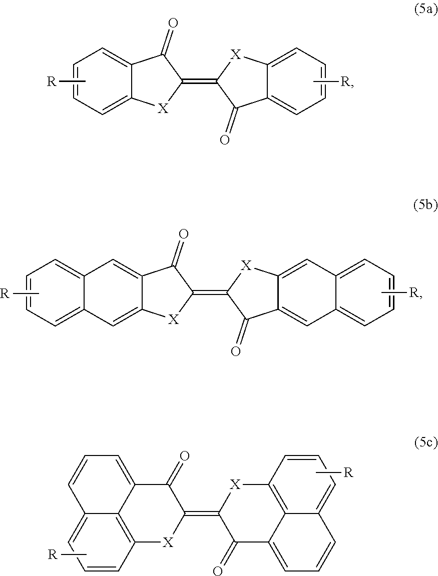

Herein, a preferred indigoid may comprise the compound 4,4′,7,7′-tetrachlorothioindigo (6) which is, for example, disclosed in K. Fukushima et al., Crystal Structures and Photocarrier Generation of Thioindigo Derivatives, J. Chem. Phys. B, 102, 1988, p. 5985-5990:

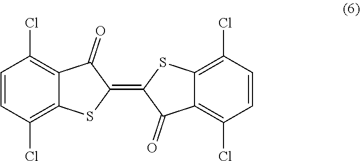 [SMILES: O=C1/C(=C2\Sc3c(Cl)ccc(Cl)c3C2=O)Sc2c(Cl)ccc(Cl)c21]

With regard to bis-azo pigments, a preferred example may be chlorodiane blue (7), which comprises the following structure:

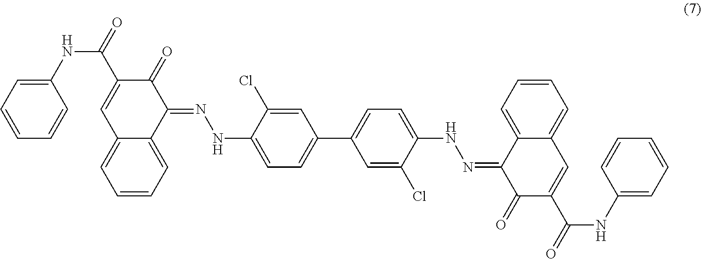 [SMILES: O=C(Nc1ccccc1)C1=Cc2ccccc2/C(=N\Nc2ccc(-c3ccc(N/N=C4/C(=O)C(C(=O)Nc5ccccc5)=Cc5ccccc54)c(Cl)c3)cc2Cl)C1=O]

With respect to perylene derivatives, preferably perylenebisimides (8a) or perylenemonoimides (8b), wherein R is an organic residue, preferably a branched or unbranched alkyl chain, may be used as the organic material:

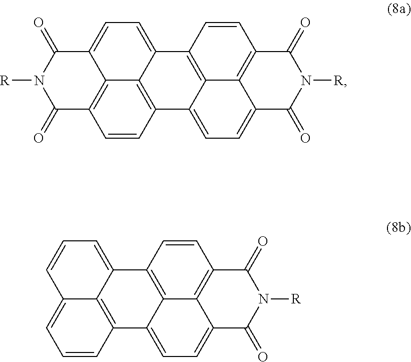

With regard to squarylium dyes, a preferred example may comprise the following molecule (9):

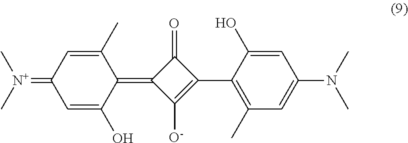

With respect to thiapyrilium dyes, a preferred example may comprise molecule (10) having the following structure:

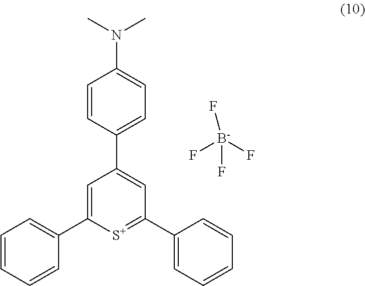 [SMILES: CN(C)c1ccc(-c2cc(-c3ccccc3)[s+]c(-c3ccccc3)c2)cc1 ; F[B-](F)(F)F]

Further, U.S. Pat. No. 4,565,761 A discloses a number of azulenium dyes, such as the following preferred compound (11):

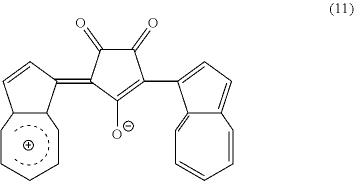 [SMILES: O=C1C(=O)/C(=C2\C=CC3CCCCCC23)C([O-])=C1c1ccc2cccccc1-2]

Concerning dithioketo-pyrrolopyrroles, U.S. Pat. No. 4,760,151 A discloses a number of compounds, such as the following preferred molecule (12):

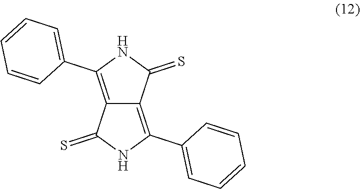 [SMILES: S=C1NC(c2ccccc2)=C2C(=S)NC(c3ccccc3)=C12]

With regard to quinacridones, U.S. Pat. No. 4,760,004 A discloses different thioquinacridones and isothio- quinacridones, including the following preferred compound (13):

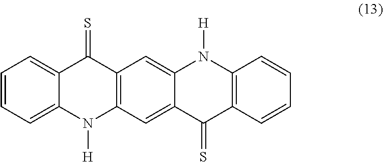 [SMILES: S=c1c2ccccc2[nH]c2cc3c(=S)c4ccccc4[nH]c3cc12]

As mentioned above, further organic materials, such as dibromoanthanthrone (14), may also exhibit properties being sufficient for being used in the detector according to the present invention:

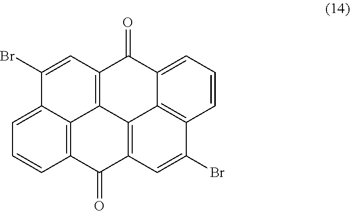 [SMILES: O=c1c2cc(Br)c3cccc4c(=O)c5cc(Br)c6cccc1c6c5-c2c34]

Furthermore, a mixture comprising at least one photoconductor and at least one sensitizer, such as further specified, for example, in U.S. Pat. No. 3,112,197 A or EP 0 112 169 A2 or in a respective reference therein, may also be suitable for being used in the detector according to the present invention.

Preferably, the electron donor material and the electron acceptor material may be comprised within a layer which comprises the materials in form of a mixture. As generally used, the term “mixture” relates to a blend of two or more individual compounds, wherein the individual compounds within the mixture maintain their chemical identity. In a particularly preferred embodiment, the mixture may comprise the electron donor material and the electron acceptor material in a ratio from 1:100 to 100:1, more preferred from 1:10 to 10:1, in particular in a ratio of from 1:2 to 2:1, such as 1:1. However, other ratios of the respective compounds may also be applicable, in particular depending on the kind and number of individual compounds being involved. Preferably, the electron donor material and the electron acceptor material as comprised in form of the mixture may constitute an interpenetrating network of donor domains, in which the electron donor material may predominantly, particularly completely, be present, and of acceptor domains, in which the electron acceptor material may predominantly, in particular completely, be present, wherein interfacial areas between the donor domains and the acceptor domains may exist, and wherein as conductive paths in form of percolation pathways may connect the corresponding domains to the respective electrodes.

In a further preferred embodiment, the electron donor material may comprise a donor polymer, in particular an organic donor polymer, whereas the electron acceptor material may comprise an acceptor small molecule, preferably selected from the group comprising a fullerene-based electron acceptor material, tetracyanoquinodimethane (TCNQ), a perylene derivate, and an acceptor polymer. Thus, the electron donor material may comprise a donor polymer while the electron acceptor material may comprise an acceptor polymer, thus providing a basis for an all- polymer layer. In a particular embodiment, a copolymer may, simultaneously, be constituted from one of the donor polymers and from one of the acceptor polymers and which may, therefore, also be denominated as a “push-pull copolymer” based on the respective function of each of the constituents of the copolymer. As generally used, the term “polymer” refers to a macromolecular composition that generally comprises a large number of molecular repeat units, which are usually denominated as “monomers” or “monomeric units”. For the purposes of the present invention, however, a synthetic organic polymer may be preferred. Within this regard, the term “organic polymer” refers to the nature of the monomeric units which may, generally, be attributed as organic chemical compounds. As used herein, the term “donor polymer” refers to a polymer which may particularly be adapted to provide electrons as the electron donor material. Analogously, the term “acceptor polymer” refers to a polymer which may particularly be adapted to receive electrons as the electron acceptor material. Preferably, the layer comprising the organic electron donor material and the organic electron acceptor material may exhibit a thickness from 100 nm to 2000 nm.

Thus, the at least one electron donor material may comprise a donor polymer, in particular an organic donor polymer. Preferably, the donor polymer may comprise a conjugated system, in which delocalized electrons may be distributed over a group of atoms being bonded together by alternating single and multiple bonds, wherein the conjugated system may be one or more of cyclic, acyclic, and linear. Thus, the organic donor polymer may, preferably, be selected from one or more of the following polymers:
poly[3-hexylthiophene-2,5.diyl] (P3HT),
poly[3-(4-n-octyl)-phenylthiophene] (POPT),
poly[3-10-n-octyl-3-phenothiazine-vinylenethiophene-co-2,5-thiophene] (PTZV-PT), poly[4,8-bis[(2-ethylhexyl)oxy]benzo[1,2-b:4,5-b]dithiophene-2,6-diyl][3-fluoro-2-[(2-ethylhexyl)carbonyl]thieno[3,4-b]thiophenediyl] (PTB7),
poly[thiophene-2,5-diyl-alt-[5,6-bis(dodecyloxy)benzo[c][1,2,5]thiadiazole]-4,7-diyl] (PBT-T1),
poly[2,6-(4,4-bis-(2-ethylhexyl)-4H-cyclopenta[2,1-b;3,4-b]dithiophene)-alt-4,7(2,1,3-benzothiadiazole)] (PCPDTBT),
poly[5,7-bis(4-decanyl-2-thienyl)-thieno(3,4-b)diathiazolethiophene-2,5] (PDDTT),
poly[N-9′-heptadecanyl-2,7-carbazole-alt-5,5-(4′,7′-di-2-thienyl-2′,1′,3′-benzothiadiazole)] (PCDTBT), or
poly[(4,4′-bis(2-ethylhexyl)dithieno[3,2-b;2′,3′-d]silole)-2,6-diyl-alt-(2,1,3-benzothia-diazole)-4,7-diyl] (PSBTBT),
poly[3-phenylhydrazone thiophene] (PPHT),
poly[2-methoxy-5-(2-ethylhexyloxy)-1,4-phenylenevinylene] (MEH-PPV),
poly[2-methoxy-5-(2′-ethylhexyloxy)-1,4-phenylene-1,2-ethenylene-2,5-dimethoxy-1,4-phenylene-1,2-ethenylene] (M3EH-PPV),
poly[2-methoxy-5-(3′,7′-dimethyloctyloxy)-1,4-phenylenevinylene] (MDMO-PPV),
poly[9,9-di-octylfluorene-co-bis-N,N-4-butylphenyl-bis-N,N-phenyl-1,4-phenylenediamine] (PFB),
   or a derivative, a modification, or a mixture thereof.

However, other kinds of donor polymers or further electron donor materials may also be suitable, in particular polymers which are sensitive in the infrared spectral range, especially above 1000 nm, preferably diketopyrrolopyrrol polymers, in particular, the polymers as described in EP 2 818 493 A1, more preferably the polymers denoted as “P-1” to “P-10” therein; benzodithiophene polymers as disclosed in WO 2014/086722 A1, especially diketopyrrolopyrrol polymers comprising benzodithiophene units; dithienobenzofuran polymers according to US 2015/0132887 A1, especially dithienobenzofuran polymers comprising diketopyrrolopyrrol units; phenantro[9, 10-B]furan polymers as described in US 2015/0111337 A1, especially phenan- tro[9, 10-B]furan polymers which comprise diketopyrrolopyrrol units; and polymer compositions comprising diketopyrrolopyrrol oligomers, in particular, in an oligomer-polymer ratio of 1:10 or 1:100, such as disclosed in US 2014/0217329 A1.

As further mentioned above, the electron acceptor material may, preferably, comprise a fullerene-based electron acceptor material. As generally used, the term “fullerenes” refers to cage-like molecules of pure carbon, including Buckminster fullerene (C60) and the related spherical fullerenes. In principle, the fullerenes in the range of from C20 to C2000 may be used, the range C60 to C96 being preferred, particularly C60, C70 and C84. Mostly preferred are fullerenes which are chemically modified, in particular one or more of:
[6,6]-phenyl-C61-butyric acid methyl ester (PC60BM),
[6,6]-Phenyl-C71-butyric acid methyl ester (PC70BM),
[6,6]-phenyl C84 butyric acid methyl ester (PC84BM), or
an indene-C60 bisadduct (ICBA),
   but also dimers comprising one or two C60 or C70 moieties, in particular
a diphenylmethanofullerene (DPM) moiety comprising one attached oligoether (OE) chain (C70-DPM-OE), or
a diphenylmethanofullerene (DPM) moiety comprising two attached oligoether (OE) chains (C70-DPM-OE2),
   or a derivative, a modification, or a mixture thereof. However, TCNQ, or a perylene derivative may also be suitable.

Alternatively or in addition, the electron acceptor material may, preferably, comprise an acceptor polymer. Generally, conjugated polymers based on cyanated poly(phenylenevinylene), benzo-thiadiazole, perylene or naphthalenediimide are preferred for this purpose. In particular, the acceptor polymer may, preferably, be selected from one or more of the following polymers:
a cyano-poly[phenylenevinylene] (CN-PPV), such as C6-CN-PPV or C8-CN-PPV,
poly[5-(2-(ethylhexyloxy)-2-methoxycyanoterephthalyliden] (MEH-CN-PPV),
poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV),
poly[1,4-dioctyloxyl-p-2,5-dicyanophenylenevinylene] (DOCN-PPV),
poly[9,9′-dioctylfluoreneco-benzothiadiazole] (PF8BT),
   or a derivative, a modification, or a mixture thereof. However, other kinds of acceptor polymers may also be suitable.

For more details concerning the mentioned compounds which may be used as the donor polymer or the electron acceptor material, reference may be made to the review articles by L. Biana, E. Zhua, J. Tanga, W. Tanga, and F. Zhang, Progress in Polymer Science 37, 2012, p. 1292-1331, A. Facchetti, Materials Today, Vol. 16, No. 4, 2013, p. 123-132, and S. Günes and N. S. Sariciftci, Inorganica Chimica Acta 361, 2008, p. 581-588, as well as the respective references cited therein. Further compounds are described in the dissertation of F. A. Sperlich, Electron Paramagnetic Resonance Spectroscopy of Conjugated Polymers and Fullerenes for Organic Photovoltaics, Julius-Maximilians-Universitat Würzburg, 2013, and the references cited therein.

Using a layer of the organic materials exhibits a number of advantages, in particular with respect to the known inorganic materials. The layer of the organic materials may, preferably, be produced by known high-throughput methods, in particular by a deposition method, preferably a coating method, more preferred a spin-coating method, a slot-coating method, or a blade-coating method, or, alternatively, by evaporation. The transparency, semitransparency or translucency of the organic materials as obtained in this manner, thus, allows providing a stack of longitudinal sensors which each comprises a layer of this kind of materials.

As used herein, the term “evaluation device” generally refers to an arbitrary device designed to generate the items of information, i.e. the at least one item of information on the position of the object. As an example, the evaluation device may be or may comprise one or more integrated circuits, such as one or more application-specific integrated circuits (ASICs), and/or field programmable gate arrays (FPGAs), and/or digital signal processors (DSPs), and/or one or more data processing devices, such as one or more computers, preferably one or more microcomputers and/or microcontrollers. Additional components may be comprised, such as one or more preprocessing devices and/or data acquisition devices, such as one or more devices for receiving and/or preprocessing of the sensor signals, such as one or more AD-converters and/or one or more filters. As used herein, the sensor signal may generally refer to one of the longitudinal sensor signal and, if applicable, to the transversal sensor signal. Further, the evaluation device may comprise one or more data storage devices. Further, as outlined above, the evaluation device may comprise one or more interfaces, such as one or more wireless interfaces and/or one or more wire-bound interfaces.

The at least one evaluation device may be adapted to perform at least one computer program, such as at least one computer program performing or supporting the step of generating the items of information. As an example, one or more algorithms may be implemented which, by using the sensor signals as input variables, may perform a predetermined transformation into the position of the object.

The evaluation device may particularly comprise at least one data processing device, in particular an electronic data processing device, which can be designed to generate the items of information by evaluating the sensor signals. Thus, the evaluation device is designed to use the sensor signals as input variables and to generate the items of information on the transversal position and the longitudinal position of the object by processing these input variables. The processing can be done in parallel, subsequently or even in a combined manner. The evaluation device may use an arbitrary process for generating these items of information, such as by calculation and/or using at least one stored and/or known relationship. Besides the sensor signals, one or a plurality of further parameters and/or items of information can influence said relationship, for example at least one item of information about a modulation frequency. The relationship can be determined or determinable empirically, analytically or else semi-empirically. Particularly preferably, the relationship comprises at least one calibration curve, at least one set of calibration curves, at least one function or a combination of the possibilities mentioned. One or a plurality of calibration curves can be stored for example in the form of a set of values and the associated function values thereof, for example in a data storage device and/or a table. Alternatively or additionally, however, the at least one calibration curve can also be stored for example in parameterized form and/or as a functional equation. Separate relationships for processing the sensor signals into the items of information may be used. Alternatively, at least one combined relationship for processing the sensor signals is feasible. Various possibilities are conceivable and can also be combined.

By way of example, the evaluation device can be designed in terms of programming for the purpose of determining the items of information. The evaluation device can comprise in particular at least one computer, for example at least one microcomputer. Furthermore, the evaluation device can comprise one or a plurality of volatile or nonvolatile data memories. As an alternative or in addition to a data processing device, in particular at least one computer, the evaluation device can comprise one or a plurality of further electronic components which are designed for determining the items of information, for example an electronic table and in particular at least one look-up table and/or at least one application-specific integrated circuit (ASIC).

The detector has, as described above, at least one evaluation device. In particular, the at least one evaluation device can also be designed to completely or partly control or drive the detector, for example by the evaluation device being designed to control at least one illumination source and/or to control at least one modulation device of the detector. The evaluation device can be designed, in particular, to carry out at least one measurement cycle in which one or a plurality of sensor signals, such as a plurality of sensor signals, are picked up, for example a plurality of sensor signals of successively at different modulation frequencies of the illumination.

The evaluation device is designed, as described above, to generate at least one item of information on the position of the object by evaluating the at least one sensor signal. Said position of the object can be static or may even comprise at least one movement of the object, for example a relative movement between the detector or parts thereof and the object or parts thereof. In this case, a relative movement can generally comprise at least one linear movement and/or at least one rotational movement. Items of movement information can for example also be obtained by comparison of at least two items of information picked up at different times, such that for example at least one item of location information can also comprise at least one item of velocity information and/or at least one item of acceleration information, for example at least one item of information about at least one relative velocity between the object or parts thereof and the detector or parts thereof. In particular, the at least one item of location information can generally be selected from: an item of information about a distance between the object or parts thereof and the detector or parts thereof, in particular an optical path length; an item of information about a distance or an optical distance between the object or parts thereof and the optional transfer device or parts thereof; an item of information about a positioning of the object or parts thereof relative to the detector or parts thereof; an item of information about an orientation of the object and/or parts thereof relative to the detector or parts thereof; an item of information about a relative movement between the object or parts thereof and the detector or parts thereof; an item of information about a two-dimensional or three-dimensional spatial configuration of the object or of parts thereof, in particular a geometry or form of the object. Generally, the at least one item of location information can therefore be selected for example from the group consisting of: an item of information about at least one location of the object or at least one part thereof; information about at least one orientation of the object or a part thereof; an item of information about a geometry or form of the object or of a part thereof, an item of information about a velocity of the object or of a part thereof, an item of information about an acceleration of the object or of a part thereof, an item of information about a presence or absence of the object or of a part thereof in a visual range of the detector.

The at least one item of location information can be specified for example in at least one coordinate system, for example a coordinate system in which the detector or parts thereof rest. Alternatively or additionally, the location information can also simply comprise for example a distance between the detector or parts thereof and the object or parts thereof. Combinations of the possibilities mentioned are also conceivable.

In a particular embodiment of the present invention, the detector may comprise at least two individual longitudinal optical sensors, wherein each longitudinal optical sensor may be adapted to generate at least one longitudinal sensor signal. As an example, the sensor regions or the sensor surfaces of the longitudinal optical sensors may, thus, be oriented in parallel, wherein slight angular tolerances might be tolerable, such as angular tolerances of no more than 10°. preferably of no more than 5°. Herein, preferably all of the longitudinal optical sensors of the detector, which may, preferably, be arranged in form of a stack along the optical axis of the detector, may be transparent. Thus, the light beam may pass through a first transparent longitudinal optical sensor before impinging on the other longitudinal optical sensors, preferably subsequently. Thus, the light beam from the object may subsequently reach all longitudinal optical sensors present in the optical detector. Herein, the different longitudinal optical sensors may exhibit the same or different spectral sensitivities with respect to the incident light beam.

Preferably, the detector according to the present invention may comprise a stack of longitudinal optical sensors as disclosed in WO 2014/097181 A1, particularly in combination with one or more transversal optical sensors. As an example, one or more transversal optical sensors may be located on a side of the stack of longitudinal optical sensors facing towards the object. Alternatively or additionally, one or more transversal optical sensors may be located on a side of the stack of longitudinal optical sensors facing away from the object. Again, additionally or alternatively, one or more transversal optical sensors may be interposed in between the longitudinal optical sensors of the stack. However, embodiments which may only comprise a single longitudinal optical sensor but no transversal optical sensor may still be possible, such as in a case wherein only determining the depth of the object may be desired.

As used herein, the term “transversal optical sensor” generally refers to a device which is adapted to determine a transversal position of at least one light beam traveling from the object to the detector. With regard to the term position, reference may be made to the definition above. Thus, preferably, the transversal position may be or may comprise at least one coordinate in at least one dimension perpendicular to an optical axis of the detector. As an example, the transversal position may be a position of a light spot generated by the light beam in a plane perpendicular to the optical axis, such as on a light-sensitive sensor surface of the transversal optical sensor. As an example, the position in the plane may be given in Cartesian coordinates and/or polar coordinates. Other embodiments are feasible. For potential embodiments of the transversal optical sensor, reference may be made to WO 2014/097181 A1 or to PCT patent application No. PCT/EP2016/051817, filed Jan. 28, 2016. However, other embodiments are feasible and will be outlined in further detail below.

The transversal optical sensor may provide at least one transversal sensor signal. Herein, the transversal sensor signal may generally be an arbitrary signal indicative of the transversal position. As an example, the transversal sensor signal may be or may comprise a digital and/or an analog signal. As an example, the transversal sensor signal may be or may comprise a voltage signal and/or a current signal. Additionally or alternatively, the transversal sensor signal may be or may comprise digital data. The transversal sensor signal may comprise a single signal value and/or a series of signal values. The transversal sensor signal may further comprise an arbitrary signal which may be derived by combining two or more individual signals, such as by averaging two or more signals and/or by forming a quotient of two or more signals.

In a first embodiment similar to the disclosure according to WO 2014/097181 A1, the transversal optical sensor may be a photo detector having at least one first electrode, at least one second electrode and at least one photovoltaic material, wherein the photovoltaic material may be embedded in between the first electrode and the second electrode. Thus, the transversal optical sensor may be or may comprise one or more photo detectors, such as one or more organic photodetectors and, most preferably, one or more dye-sensitized organic solar cells (DSCs, also referred to as dye solar cells), such as one or more solid dye-sensitized organic solar cells (s-DSCs). Thus, the detector may comprise one or more DSCs (such as one or more sDSCs) acting as the at least one transversal optical sensor and one or more DSCs (such as one or more sDSCs) acting as the at least one longitudinal optical sensor.

In a further embodiment, the transversal optical sensor may comprise a layer of the photoconductive material, preferably an inorganic photoconductive material, such as one of the photoconductive materials as disclosed in PCT patent application No. PCT/EP2016/051817, filed Jan. 28, 2016. Herein, the layer of the photoconductive material may comprise a composition selected from a homogeneous, a crystalline, a polycrystalline, a microcrystalline, a nanocrystalline and/or an amorphous phase. Preferably, the layer of the photoconductive material may be embedded in between two layers of a transparent conducting oxide, preferably comprising indium tin oxide (ITO), fluorine doped tin oxide (FTO), or magnesium oxide (MgO), wherein one of the two layers may be replaced by metal nanowires, in particular by Ag nanowires. However, other material may be feasible, in particular according to the desired transparent spectral range.

Further, at least two electrodes may be present for recording the transversal optical signal. In a preferred embodiment, the at least two electrodes may actually be arranged in the form of at least two physical electrodes, wherein each physical electrode may comprise an electrically conducting material, preferably a metallically conducting material, more preferred a highly metallically conducting material such as copper, silver, gold, an alloy or a composition which comprises these kinds of materials, or graphene. Herein, each of the at least two physical electrodes may, preferably, be arranged in a manner that a direct electrical contact between the respective electrode and the adjacent layer in the optical sensor may be achieved, particularly in order to acquire the longitudinal sensor signal with as little loss as possible, such as due to additional resistances in a transport path between the optical sensor and the evaluation device.

Preferably, at least one of the electrodes of the transversal optical sensor may be a split electrode having at least two partial electrodes, wherein the transversal optical sensor may have a sensor area, wherein the at least one transversal sensor signal may indicate an x- and/or a y-position of the incident light beam within the sensor area. The sensor area may be a surface of the photo detector facing towards the object. The sensor area preferably may be oriented perpendicular to the optical axis. Thus, the transversal sensor signal may indicate a position of a light spot generated by the light beam in a plane of the sensor area of the transversal optical sensor. Generally, as used herein, the term “partial electrode” refers to an electrode out of a plurality of electrodes, adapted for measuring at least one current and/or voltage signal, preferably independent from other partial electrodes. Thus, in case a plurality of partial electrodes is provided, the respective electrode is adapted to provide a plurality of electric potentials and/or electric currents and/or voltages via the at least two partial electrodes, which may be measured and/or used independently.

The transversal optical sensor may further be adapted to generate the transversal sensor signal in accordance with the electrical currents through the partial electrodes. Thus, a ratio of electric currents through two horizontal partial electrodes may be formed, thereby generating an x-coordinate, and/or a ratio of electric currents through to vertical partial electrodes may be formed, thereby generating a y-coordinate. The detector, preferably the transversal optical sensor and/or the evaluation device, may be adapted to derive the information on the transversal position of the object from at least one ratio of the currents through the partial electrodes. Other ways of generating position coordinates by comparing currents through the partial electrodes are feasible.

The partial electrodes may generally be defined in various ways, in order to determine a position of the light beam in the sensor area. Thus, two or more horizontal partial electrodes may be provided in order to determine a horizontal coordinate or x-coordinate, and two or more vertical partial electrodes may be provided in order to determine a vertical coordinate or y- coordinate. Thus, the partial electrodes may be provided at a rim of the sensor area, wherein an interior space of the sensor area remains free and may be covered by one or more additional electrode materials. As will be outlined in further detail below, the additional electrode material preferably may exhibit transparent, semi-transparent or translucent optical properties, such as a transparent metal and/or a transparent conductive oxide and/or, most preferably, a transparent conductive polymer.

By using the transversal optical sensor, wherein one of the electrodes is a split electrode with three or more partial electrodes, currents through the partial electrodes may be dependent on a position of the light beam in the sensor area. This may generally be due to the fact that Ohmic losses or resistive losses may occur on the way from a location of generation of electrical charges due to the impinging light onto the partial electrodes. Thus, besides the partial electrodes, the split electrode may comprise one or more additional electrode materials connected to the partial electrodes, wherein the one or more additional electrode materials provide an electrical resistance. Thus, due to the Ohmic losses on the way from the location of generation of the electric charges to the partial electrodes through with the one or more additional electrode materials, the currents through the partial electrodes depend on the location of the generation of the electric charges and, thus, to the position of the light beam in the sensor area. For details of this principle of determining the position of the light beam in the sensor area, reference may be made to the preferred embodiments below and/or to the physical principles and device options as disclosed in WO 2014/097181 A1 and the respective references therein.

Accordingly, the transversal optical sensor may comprise the sensor area, which, preferably, may be transparent to the light beam travelling from the object to the detector. The transversal optical sensor may, therefore, be adapted to determine a transversal position of the light beam in one or more transversal directions, such as in the x- and/or in the y-direction. For this purpose, the at least one transversal optical sensor may further be adapted to generate at least one transversal sensor signal. Thus, the evaluation device may be designed to generate at least one item of information on a transversal position of the object by evaluating the transversal sensor signal of the longitudinal optical sensor.

Further embodiments of the present invention referred to the nature of the light beam which propagates from the object to the detector. As used herein, the term “light” generally refers to electromagnetic radiation in one or more of the visible spectral range, the ultraviolet spectral range and the infrared spectral range. Therein, in partial accordance with standard ISO-21348, the term visible spectral range generally refers to a spectral range of 380 nm to 760 nm. The term infrared (IR) spectral range generally refers to electromagnetic radiation in the range of 760 nm to 1000 μm, wherein the range of 760 nm to 1.4 μm is usually denominated as the near infrared (NIR) spectral range, the range from 1.4 μm to 3 μm as the short-wavelength infrared (SWIR) spectral range, the range from 3 μm to 8 μm as the mid-wavelength infrared (MWIR) spectral range, the range from 8 μm to 15 μm as the long-wavelength infrared (LWIR) spectral range, and the range from 15 μm to 1000 μm as the far infrared (FIR) spectral range. The term ultraviolet spectral range generally refers to electromagnetic radiation in the range of 1 nm to 380 nm, preferably in the range of 100 nm to 380 nm. Preferably, light as used within the present invention is visible light, i.e. light in the visible spectral range.

The term “light beam” generally refers to an amount of light emitted into a specific direction. Thus, the light beam may be a bundle of the light rays having a predetermined extension in a direction perpendicular to a direction of propagation of the light beam. Preferably, the light beam may be or may comprise one or more Gaussian light beams which may be characterized by one or more Gaussian beam parameters, such as one or more of a beam waist, a Rayleigh-length or any other beam parameter or combination of beam parameters suited to characterize a development of a beam diameter and/or a beam propagation in space.

The light beam might be admitted by the object itself, i.e. might originate from the object. Additionally or alternatively, another origin of the light beam is feasible. Thus, as will be outlined in further detail below, one or more illumination sources might be provided which illuminate the object, such as by using one or more primary rays or beams, such as one or more primary rays or beams having a predetermined characteristic. In the latter case, the light beam propagating from the object to the detector might be a light beam which is reflected by the object and/or a reflection device connected to the object.

As outlined above, the at least one longitudinal sensor signal, given the same total power of the illumination by the light beam, is, according to the FiP effect, dependent on a beam cross- section of the light beam in the sensor region of the at least one longitudinal optical sensor. As used herein, the term beam cross-section generally refers to a lateral extension of the light beam or a light spot generated by the light beam at a specific location. In case a circular light spot is generated, a radius, a diameter or a Gaussian beam waist or twice the Gaussian beam waist may function as a measure of the beam cross-section. In case non-circular light-spots are generated, the cross-section may be determined in any other feasible way, such as by determining the cross-section of a circle having the same area as the non-circular light spot, which is also referred to as the equivalent beam cross-section. Within this regard, it may be possible to employ the observation of an extremum, i.e. a maximum or a minimum, of the longitudinal sensor signal, in particular a global extremum, under a condition in which the corresponding material, such as a photovoltaic material, may be impinged by a light beam with the smallest possible cross-section, such as when the material may be located at or near a focal point as affected by an optical lens. In case the extremum is a maximum, this observation may be denominated as the positive FiP effect, while in case the extremum is a minimum, this observation may be denominated as the negative FiP effect.

Thus, irrespective of the material actually comprised in the sensor region but given the same total power of the illumination of the sensor region by the light beam, a light beam having a first beam diameter or beam cross-section may generate a first longitudinal sensor signal, whereas a light beam having a second beam diameter or beam-cross section being different from the first beam diameter or beam cross-section generates a second longitudinal sensor signal being different from the first longitudinal sensor signal. Thus, by comparing the longitudinal sensor signals, at least one item of information on the beam cross-section, specifically on the beam diameter, may be generated. For details of this effect, reference may be made to WO 2012/110924 A1. Accordingly, the longitudinal sensor signals generated by the longitudinal optical sensors may be compared, in order to gain information on the total power and/or intensity of the light beam and/or in order to normalize the longitudinal sensor signals and/or the at least one item of information on the longitudinal position of the object for the total power and/or total intensity of the light beam. Thus, as an example, a maximum value of the longitudinal optical sensor signals may be detected, and all longitudinal sensor signals may be divided by this maximum value, thereby generating normalized longitudinal optical sensor signals, which, then, may be transformed by using the above-mentioned known relationship, into the at least one item of longitudinal information on the object. Other ways of normalization are feasible, such as a normalization using a mean value of the longitudinal sensor signals and dividing all longitudinal sensor signals by the mean value. Other options are possible. Each of these options may be appropriate to render the transformation independent from the total power and/or intensity of the light beam. In addition, information on the total power and/or intensity of the light beam might, thus, be generated.

Specifically in case one or more beam properties of the light beam propagating from the object to the detector are known, the at least one item of information on the longitudinal position of the object may thus be derived from a known relationship between the at least one longitudinal sensor signal and a longitudinal position of the object. The known relationship may be stored in the evaluation device as an algorithm and/or as one or more calibration curves. As an example, specifically for Gaussian beams, a relationship between a beam diameter or beam waist and a position of the object may easily be derived by using the Gaussian relationship between the beam waist and a longitudinal coordinate.

This embodiment may, particularly, be used by the evaluation device in order to resolve an ambiguity in the known relationship between a beam cross-section of the light beam and the longitudinal position of the object. Thus, even if the beam properties of the light beam propagating from the object to the detector are known fully or partially, it is known that, in many beams, the beam cross-section narrows before reaching a focal point and, afterwards, widens again. Thus, before and after the focal point in which the light beam has the narrowest beam cross-section, positions along the axis of propagation of the light beam may occur in which the light beam has the same cross-section. Thus, as an example, at a distance z0 before and after the focal point, the cross-section of the light beam is identical. Thus, in case only one longitudinal optical sensor with a specific spectral sensitivity is used, a specific cross-section of the light beam might be determined, in case the overall power or intensity of the light beam is known. By using this information, the distance z0 of the respective longitudinal optical sensor from the focal point might be determined. However, in order to determine whether the respective longitudinal optical sensor is located before or behind the focal point, additional information is required, such as a history of movement of the object and/or the detector and/or information on whether the detector is located before or behind the focal point. In typical situations, this additional information may not be provided. Therefore, additional information may be gained in order to resolve the above-mentioned ambiguity. Thus, in case the evaluation device, by evaluating the longitudinal sensor signals, recognizes that the beam cross-section of the light beam on a first longitudinal optical sensor is larger than the beam cross-section of the light beam on a second longitudinal optical sensor, wherein the second longitudinal optical sensor is located behind the first longitudinal optical sensor, the evaluation device may determine that the light beam is still narrowing and that the location of the first longitudinal optical sensor is situated before the focal point of the light beam. Contrarily, in case the beam cross-section of the light beam on the first longitudinal optical sensor is smaller than the beam cross-section of the light beam on the second longitudinal optical sensor, the evaluation device may determine that the light beam is widening and that the location of the second longitudinal optical sensor is situated behind the focal point. Thus, generally, the evaluation device may be adapted to recognize whether the light beam widens or narrows, by comparing the longitudinal sensor signals of different longitudinal sensors.

For further details with regard to determining the at least one item of information on the longitudinal position of the object by employing the evaluation device according to the present invention, reference may made to the description in WO 2014/097181 A1. Thus, generally, the evaluation device may be adapted to compare the beam cross-section and/or the diameter of the light beam with known beam properties of the light beam in order to determine the at least one item of information on the longitudinal position of the object, preferably from a known dependency of a beam diameter of the light beam on at least one propagation coordinate in a direction of propagation of the light beam and/or from a known Gaussian profile of the light beam.

In addition to the at least one longitudinal coordinate of the object, at least one transversal coordinate of the object may be determined. Thus, generally, the evaluation device may further be adapted to determine at least one transversal coordinate of the object by determining a position of the light beam on the at least one transversal optical sensor, which may be a pixelated, a segmented or a large-area transversal optical sensor, as further outlined also in WO 2014/097181 A1.

In addition, the detector may comprise at least one transfer device, such as an optical lens, in particular one or more refractive lenses, particularly converging thin refractive lenses, such as convex or biconvex thin lenses, and/or one or more convex mirrors, which may further be arranged along the common optical axis. Most preferably, the light beam which emerges from the object may in this case travel first through the at least one transfer device and thereafter through the single transparent longitudinal optical sensor or the stack of the transparent longitudinal optical sensors until it may finally impinge on an imaging device. As used herein, the term “transfer device” refers to an optical element which may be configured to transfer the at least one light beam emerging from the object to optical sensors within the detector, i.e. the at least two longitudinal optical sensors and the at least one optional transversal optical sensor. Thus, the transfer device can be designed to feed light propagating from the object to the detector to the optical sensors, wherein this feeding can optionally be effected by means of imaging or else by means of non-imaging properties of the transfer device. In particular the transfer device can also be designed to collect the electromagnetic radiation before the latter is fed to the transversal and/or longitudinal optical sensor.

In addition, the at least one transfer device may have imaging properties. Consequently, the transfer device comprises at least one imaging element, for example at least one lens and/or at least one curved mirror, since, in the case of such imaging elements, for example, a geometry of the illumination on the sensor region can be dependent on a relative positioning, for example a distance, between the transfer device and the object. As used herein, the transfer device may be designed in such a way that the electromagnetic radiation which emerges from the object is transferred completely to the sensor region, for example is focused completely onto the sensor region, in particular if the object is arranged in a visual range of the detector.

Generally, the detector may further comprise at least one imaging device, i.e. a device capable of acquiring at least one image. The imaging device can be embodied in various ways. Thus, the imaging device can be for example part of the detector in a detector housing. Alternatively or additionally, however, the imaging device can also be arranged outside the detector housing, for example as a separate imaging device. Alternatively or additionally, the imaging device can also be connected to the detector or even be part of the detector. In a preferred arrangement, the stack of the transparent longitudinal optical sensors and the imaging device are aligned along a common optical axis along which the light beam travels. Thus, it may be possible to locate an imaging device in the optical path of the light beam in a manner that the light beam travels through the stack of the transparent longitudinal optical sensors until it impinges on the imaging device. However, other arrangements are possible.

As used herein, an “imaging device” is generally understood as a device which can generate a one-dimensional, a two-dimensional, or a three-dimensional image of the object or of a part thereof. In particular, the detector, with or without the at least one optional imaging device, can be completely or partly used as a camera, such as an IR camera, or an RGB camera, i.e. a camera which is designed to deliver three basic colors which are designated as red, green, and blue, on three separate connections. Thus, as an example, the at least one imaging device may be or may comprise at least one imaging device selected from the group consisting of: a pixelated organic camera element, preferably a pixelated organic camera chip; a pixelated inorganic camera element, preferably a pixelated inorganic camera chip, more preferably a CCD- or CMOS-chip; a monochrome camera element, preferably a monochrome camera chip; a multicolor camera element, preferably a multicolor camera chip; a full-color camera element, preferably a full-color camera chip. The imaging device may be or may comprise at least one device selected from the group consisting of a monochrome imaging device, a multi-chrome imaging device and at least one full color imaging device. A multi-chrome imaging device and/or a full color imaging device may be generated by using filter techniques and/or by using intrinsic color sensitivity or other techniques, as the skilled person will recognize. Other embodiments of the imaging device are also possible.

The imaging device may be designed to image a plurality of partial regions of the object successively and/or simultaneously. By way of example, a partial region of the object can be a one-dimensional, a two-dimensional, or a three-dimensional region of the object which is delimited for example by a resolution limit of the imaging device and from which electromagnetic radiation emerges. In this context, imaging should be understood to mean that the electromagnetic radiation which emerges from the respective partial region of the object is fed into the imaging device, for example by means of the at least one optional transfer device of the detector. The electromagnetic rays can be generated by the object itself, for example in the form of a luminescent radiation. Alternatively or additionally, the at least one detector may comprise at least one illumination source for illuminating the object.

In particular, the imaging device can be designed to image sequentially, for example by means of a scanning method, in particular using at least one row scan and/or line scan, the plurality of partial regions sequentially. However, other embodiments are also possible, for example embodiments in which a plurality of partial regions is simultaneously imaged. The imaging device is designed to generate, during this imaging of the partial regions of the object, signals, preferably electronic signals, associated with the partial regions. The signal may be an analogue and/or a digital signal. By way of example, an electronic signal can be associated with each partial region. The electronic signals can accordingly be generated simultaneously or else in a temporally staggered manner. By way of example, during a row scan or line scan, it is possible to generate a sequence of electronic signals which correspond to the partial regions of the object, which are strung together in a line, for example. Further, the imaging device may comprise one or more signal processing devices, such as one or more filters and/or analogue- digital-converters for processing and/or preprocessing the electronic signals.

Light emerging from the object can originate in the object itself, but can also optionally have a different origin and propagate from this origin to the object and subsequently toward the optical sensors. The latter case can be affected for example by at least one illumination source being used. The illumination source can be embodied in various ways. Thus, the illumination source can be for example part of the detector in a detector housing. Alternatively or additionally, however, the at least one illumination source can also be arranged outside a detector housing, for example as a separate light source. The illumination source can be arranged separately from the object and illuminate the object from a distance. Alternatively or additionally, the illumination source can also be connected to the object or even be part of the object, such that, by way of example, the electromagnetic radiation emerging from the object can also be generated directly by the illumination source. By way of example, at least one illumination source can be arranged on and/or in the object and directly generate the electromagnetic radiation by means of which the sensor region is illuminated. This illumination source can for example be or comprise an ambient light source and/or may be or may comprise an artificial illumination source. By way of example, at least one infrared emitter and/or at least one emitter for visible light and/or at least one emitter for ultraviolet light can be arranged on the object. By way of example, at least one light emitting diode and/or at least one laser diode can be arranged on and/or in the object. The illumination source can comprise in particular one or a plurality of the following illumination sources: a laser, in particular a laser diode, although in principle, alternatively or additionally, other types of lasers can also be used; a light emitting diode; an incandescent lamp; a neon light; a flame source; a heat source; an organic light source, in particular an organic light emitting diode; a structured light source. Alternatively or additionally, other illumination sources can also be used. It is particularly preferred if the illumination source is designed to generate one or more light beams having a Gaussian beam profile, as is at least approximately the case for example in many lasers. For further potential embodiments of the optional illumination source, reference may be made to one of WO 2012/110924 A1 and WO 2014/097181 A1. Still, other embodiments are feasible.

The at least one optional illumination source generally may emit light in at least one of: the ultraviolet spectral range, preferably in the range of 200 nm to 380 nm; the visible spectral range (380 nm to 780 nm); the infrared spectral range, preferably in the range of 780 nm to 3.0 micrometers. Most preferably, the at least one illumination source is adapted to emit light in the visible spectral range, preferably in the range of 500 nm to 780 nm, most preferably at 650 nm to 750 nm or at 690 nm to 700 nm. Herein, it is particularly preferred when the illumination source may exhibit a spectral range which may be related to the spectral sensitivities of the longitudinal sensors, particularly in a manner to ensure that the longitudinal sensor which may be illuminated by the respective illumination source may provide a sensor signal with a high intensity which may, thus, enable a high-resolution evaluation with a sufficient signal-to-noise- ratio.

Preferably, the materials used for the at least one longitudinal optical sensor may be fabricated by depositing the respective material on an insulating substrate, preferably on a ceramic substrate, in particular for providing mechanical stability to the layer of the material. In this manner, by depositing the selected layer on the appropriate substrate and providing at least two electrodes as electrically conducting contacts, the longitudinal optical sensor according to the present invention may, thus, be obtained. Herein, an illumination of the material in the sensor region by an incident light beam results in a variation of an electrically detectable porperty in the illuminated layer of the material in the sensor region which, given the same total power of the illumination, depends on the beam cross-section of the light beam in the sensor region. Consequently, upon impingement of the sensor region by the light beam the at least two electrodes may provide the longitudinal sensor signal which depends on the electrically detectable property of the material in the sensor region and, thus, allows determining the beam cross-section of the light beam in the sensor region, as described elsewhere. In this preferred embodiment, the incident light beam may directly impinge on the material in the sensor region, or may first impinge on the substrate until it may reach the sensor region, in which case it may be advantageous to employ a transparent substrate or at least a translucent substrate, such as a glass substrate, a quartz substrate, or a substrate comprising a transparent organic polymer.

Furthermore, the detector can have at least one modulation device for modulating the illumination, in particular for a periodic modulation, in particular a periodic beam interrupting device. A modulation of the illumination should be understood to mean a process in which a total power of the illumination is varied, preferably periodically, in particular with one or a plurality of modulation frequencies. In particular, a periodic modulation can be effected between a maximum value and a minimum value of the total power of the illumination. The minimum value can be 0, but can also be >0, such that, by way of example, complete modulation does not have to be effected. The modulation can be effected for example in a beam path between the object and the optical sensor, for example by the at least one modulation device being arranged in said beam path. Alternatively or additionally, however, the modulation can also be effected in a beam path between an optional illumination source—described in even greater detail below—for illuminating the object and the object, for example by the at least one modulation device being arranged in said beam path. A combination of these possibilities is also conceivable. The at least one modulation device can comprise for example a beam chopper or some other type of periodic beam interrupting device, for example comprising at least one interrupter blade or interrupter wheel, which preferably rotates at constant speed and which can thus periodically interrupt the illumination. Alternatively or additionally, however, it is also possible to use one or a plurality of different types of modulation devices, for example modulation devices based on an electro-optical effect and/or an acousto-optical effect. Once again alternatively or additionally, the at least one optional illumination source itself can also be designed to generate a modulated illumination, for example by said illumination source itself having a modulated intensity and/or total power, for example a periodically modulated total power, and/or by said illumination source being embodied as a pulsed illumination source, for example as a pulsed laser. Thus, by way of example, the at least one modulation device can also be wholly or partly integrated into the illumination source. Various possibilities are conceivable.

Accordingly, the detector can be designed in particular to detect at least two longitudinal sensor signals in the case of different modulations, in particular at least two longitudinal sensor signals at respectively different modulation frequencies. The evaluation device can be designed to generate the geometrical information from the at least two longitudinal sensor signals. As described in WO 2012/110924 A1 and WO 2014/097181 A1, it is possible to resolve ambiguities and/or it is possible to take account of the fact that, for example, a total power of the illumination is generally unknown. By way of example, the detector can be designed to bring about a modulation of the illumination of the object and/or at least one sensor region of the detector, such as at least one sensor region of the at least one longitudinal optical sensor, with a frequency of 0.05 Hz to 1 MHz, such as 0.1 Hz to 10 kHz. As outlined above, for this purpose, the detector may comprise at least one modulation device, which may be integrated into the at least one optional illumination source and/or may be independent from the illumination source. Thus, at least one illumination source might, by itself, be adapted to generate the above- mentioned modulation of the illumination, and/or at least one independent modulation device may be present, such as at least one chopper and/or at least one device having a modulated transmissibility, such as at least one electro-optical device and/or at least one acousto-optical device.

According to the present invention, it may be advantageous in order to apply at least one modulation frequency to the optical detector as described above. However, it may still be possible to directly determine the longitudinal sensor signal without applying a modulation frequency to the optical detector. As will be demonstrated below in more detail, an application of a modulation frequency may not be required under many relevant circumstances in order to acquire the desired longitudinal information about the object. As a result, the optical detector may, thus, not be required to comprise a modulation device which may further contribute to the simple and cost-effective setup of the spatial detector. As a further result, a spatial light modulator may be used in a time-multiplexing mode rather than a frequency-multiplexing mode or in a combination thereof.

In a further aspect of the present invention, an arrangement comprising at least two individual detectors according to any one of the preceding embodiments, preferably two or three individual optical sensors, which may be placed at at least two distinct locations is proposed. Herein, the at least two detectors preferably may have identical optical properties but might also be different with respect from each other. In addition, the arrangement may further comprise at least one illumination source. Herein, the at least one object might be illuminated by using at least one illumination source which generates primary light, wherein the at least one object elastically or inelastically reflects the primary light, thereby generating a plurality of light beams which propagate to one of the at least two detectors. The at least one illumination source may form or may not form a constituent part of each of the at least two detectors. By way of example, the at least one illumination source itself may be or may comprise an ambient light source and/or may be or may comprise an artificial illumination source. This embodiment is preferably suited for an application in which at least two detectors, preferentially two identical detectors, are employed for acquiring depth information, in particular, for the purpose to providing a measurement volume which extends the inherent measurement volume of a single detector.

In this regard, the individual optical sensor may, preferably, be spaced apart from the other individual optical sensors comprised by the detector in order to allow acquiring an individual image which may differ from the images taken by the other individual optical sensors. In particular, the individual optical sensors may be arranged in separate beam paths in a collimated arrangement in order to generate a single circular, three-dimensional image. Thus, the individual optical sensors may be aligned in a manner that they are located parallel to the optical axis and may, in addition, exhibit an individual displacement in an orientation perpendicular to the optical axis of the detector. Herein, an alignment may be achieved by adequate measures, such as by adjusting a location and orientation of the individual optical sensor and/or the corresponding transfer element. Thus, the two individual optical sensors may, preferably, be spaced apart in a manner that they may be able to generate or increase a perception of depth information, especially in a fashion that the depth information may be obtained by combining visual information as derived from the two individual optical sensors having overlapping fields of view, such as the visual information as obtained by binocular vision. For this purpose, the individual optical sensors may, preferably be spaced apart from each other by a distance from 1 cm to 100 cm, preferably from 10 cm to 25 cm, as determined in the direction perpendicular to the optical axis. As used herein, the detector as provided in this embodiment may, in particular, be part of a “stereoscopic system” which will be described below in more detail. Besides allowing stereoscopic vision, further particular advantages of the stereoscopic system which are primarily based on a use of more than one optical sensor may, in particular, include an increase of the total intensity and/or a lower detection threshold.

In a further aspect of the present invention, a human-machine interface for exchanging at least one item of information between a user and a machine is proposed. The human-machine interface as proposed may make use of the fact that the above-mentioned detector in one or more of the embodiments mentioned above or as mentioned in further detail below may be used by one or more users for providing information and/or commands to a machine. Thus, preferably, the human-machine interface may be used for inputting control commands.

The human-machine interface comprises at least one detector according to the present invention, such as according to one or more of the embodiments disclosed above and/or according to one or more of the embodiments as disclosed in further detail below, wherein the human-machine interface is designed to generate at least one item of geometrical information of the user by means of the detector wherein the human-machine interface is designed to assign the geometrical information to at least one item of information, in particular to at least one control command.

In a further aspect of the present invention, an entertainment device for carrying out at least one entertainment function is disclosed. As used herein, an entertainment device is a device which may serve the purpose of leisure and/or entertainment of one or more users, in the following also referred to as one or more players. As an example, the entertainment device may serve the purpose of gaming, preferably computer gaming. Additionally or alternatively, the entertainment device may also be used for other purposes, such as for exercising, sports, physical therapy or motion tracking in general. Thus, the entertainment device may be implemented into a computer, a computer network or a computer system or may comprise a computer, a computer network or a computer system which runs one or more gaming software programs.

The entertainment device comprises at least one human-machine interface according to the present invention, such as according to one or more of the embodiments disclosed above and/or according to one or more of the embodiments disclosed below. The entertainment device is designed to enable at least one item of information to be input by a player by means of the human-machine interface. The at least one item of information may be transmitted to and/or may be used by a controller and/or a computer of the entertainment device.

In a further aspect of the present invention, a tracking system for tracking the position of at least one movable object is provided. As used herein, a tracking system is a device which is adapted to gather information on a series of past positions of the at least one object or at least one part of an object. Additionally, the tracking system may be adapted to provide information on at least one predicted future position of the at least one object or the at least one part of the object. The tracking system may have at least one track controller, which may fully or partially be embodied as an electronic device, preferably as at least one data processing device, more preferably as at least one computer or microcontroller. Again, the at least one track controller may comprise the at least one evaluation device and/or may be part of the at least one evaluation device and/or might fully or partially be identical to the at least one evaluation device.

The tracking system comprises at least one detector according to the present invention, such as at least one detector as disclosed in one or more of the embodiments listed above and/or as disclosed in one or more of the embodiments below. The tracking system further comprises at least one track controller. The tracking system may comprise one, two or more detectors, particularly two or more identical detectors, which allow for a reliable acquisition of depth information about the at least one object in an overlapping volume between the two or more detectors. The track controller is adapted to track a series of positions of the object, each position comprising at least one item of information on a position of the object at a specific point in time.

The tracking system may further comprise at least one beacon device connectable to the object. For a potential definition of the beacon device, reference may be made to WO 2014/097181 A1. The tracking system preferably is adapted such that the detector may generate an information on the position of the object of the at least one beacon device, in particular to generate the information on the position of the object which comprises a specific beacon device exhibiting a specific spectral sensitivity. Thus, more than one beacon exhibiting a different spectral sensitivity may be tracked by the detector of the present invention, preferably in a simultaneous manner. Herein, the beacon device may fully or partially be embodied as an active beacon device and/or as a passive beacon device. As an example, the beacon device may comprise at least one illumination source adapted to generate at least one light beam to be transmitted to the detector. Additionally or alternatively, the beacon device may comprise at least one reflector adapted to reflect light generated by an illumination source, thereby generating a reflected light beam to be transmitted to the detector.

In a further aspect of the present invention, a scanning system for determining at least one position of at least one object is provided. As used herein, the scanning system is a device which is adapted to emit at least one light beam being configured for an illumination of at least one dot located at at least one surface of the at least one object and for generating at least one item of information about the distance between the at least one dot and the scanning system. For the purpose of generating the at least one item of information about the distance between the at least one dot and the scanning system, the scanning system comprises at least one of the detectors according to the present invention, such as at least one of the detectors as disclosed in one or more of the embodiments listed above and/or as disclosed in one or more of the embodiments below.

Thus, the scanning system comprises at least one illumination source which is adapted to emit the at least one light beam being configured for the illumination of the at least one dot located at the at least one surface of the at least one object. As used herein, the term “dot” refers to a small area on a part of the surface of the object which may be selected, for example by a user of the scanning system, to be illuminated by the illumination source. Preferably, the dot may exhibit a size which may, on one hand, be as small as possible in order to allow the scanning system determining a value for the distance between the illumination source comprised by the scanning system and the part of the surface of the object on which the dot may be located as exactly as possible and which, on the other hand, may be as large as possible in order to allow the user of the scanning system or the scanning system itself, in particular by an automatic procedure, to detect a presence of the dot on the related part of the surface of the object.

For this purpose, the illumination source may comprise an artificial illumination source, in particular at least one laser source and/or at least one incandescent lamp and/or at least one semiconductor light source, for example, at least one light-emitting diode, in particular an organic and/or inorganic light-emitting diode. On account of their generally defined beam profiles and other properties of handleability, the use of at least one laser source as the illumination source is particularly preferred. Herein, the use of a single laser source may be preferred, in particular in a case in which it may be important to provide a compact scanning system that might be easily storable and transportable by the user. The illumination source may thus, preferably be a constituent part of the detector and may, therefore, in particular be integrated into the detector, such as into the housing of the detector. In a preferred embodiment, particularly the housing of the scanning system may comprise at least one display configured for providing distance-related information to the user, such as in an easy-to-read manner. In a further preferred embodiment, particularly the housing of the scanning system may, in addition, comprise at least one button which may be configured for operating at least one function related to the scanning system, such as for setting one or more operation modes. In a further preferred embodiment, particularly the housing of the scanning system may, in addition, comprise at least one fastening unit which may be configured for fastening the scanning system to a further surface, such as a rubber foot, a base plate or a wall holder, such comprising as magnetic material, in particular for increasing the accuracy of the distance measurement and/or the handleablity of the scanning system by the user.

In a particularly preferred embodiment, the illumination source of the scanning system may, thus, emit a single laser beam which may be configured for the illumination of a single dot located at the surface of the object. By using at least one of the detectors according to the present invention at least one item of information about the distance between the at least one dot and the scanning system may, thus, be generated. Hereby, preferably, the distance between the illumination system as comprised by the scanning system and the single dot as generated by the illumination source may be determined, such as by employing the evaluation device as comprised by the at least one detector. However, the scanning system may, further, comprise an additional evaluation system which may, particularly, be adapted for this purpose. Alternatively or in addition, a size of the scanning system, in particular of the housing of the scanning system, may be taken into account and, thus, the distance between a specific point on the housing of the scanning system, such as a front edge or a back edge of the housing, and the single dot may, alternatively, be determined.

Alternatively, the illumination source of the scanning system may emit two individual laser beams which may be configured for providing a respective angle, such as a right angle, between the directions of an emission of the beams, whereby two respective dots located at the surface of the same object or at two different surfaces at two separate objects may be illuminated. However, other values for the respective angle between the two individual laser beams may also be feasible. This feature may, in particular, be employed for indirect measuring functions, such as for deriving an indirect distance which may not be directly accessible, such as due to a presence of one or more obstacles between the scanning system and the dot or which may otherwise be hard to reach. By way of example, it may, thus, be feasible to determine a value for a height of an object by measuring two individual distances and deriving the height by using the Pythagoras formula. In particular for being able to keep a predefined level with respect to the object, the scanning system may, further, comprise at least one leveling unit, in particular an integrated bubble vial, which may be used for keeping the predefined level by the user.

As a further alternative, the illumination source of the scanning system may emit a plurality of individual laser beams, such as an array of laser beams which may exhibit a respective pitch, in particular a regular pitch, with respect to each other and which may be arranged in a manner in order to generate an array of dots located on the at least one surface of the at least one object. For this purpose, specially adapted optical elements, such as beam-splitting devices and mirrors, may be provided which may allow a generation of the described array of the laser beams.

Thus, the scanning system may provide a static arrangement of the one or more dots placed on the one or more surfaces of the one or more objects. Alternatively, illumination source of the scanning system, in particular the one or more laser beams, such as the above described array of the laser beams, may be configured for providing one or more light beams which may exhibit a varying intensity over time and/or which may be subject to an alternating direction of emission in a passage of time. Thus, the illumination source may be configured for scanning a part of the at least one surface of the at least one object as an image by using one or more light beams with alternating features as generated by the at least one illumination source of the scanning device. In particular, the scanning system may, thus, use at least one row scan and/or line scan, such as to scan the one or more surfaces of the one or more objects sequentially or simultaneously.

In a further aspect of the present invention, a stereoscopic system for generating at least one single circular, three-dimensional image of at least one object is provided. As used herein, the stereoscopic system as disclosed above and/or below may comprise at least two of the FiP sensors as the optical sensors, wherein a first FiP sensor may be comprised in a tracking system, in particular in a tracking system according to the present invention, while a second FiP sensor may be comprised in a scanning system, in particular in a scanning system according to the present invention. Herein, the FiP sensors may, preferably, be arranged in separate beam paths in a collimated arrangement, such as by aligning the FiP sensors parallel to the optical axis and individually displaced perpendicular to the optical axis of the stereoscopic system. Thus, the FiP sensors may be able to generate or increase a perception of depth information, especially, by obtaining the depth information by a combination of the visual information derived from the individual FiP sensors which have overlapping fields of view and are, preferably, sensitive to an individual modulation frequency. For this purpose, the individual FiP sensors may, preferably, be spaced apart from each other by a distance from 1 cm to 100 cm, preferably from 10 cm to 25 cm, as determined in the direction perpendicular to the optical axis. In this preferred embodiment, the tracking system may, thus, be employed for determining a position of a modulated active target while the scanning system which is adapted to project one or more dots onto the one or more surfaces of the one or more objects may be used for generating at least one item of information about the distance between the at least one dot and the scanning system. In addition, the stereoscopic system may further comprise a separate position sensitive device being adapted for generating the item of information on the transversal position of the at least one object within the image as described elsewhere in this application.

Besides allowing stereoscopic vision, further particular advantages of the stereoscopic system which are primarily based on a use of more than one optical sensor may, in particular, include an increase of the total intensity and/or a lower detection threshold. Further, whereas in a conventional stereoscopic system which comprises at least two conventional position sensitive devices corresponding pixels in the respective images have to be determined by applying considerable computational effort, in the stereoscopic system according to the present invention which comprises at least two FiP sensors the corresponding pixels in the respective images being recorded by using the FiP sensors, wherein each of the FiP sensors may be operated with a different modulation frequency, may apparently be assigned with respect to each other. Thus, it may be emphasized that the stereoscopic system according to the present invention may allow generating the at least one item of information on the longitudinal position of the object as well as on the transversal position of the object with reduced effort.

For further details of the stereoscopic system, reference may be made to the description of the tracking system and the scanning system, respectively.

In a further aspect of the present invention, a camera for imaging at least one object is disclosed. The camera comprises at least one detector according to the present invention, such as disclosed in one or more of the embodiments given above or given in further detail below. Thus, the detector may be part of a photographic device, specifically of a digital camera. Specifically, the detector may be used for 3D photography, specifically for digital 3D photography. Thus, the detector may form a digital 3D camera or may be part of a digital 3D camera. As used herein, the term “photography” generally refers to the technology of acquiring image information of at least one object. As further used herein, a “camera” generally is a device adapted for performing photography. As further used herein, the term “digital photography” generally refers to the technology of acquiring image information of at least one object by using a plurality of light-sensitive elements adapted to generate electrical signals indicating an intensity of illumination, preferably digital electrical signals. As further used herein, the term “3D photography” generally refers to the technology of acquiring image information of at least one object in three spatial dimensions. Accordingly, a 3D camera is a device adapted for performing 3D photography. The camera generally may be adapted for acquiring a single image, such as a single 3D image, or may be adapted for acquiring a plurality of images, such as a sequence of images. Thus, the camera may also be a video camera adapted for video applications, such as for acquiring digital video sequences.

Thus, generally, the present invention further refers to a camera, specifically a digital camera, more specifically a 3D camera or digital 3D camera, for imaging at least one object. As outlined above, the term imaging, as used herein, generally refers to acquiring image information of at least one object. The camera comprises at least one detector according to the present invention. The camera, as outlined above, may be adapted for acquiring a single image or for acquiring a plurality of images, such as image sequence, preferably for acquiring digital video sequences. Thus, as an example, the camera may be or may comprise a video camera. In the latter case, the camera preferably comprises a data memory for storing the image sequence.

In a further aspect of the present invention, a method for determining a position of at least one object is disclosed. The method preferably may make use of at least one detector according to the present invention, such as of at least one detector according to one or more of the embodiments disclosed above or disclosed in further detail below. Thus, for optional embodiments of the method, reference might be made to the description of the various embodiments of the detector.

The method comprises the following steps, which may be performed in the given order or in a different order. Further, additional method steps might be provided which are not listed. Further, two or more or even all of the method steps might be performed simultaneously, at least partially. Further, two or more or even all of the method steps might be performed twice or even more than twice, repeatedly.

The method according to the present invention comprises the following steps:
generating at least one longitudinal sensor signal by using at least one longitudinal optical sensor, wherein the longitudinal optical sensor has at least two individual pin diodes arranged between at least two electrodes, wherein at least one of the pin diodes is designated as a sensor region for an incident light beam, wherein the sensor region is designated to generate at least one longitudinal sensor signal in a manner dependent on an illumination of the sensor region by the light beam, wherein the longitudinal sensor signal, given the same total power of the illumination, is dependent on a beam cross- section of the light beam in the sensor region; and
generating at least one item of information on a longitudinal position of the object by evaluating the longitudinal sensor signal of the longitudinal optical sensor.

For further details concerning the method according to the present invention, reference may be made to the description of the optical detector as provided above and/or below.

In a further aspect of the present invention, a use of a detector according to the present invention is disclosed. Therein, a use of the detector for a purpose of determining a position, in particular a depth, of an object is proposed, in particular, for a purpose of use selected from the group consisting of: a distance measurement, in particular in traffic technology; a position measurement, in particular in traffic technology; an entertainment application; a security application; a human-machine interface application; a tracking application; a scanning application; a stereoscopic vision application; a photography application; an imaging application or camera application; a mapping application for generating maps of at least one space; a homing or tracking beacon detector for vehicles; a distance and/or position measurement of objects with a thermal signature (hotter or colder than background); a machine vision application; a robotic application.

Specifically, the optical detector according to the present invention may, particularly depending on the kind of material selected for the corresponding sensor region, be used as an optical detector for electromagnetic waves over a considerably wide spectral range. Within this regard, the ultraviolet (UV), visible, near infrared (NIR), infrared (IR), far infrared (FIR) spectral range may particularly be preferred. As non-limiting examples, the following kinds of materials may, particularly, be selected:
doped diamond (C), zinc oxide (ZnO), titanium oxide (TiO₂), gallium nitride (GaN), gallium phosphide (GaP) or silicon carbide (SiC) for the UV spectral range;
silicon (Si), gallium arsenide (GaAs), cadmium sulfide (CdS), cadmium telluride (CdTe), copper indium sulfide (CulnS₂; CIS), copper indium gallium selenide (CIGS), copper zinc tin sulfide (CZTS), quantum dots comprising lead sulfide (PbS), indium phosphide (InP), or an organic materials as described above for the visible spectral range;
indium gallium arsenide (InGaAs), silicon (Si), germanium (Ge), cadmium telluride (CdTe), copper indium sulfide (CulnS₂; CIS), copper indium gallium selenide (CIGS), copper zinc tin sulfide (CZTS), or quantum dots comprising lead sulfide (PbS) for the NIR spectral range, wherein CdTe, CIS, CIGS, and CZTS are particularly preferred for wavelengths above 850 nm;
lead sulfide (PbS) for the SWIR and MWIR spectral ranges; and
lead selenide (PbSe), mercury cadmium telluride (HgCdTe; MCT), indium antimonide (InSb), or indium arsenide (InAs) for the SWIR, MWIR, LWIR and FIR spectral ranges.

Further uses of the optical detector according to the present invention may also refer to combinations with applications for which optical detector have already been applied successfully, such as determining the presence or absence of an object; extending optical applications, e.g. camera exposure control, auto slide focus, automated rear view mirrors, electronic scales, automatic gain control, particularly in modulated light sources, automatic headlight dimmers, night (street) light controls, oil burner flame outs, or smoke detectors; or other applications, such as in densitometers, e.g. determining the density of toner in photocopy machines; or in colorimetric measurements.

Thus, generally, the devices according to the present invention, such as the detector, may be applied in various fields of uses. Specifically, the detector may be applied for a purpose of use, selected from the group consisting of: a position measurement in traffic technology; an entertainment application; a security application; a human-machine interface application; a tracking application; a photography application; a mapping application for generating maps of at least one space, such as at least one space selected from the group of a room, a building and a street; a mobile application; a webcam; an audio device; a dolby surround audio system; a computer peripheral device; a gaming application; a camera or video application; a security application; a surveillance application; an automotive application; a transport application; a medical application; a sports' application; a machine vision application; a vehicle application; an airplane application; a ship application; a spacecraft application; a building application; a construction application; a cartography application; a manufacturing application; a use in combination with at least one state-of-the-art sensing technology, such as a time-of-flight detector, radar, lidar, ultrasonic sensors, or interferometry. Additionally or alternatively, applications in local and/or global positioning systems may be named, especially landmark- based positioning and/or navigation, specifically for use in cars or other vehicles (such as trains, motorcycles, bicycles, trucks for cargo transportation), robots or for use by pedestrians. Further, indoor positioning systems may be named as potential applications, such as for household applications and/or for robots used in manufacturing, logistics, surveillance, or maintenance technology.

Thus, firstly, the devices according to the present invention may be used in mobile phones, tablet computers, laptops, smart panels or other stationary or mobile or wearable computer or communication applications. Thus, the devices according to the present invention may be combined with at least one active light source, such as a light source emitting light in the visible range or infrared spectral range, in order to enhance performance. Thus, as an example, the devices according to the present invention may be used as cameras and/or sensors, such as in combination with mobile software for scanning and/or detecting environment, objects and living beings. The devices according to the present invention may even be combined with 2D cameras, such as conventional cameras, in order to increase imaging effects. The devices according to the present invention may further be used for surveillance and/or for recording purposes or as input devices to control mobile devices, especially in combination with voice and/or gesture recognition. Thus, specifically, the devices according to the present invention acting as human-machine interfaces, also referred to as input devices, may be used in mobile applications, such as for controlling other electronic devices or components via the mobile device, such as the mobile phone. As an example, the mobile application including at least one device according to the present invention may be used for controlling a television set, a game console, a music player or music device or other entertainment devices.

Further, the devices according to the present invention may be used in webcams or other peripheral devices for computing applications. Thus, as an example, the devices according to the present invention may be used in combination with software for imaging, recording, surveillance, scanning, or motion detection. As outlined in the context of the human-machine interface and/or the entertainment device, the devices according to the present invention are particularly useful for giving commands by facial expressions and/or body expressions. The devices according to the present invention can be combined with other input generating devices like e.g. mouse, keyboard, touchpad, microphone etc. Further, the devices according to the present invention may be used in applications for gaming, such as by using a webcam. Further, the devices according to the present invention may be used in virtual training applications and/or video conferences. Further, devices according to the present invention may be used to recognize or track hands, arms, or objects used in a virtual or augmented reality application, especially when wearing head mounted displays.

Further, the devices according to the present invention may be used in mobile audio devices, television devices and gaming devices, as partially explained above. Specifically, the devices according to the present invention may be used as controls or control devices for electronic devices, entertainment devices or the like. Further, the devices according to the present invention may be used for eye detection or eye tracking, such as in 2D- and 3D-display techniques, especially with transparent displays for augmented reality applications and/or for recognizing whether a display is being looked at and/or from which perspective a display is being looked at. Further, devices according to the present invention may be used to explore a room, boundaries, obstacles, in connection with a virtual or augmented reality application, especially when wearing a head-mounted display.

Further, the devices according to the present invention may be used in or as digital cameras such as DSC cameras and/or in or as reflex cameras such as SLR cameras. For these applications, reference may be made to the use of the devices according to the present invention in mobile applications such as mobile phones, as disclosed above.

Further, the devices according to the present invention may be used for security or surveillance applications. Thus, as an example, at least one device according to the present invention can be combined with one or more digital and/or analogue electronics that will give a signal if an object is within or outside a predetermined area (e.g. for surveillance applications in banks or museums). Specifically, the devices according to the present invention may be used for optical encryption. Detection by using at least one device according to the present invention can be combined with other detection devices to complement wavelengths, such as with IR, x-ray, UV-VIS, radar or ultrasound detectors. The devices according to the present invention may further be combined with an active infrared light source to allow detection in low light surroundings. The devices according to the present invention are generally advantageous as compared to active detector systems, specifically since the devices according to the present invention avoid actively sending signals which may be detected by third parties, as is the case e.g. in radar applications, ultrasound applications, LIDAR or similar active detector devices. Thus, generally, the devices according to the present invention may be used for an unrecognized and undetectable tracking of moving objects. Additionally, the devices according to the present invention generally are less prone to manipulations and irritations as compared to conventional devices.

Further, given the ease and accuracy of 3D detection by using the devices according to the present invention, the devices according to the present invention generally may be used for facial, body and person recognition and identification. Therein, the devices according to the present invention may be combined with other detection means for identification or personalization purposes such as passwords, finger prints, iris detection, voice recognition or other means. Thus, generally, the devices according to the present invention may be used in security devices and other personalized applications.

Further, the devices according to the present invention may be used as 3D barcode readers for product identification.

In addition to the security and surveillance applications mentioned above, the devices according to the present invention generally can be used for surveillance and monitoring of spaces and areas. Thus, the devices according to the present invention may be used for surveying and monitoring spaces and areas and, as an example, for triggering or executing alarms in case prohibited areas are violated. Thus, generally, the devices according to the present invention may be used for surveillance purposes in building surveillance or museums, optionally in combination with other types of sensors, such as in combination with motion or heat sensors, in combination with image intensifiers or image enhancement devices and/or photomultipliers. Further, the devices according to the present invention may be used in public spaces or crowded spaces to detect potentially hazardous activities such as commitment of crimes such as theft in a parking lot or unattended objects such as unattended baggage in an airport.

Further, the devices according to the present invention may advantageously be applied in camera applications such as video and camcorder applications. Thus, the devices according to the present invention may be used for motion capture and 3D-movie recording. Therein, the devices according to the present invention generally provide a large number of advantages over conventional optical devices. Thus, the devices according to the present invention generally require a lower complexity with regard to optical components. Thus, as an example, the number of lenses may be reduced as compared to conventional optical devices, such as by providing the devices according to the present invention having one lens only. Due to the reduced complexity, very compact devices are possible, such as for mobile use. Conventional optical systems having two or more lenses with high quality generally are voluminous, such as due to the general need for voluminous beam-splitters. Further, the devices according to the present invention generally may be used for focus/autofocus devices, such as autofocus cameras. Further, the devices according to the present invention may also be used in optical microscopy, especially in confocal microscopy.

Further, the devices according to the present invention generally are applicable in the technical field of automotive technology and transport technology. Thus, as an example, the devices according to the present invention may be used as distance and surveillance sensors, such as for adaptive cruise control, emergency brake assist, lane departure warning, surround view, blind spot detection, traffic sign detection, traffic sign recognition, lane recognition, rear cross traffic alert, light source recognition for adapting the head light intensity and range depending on approaching traffic or vehicles driving ahead, adaptive front-lighting systems, automatic control of high beam head lights, adaptive cut-off lights in front light systems, glare-free high beam front lighting systems, marking animals, obstacles, or the like by headlight illumination, rear cross traffic alert, and other driver assistance systems, such as advanced driver assistance systems, or other automotive and traffic applications. Further, devices according to the present invention may be used in driver assistance systems which may, particularly, be adapted for anticipating maneuvers of the driver beforehand for collision avoidance. Further, the devices according to the present invention can also be used for velocity and/or acceleration measurements, such as by analyzing a first and second time-derivative of position information gained by using the detector according to the present invention. This feature generally may be applicable in automotive technology, transportation technology or general traffic technology. Applications in other fields of technology are feasible. A specific application in an indoor positioning system may be the detection of positioning of passengers in transportation, more specifically to electronically control the use of safety systems such as airbags. Herein, the use of an airbag may, especially, be prevented in a case in which the passenger may be located within the vehicle in a manner that a use of the airbag might cause an injury, in particular a severe injury, with the passenger. Further, in vehicles such as cars, trains, planes or the like, especially in autonomous vehicles, devices according to the present invention may be used to determine whether a driver pays attention to the traffic or is distracted, or asleep, or tired, or incapable of driving, such as due to the consumption of alcohol or other drugs.

In these or other applications, generally, the devices according to the present invention may be used as standalone devices or in combination with other sensor devices, such as in combination with radar and/or ultrasonic devices. Specifically, the devices according to the present invention may be used for autonomous driving and safety issues. Further, in these applications, the devices according to the present invention may be used in combination with infrared sensors, radar sensors, which are sonic sensors, two-dimensional cameras or other types of sensors. In these applications, the generally passive nature of the devices according to the present invention is advantageous. Thus, since the devices according to the present invention generally do not require emitting signals, the risk of interference of active sensor signals with other signal sources may be avoided. The devices according to the present invention specifically may be used in combination with recognition software, such as standard image recognition software. Thus, signals and data as provided by the devices according to the present invention typically are readily processable and, therefore, generally require lower calculation power than established stereovision systems such as LI DAR. Given the low space demand, the devices according to the present invention such as cameras may be placed at virtually any place in a vehicle, such as on or behind a window screen, on a front hood, on bumpers, on lights, on mirrors or other places and the like. Various detectors according to the present invention such as one or more detectors based on the effect disclosed within the present invention can be combined, such as in order to allow autonomously driving vehicles or in order to increase the performance of active safety concepts. Thus, various devices according to the present invention may be combined with one or more other devices according to the present invention and/or conventional sensors, such as in the windows like rear window, side window or front window, on the bumpers or on the lights.

A combination of at least one device according to the present invention such as at least one detector according to the present invention with one or more rain detection sensors is also possible. This is due to the fact that the devices according to the present invention generally are advantageous over conventional sensor techniques such as radar, specifically during heavy rain. A combination of at least one device according to the present invention with at least one conventional sensing technique such as radar may allow for a software to pick the right combination of signals according to the weather conditions.

Further, the devices according to the present invention may generally be used as break assist and/or parking assist and/or for speed measurements. Speed measurements can be integrated in the vehicle or may be used outside the vehicle, such as in order to measure the speed of other cars in traffic control. Further, the devices according to the present invention may be used for detecting free parking spaces in parking lots.

Further, the devices according to the present invention may generally be used for vision, in particular for vision under difficult visibility conditions, such as in night vision, fog vision, or fume vision. For achieving this purpose, the optical detector may comprise a specifically selected optical sensor which may be sensitive at least within a wavelength range in which small particles, such as particles being present in smoke or fume, or small droplets, such as droplets being present in fog, mist or haze, may not reflect an incident light beam or only a small partition thereof. As generally know, the reflection of the incident light beam may be small or negligent in a case in which the wavelength of the incident beam exceeds the size of the particles or of the droplets, respectively. Further, might vision may be enabled by detecting thermal radiation being emitted by a bodies and objects. Thus, the optical detector which comprises the specifically selected material in the sensor region which may particularly be sensitive within the infrared (IR) spectral range, preferably within the near infrared (NIR) spectral range, may, thus, allow good visibility even at night, in fume, smoke, fog, mist, or haze.

Further, the devices according to the present invention may be used in the fields of medical systems and sports. Thus, in the field of medical technology, surgery robotics, e.g. for use in endoscopes, may be named, since, as outlined above, the devices according to the present invention may require a low volume only and may be integrated into other devices. Specifically, the devices according to the present invention having one lens, at most, may be used for capturing 3D information in medical devices such as in endoscopes. Further, the devices according to the present invention may be combined with an appropriate monitoring software, in order to enable tracking and analysis of movements. This may allow an instant overlay of the position of a medical device, such as an endoscope or a scalpel, with results from medical imaging, such as obtained from magnetic resonance imaging, x-ray imaging, or ultrasound imaging. These applications are specifically valuable e.g. in medical treatments where precise location information is important such as in brain surgery and long-distance diagnosis and tele-medicine. Further, the devices according to the present invention may be used in 3D-body scanning. Body scanning may be applied in a medical context, such as in dental surgery, plastic surgery, bariatric surgery, or cosmetic plastic surgery, or it may be applied in the context of medical diagnosis such as in the diagnosis of myofascial pain syndrome, cancer, body dysmorphic disorder, or further diseases. Body scanning may further be applied in the field of sports to assess ergonomic use or fit of sports equipment.

Body scanning may further be used in the context of clothing, such as to determine a suitable size and fitting of clothes. This technology may be used in the context of tailor-made clothes or in the context of ordering clothes or shoes from the internet or at a self-service shopping device such as a micro kiosk device or customer concierge device. Body scanning in the context of clothing is especially important for scanning fully dressed customers.

Further, the devices according to the present invention may be used in the context of people counting systems, such as to count the number of people in an elevator, a train, a bus, a car, or a plane, or to count the number of people passing a hallway, a door, an aisle, a retail store, a stadium, an entertainment venue, a museum, a library, a public location, a cinema, a theater, or the like. Further, the 3D-function in the people counting system may be used to obtain or estimate further information about the people that are counted such as height, weight, age, physical fitness, or the like. This information may be used for business intelligence metrics, and/or for further optimizing the locality where people may be counted to make it more attractive or safe. In a retail environment, the devices according to the present invention in the context of people counting may be used to recognize returning customers or cross shoppers, to assess shopping behavior, to assess the percentage of visitors that make purchases, to optimize staff shifts, or to monitor the costs of a shopping mall per visitor. Further, people counting systems may be used for anthropometric surveys. Further, the devices according to the present invention may be used in public transportation systems for automatically charging passengers depending on the length of transport. Further, the devices according to the present invention may be used in playgrounds for children, to recognize injured children or children engaged in dangerous activities, to allow additional interaction with playground toys, to ensure safe use of playground toys or the like.

Further, the devices according to the present invention may be used in construction tools, such as a range meter that determines the distance to an object or to a wall, to assess whether a surface is planar, to align or objects or place objects in an ordered manner, or in inspection cameras for use in construction environments or the like.

Further, the devices according to the present invention may be applied in the field of sports and exercising, such as for training, remote instructions or competition purposes. Specifically, the devices according to the present invention may be applied in the fields of dancing, aerobic, football, soccer, basketball, baseball, cricket, hockey, track and field, swimming, polo, handball, volleyball, rugby, sumo, judo, fencing, boxing, golf, car racing, laser tag, battlefield simulation etc. The devices according to the present invention can be used to detect the position of a ball, a bat, a sword, motions, etc., both in sports and in games, such as to monitor the game, support the referee or for judgment, specifically automatic judgment, of specific situations in sports, such as for judging whether a point or a goal actually was made.

Further, the devices according to the present invention may be used in the field of auto racing or car driver training or car safety training or the like to determine the position of a car or the track of a car, or the deviation from a previous track or an ideal track or the like.

The devices according to the present invention may further be used to support a practice of musical instruments, in particular remote lessons, for example lessons of string instruments, such as fiddles, violins, violas, celli, basses, harps, guitars, banjos, or ukuleles, keyboard instruments, such as pianos, organs, keyboards, harpsichords, harmoniums, or accordions, and/or percussion instruments, such as drums, timpani, marimbas, xylophones, vibraphones, bongos, congas, timbales, djembes or tablas.

The devices according to the present invention further may be used in rehabilitation and physiotherapy, in order to encourage training and/or in order to survey and correct movements. Therein, the devices according to the present invention may also be applied for distance diagnostics.

Further, the devices according to the present invention may be applied in the field of machine vision. Thus, one or more of the devices according to the present invention may be used e.g. as a passive controlling unit for autonomous driving and or working of robots. In combination with moving robots, the devices according to the present invention may allow for autonomous movement and/or autonomous detection of failures in parts. The devices according to the present invention may also be used for manufacturing and safety surveillance, such as in order to avoid accidents including but not limited to collisions between robots, production parts and living beings. In robotics, the safe and direct interaction of humans and robots is often an issue, as robots may severely injure humans when they are not recognized. Devices according to the present invention may help robots to position objects and humans better and faster and allow a safe interaction. Given the passive nature of the devices according to the present invention, the devices according to the present invention may be advantageous over active devices and/or may be used complementary to existing solutions like radar, ultrasound, 2D cameras, IR detection etc. One particular advantage of the devices according to the present invention is the low likelihood of signal interference. Therefore multiple sensors can work at the same time in the same environment, without the risk of signal interference. Thus, the devices according to the present invention generally may be useful in highly automated production environments like e.g. but not limited to automotive, mining, steel, etc. The devices according to the present invention can also be used for quality control in production, e.g. in combination with other sensors like 2-D imaging, radar, ultrasound, IR etc., such as for quality control or other purposes. Further, the devices according to the present invention may be used for assessment of surface quality, such as for surveying the surface evenness of a product or the adherence to specified dimensions, from the range of micrometers to the range of meters. Other quality control applications are feasible. In a manufacturing environment, the devices according to the present invention are especially useful for processing natural products such as food or wood, with a complex 3-dimensional structure to avoid large amounts of waste material. Further, devices according to the present invention may be used to monitor the filling level of tanks, silos etc. Further, devices according to the present invention may be used to inspect complex products for missing parts, incomplete parts, loose parts, low quality parts, or the like, such as in automatic optical inspection, such as of printed circuit boards, inspection of assemblies or sub-assemblies, verification of engineered components, engine part inspections, wood quality inspection, label inspections, inspection of medical devices, inspection of product orientations, packaging inspections, food pack inspections, or the like.

Further, the devices according to the present invention may be used in vehicles, trains, airplanes, ships, spacecraft and other traffic applications. Thus, besides the applications mentioned above in the context of traffic applications, passive tracking systems for aircraft, vehicles and the like may be named. The use of at least one device according to the present invention, such as at least one detector according to the present invention, for monitoring the speed and/or the direction of moving objects is feasible. Specifically, the tracking of fast moving objects on land, sea and in the air including space may be named. The at least one device according to the present invention, such as the at least one detector according to the present invention, specifically may be mounted on a still-standing and/or on a moving device. An output signal of the at least one device according to the present invention can be combined e.g. with a guiding mechanism for autonomous or guided movement of another object. Thus, applications for avoiding collisions or for enabling collisions between the tracked and the steered object are feasible. The devices according to the present invention generally are useful and advantageous due to the low calculation power required, the instant response and due to the passive nature of the detection system which generally is more difficult to detect and to disturb as compared to active systems, like e.g. radar. The devices according to the present invention are particularly useful but not limited to e.g. speed control and air traffic control devices. Further, the devices according to the present invention may be used in automated tolling systems for road charges.

The devices according to the present invention may, generally, be used in passive applications. Passive applications include guidance for ships in harbors or in dangerous areas, and for aircraft when landing or starting. Wherein, fixed, known active targets may be used for precise guidance. The same can be used for vehicles driving on dangerous but well defined routes, such as mining vehicles. Further, the devices according to the present invention may be used to detect rapidly approaching objects, such as cars, trains, flying objects, animals, or the like. Further, the devices according to the present invention can be used for detecting velocities or accelerations of objects, or to predict the movement of an object by tracking one or more of its position, speed, and/or acceleration depending on time.

Further, as outlined above, the devices according to the present invention may be used in the field of gaming. Thus, the devices according to the present invention can be passive for use with multiple objects of the same or of different size, color, shape, etc., such as for movement detection in combination with software that incorporates the movement into its content. In particular, applications are feasible in implementing movements into graphical output. Further, applications of the devices according to the present invention for giving commands are feasible, such as by using one or more of the devices according to the present invention for gesture or facial recognition. The devices according to the present invention may be combined with an active system in order to work under e.g. low light conditions or in other situations in which enhancement of the surrounding conditions is required. Additionally or alternatively, a combination of one or more devices according to the present invention with one or more IR or VIS light sources is possible. A combination of a detector according to the present invention with special devices is also possible, which can be distinguished easily by the system and its software, e.g. and not limited to, a special color, shape, relative position to other devices, speed of movement, light, frequency used to modulate light sources on the device, surface properties, material used, reflection properties, transparency degree, absorption characteristics, etc. The device can, amongst other possibilities, resemble a stick, a racquet, a club, a gun, a knife, a wheel, a ring, a steering wheel, a bottle, a ball, a glass, a vase, a spoon, a fork, a cube, a dice, a figure, a puppet, a teddy, a beaker, a pedal, a switch, a glove, jewelry, a musical instrument or an auxiliary device for playing a musical instrument, such as a plectrum, a drumstick or the like. Other options are feasible.

Further, the devices according to the present invention may be used to detect and or track objects that emit light by themselves, such as due to high temperature or further light emission processes. The light emitting part may be an exhaust stream or the like. Further, the devices according to the present invention may be used to track reflecting objects and analyze the rotation or orientation of these objects.

Further, the devices according to the present invention may generally be used in the field of building, construction and cartography. Thus, generally, one or more devices according to the present invention may be used in order to measure and/or monitor environmental areas, e.g. countryside or buildings. Therein, one or more devices according to the present invention may be combined with other methods and devices or can be used solely in order to monitor progress and accuracy of building projects, changing objects, houses, etc. The devices according to the present invention can be used for generating three-dimensional models of scanned environments, in order to construct maps of rooms, streets, houses, communities or landscapes, both from ground or air. Potential fields of application may be construction, cartography, real estate management, land surveying or the like. As an example, the devices according to the present invention may be used in vehicles capable of flight, such as drones or multicopters, in order to monitor buildings, chimneys, production sites, agricultural production environments such as fields, production plants, or landscapes, to support rescue operations, to support work in dangerous environments, to support fire brigades in a burning location indoors or outdoors, to find or monitor one or more persons, animals, or moving objects, or for entertainment purposes, such as a drone following and recording one or more persons doing sports such as skiing or cycling or the like, which could be realized by following a helmet, a mark, a beacon device, or the like. Devices according to the present invention could be used recognize obstacles, follow a predefined route, follow an edge, a pipe, a building, or the like, or to record a global or local map of the environment. Further, devices according to the present invention could be used for indoor or outdoor localization and positioning of drones, for stabilizing the height of a drone indoors where barometric pressure sensors are not accurate enough, or for the interaction of multiple drones such as concertized movements of several drones or recharging or refueling in the air or the like.

Further, the devices according to the present invention may be used within an interconnecting network of home appliances such as CHAIN (Cedec Home Appliances Interoperating Network) to interconnect, automate, and control basic appliance-related services in a home, e.g. energy or load management, remote diagnostics, pet related appliances, child related appliances, child surveillance, appliances related surveillance, support or service to elderly or ill persons, home security and/or surveillance, remote control of appliance operation, and automatic maintenance support. Further, the devices according to the present invention may be used in heating or cooling systems such as an air-conditioning system, to locate which part of the room should be brought to a certain temperature or humidity, especially depending on the location of one or more persons. Further, the devices according to the present invention may be used in domestic robots, such as service or autonomous robots which may be used for household chores. The devices according to the present invention may be used for a number of different purposes, such as to avoid collisions or to map the environment, but also to identify a user, to personalize the robot's performance for a given user, for security purposes, or for gesture or facial recognition. As an example, the devices according to the present invention may be used in robotic vacuum cleaners, floor-washing robots, dry-sweeping robots, ironing robots for ironing clothes, animal litter robots, such as cat litter robots, security robots that detect intruders, robotic lawn mowers, automated pool cleaners, rain gutter cleaning robots, window washing robots, toy robots, telepresence robots, social robots providing company to less mobile people, or robots translating and speech to sign language or sign language to speech. In the context of less mobile people, such as elderly persons, household robots with the devices according to the present invention may be used for picking up objects, transporting objects, and interacting with the objects and the user in a safe way. Further the devices according to the present invention may be used in robots operating with hazardous materials or objects or in dangerous environments. As a non-limiting example, the devices according to the present invention may be used in robots or unmanned remote-controlled vehicles to operate with hazardous materials such as chemicals or radioactive materials especially after disasters, or with other hazardous or potentially hazardous objects such as mines, unexploded arms, or the like, or to operate in or to investigate insecure environments such as near burning objects or post disaster areas, or for manned or unmanned rescue operations in the air, in the sea, underground, or the like.

Further, the devices according to the present invention may be used in household, mobile or entertainment devices, such as a refrigerator, a microwave, a washing machine, a window blind or shutter, a household alarm, an air condition devices, a heating device, a television, an audio device, a smart watch, a mobile phone, a phone, a dishwasher, a stove or the like, to detect the presence of a person, to monitor the contents or function of the device, or to interact with the person and/or share information about the person with further household, mobile or entertainment devices. Herein, the devices according to the present invention may be used to support elderly or disabled persons, blind persons, or persons with limited vision abilities, such as in household chores or at work such as in devices for holding, carrying, or picking objects, or in a safety system with optical and/or acoustical signals adapted for signaling obstacles in the environment.

The devices according to the present invention may further be used in agriculture, for example to detect and sort out vermin, weeds, and/or infected crop plants, fully or in parts, wherein crop plants may be infected by fungus or insects. Further, for harvesting crops, the devices according to the present invention may be used to detect animals, such as deer, which may otherwise be harmed by harvesting devices. Further, the devices according to the present invention may be used to monitor the growth of plants in a field or greenhouse, in particular to adjust the amount of water or fertilizer or crop protection products for a given region in the field or greenhouse or even for a given plant. Further, in agricultural biotechnology, the devices according to the present invention may be used to monitor the size and shape of plants.

Further, the devices according to the present invention may be combined with sensors to detect chemicals or pollutants, electronic nose chips, microbe sensor chips to detect bacteria or viruses or the like, Geiger counters, tactile sensors, heat sensors, or the like. This may for example be used in constructing smart robots which are configured for handling dangerous or difficult tasks, such as in treating highly infectious patients, handling or removing highly dangerous substances, cleaning highly polluted areas, such as highly radioactive areas or chemical spills, or for pest control in agriculture.

One or more devices according to the present invention can further be used for scanning of objects, such as in combination with CAD or similar software, such as for additive manufacturing and/or 3D printing. Therein, use may be made of the high dimensional accuracy of the devices according to the present invention, e.g. in x-, y- or z-direction or in any arbitrary combination of these directions, such as simultaneously. Within this regard, determining a distance of an illuminated spot on a surface which may provide reflected or diffusely scattered light from the detector may be performed virtually independent of the distance of the light source from the illuminated spot. This property of the present invention is in direct contrast to known methods, such as triangulation or such as time-of-flight (TOF) methods, wherein the distance between the light source and the illuminated spot must be known a priori or calculated a posteriori in order to be able to determine the distance between the detector and the illuminated spot. In contrast hereto, for the detector according to the present invention is may be sufficient that the spot is adequately illuminated. Further, the devices according to the present invention may be used for scanning reflective surfaces, such of metal surfaces, independent whether they may comprise a solid or a liquid surface. Further, the devices according to the present invention may be used in inspections and maintenance, such as pipeline inspection gauges. Further, in a production environment, the devices according to the present invention may be used to work with objects of a badly defined shape such as naturally grown objects, such as sorting vegetables or other natural products by shape or size or cutting products such as meat or objects that are manufactured with a precision that is lower than the precision needed for a processing step.

Further, the devices according to the present invention may be used in local navigation systems to allow autonomously or partially autonomously moving vehicles or multicopters or the like through an indoor or outdoor space. A non-limiting example may comprise vehicles moving through an automated storage for picking up objects and placing them at a different location.

Indoor navigation may further be used in shopping malls, retail stores, museums, airports, or train stations, to track the location of mobile goods, mobile devices, baggage, customers or employees, or to supply users with a location specific information, such as the current position on a map, or information on goods sold, or the like.

Further, the devices according to the present invention may be used to ensure safe driving of motorcycles, such as driving assistance for motorcycles by monitoring speed, inclination, upcoming obstacles, unevenness of the road, or curves or the like. Further, the devices according to the present invention may be used in trains or trams to avoid collisions.

Further, the devices according to the present invention may be used in handheld devices, such as for scanning packaging or parcels to optimize a logistics process. Further, the devices according to the present invention may be used in further handheld devices such as personal shopping devices, RFID-readers, handheld devices for use in hospitals or health environments such as for medical use or to obtain, exchange or record patient or patient health related information, smart badges for retail or health environments, or the like.

As outlined above, the devices according to the present invention may further be used in manufacturing, quality control or identification applications, such as in product identification or size identification (such as for finding an optimal place or package, for reducing waste etc.).

Further, the devices according to the present invention may be used in logistics applications. Thus, the devices according to the present invention may be used for optimized loading or packing containers or vehicles. Further, the devices according to the present invention may be used for monitoring or controlling of surface damages in the field of manufacturing, for monitoring or controlling rental objects such as rental vehicles, and/or for insurance applications, such as for assessment of damages. Further, the devices according to the present invention may be used for identifying a size of material, object or tools, such as for optimal material handling, especially in combination with robots. Further, the devices according to the present invention may be used for process control in production, e.g. for observing filling level of tanks. Further, the devices according to the present invention may be used for maintenance of production assets like, but not limited to, tanks, pipes, reactors, tools etc. Further, the devices according to the present invention may be used for analyzing 3D-quality marks. Further, the devices according to the present invention may be used in manufacturing tailor-made goods such as tooth inlays, dental braces, prosthesis, clothes or the like. The devices according to the present invention may also be combined with one or more 3D-printers for rapid prototyping, 3D-copying or the like. Further, the devices according to the present invention may be used for detecting the shape of one or more articles, such as for anti-product piracy and for anti- counterfeiting purposes.

Preferably, for further potential details of the optical detector, the method, the human-machine interface, the entertainment device, the tracking system, the camera and the various uses of the detector, in particular with regard to the transfer device, the longitudinal optical sensors, the evaluation device and, if applicable, to the transversal optical sensor, the modulation device, the illumination source and the imaging device, specifically with respect to the potential materials, setups and further details, reference may be made to one or more of WO 2012/110924 A1, US 2012/206336 A1, WO 2014/097181 A1, and US 2014/291480 A1, the full content of all of which is herewith included by reference.

The above-described detector, the method, the human-machine interface and the entertainment device and also the proposed uses have considerable advantages over the prior art. Thus, generally, a simple and, still, efficient detector for an accurate determining a position of at least one object in space may be provided. Therein, as an example, three-dimensional coordinates of an object or a part thereof may be determined in a fast and efficient way.

As compared to devices known in the art, the detector as proposed provides a high degree of simplicity, specifically with regard to an optical setup of the detector. Thus, in principle, a simple combination of a material for the sensor region in combination with a variation of the cross- section of an incident light beam impinging on this material in the sensor region in conjunction with an appropriate evaluation device is sufficient for reliable high precision position detection.

This high degree of simplicity, in combination with the possibility of high precision measurements, is specifically suited for machine control, such as in human-machine interfaces and, more preferably, in gaming, tracking, scanning, and a stereoscopic vision. Thus, cost- efficient entertainment devices may be provided which may be used for a large number of gaming, entertaining, tracking, scanning, and stereoscopic vision purposes.

Summarizing, in the context of the present invention, the following embodiments are regarded as particularly preferred:

Embodiment 1: A detector for an optical detection of at least one object, comprising:
at least one longitudinal optical sensor, the longitudinal optical sensor having at least two individual pin diodes arranged between at least two electrodes, wherein at least one of the pin diodes is designated as a sensor region for an incident light beam, wherein the sensor region is designated to generate at least one longitudinal sensor signal in a manner dependent on an illumination of the sensor region by the light beam, wherein the longitudinal sensor signal, given the same total power of the illumination, is dependent on a beam cross-section of the light beam in the sensor region, and
at least one evaluation device, wherein the evaluation device is designated to generate at least one item of information on a longitudinal position of the object by evaluating the longitudinal sensor signal.

Embodiment 2: The detector according to the preceding embodiment, wherein the at least two individual pin diodes are arranged in a stack-like fashion.

Embodiment 3: The detector according to any one of the preceding embodiments, wherein each of the pin diodes comprises an i-type semiconductor layer located between an n-type semiconductor layer and a p-type semiconductor layer,

Embodiment 4: The detector according to the preceding embodiment, wherein the i-type semiconductor layer exceeds the thickness of each of the n-type semiconductor layer and the p-type semiconductor layer, in particular by a factor of at least 2, preferably of at least 5, more preferred of at least 10.

Embodiment 5: The detector according to the preceding embodiment, wherein the i-type semiconductor layer of at least one of the pin diodes is designed as the sensor region.

Embodiment 6: The detector according to any one of the preceding embodiments, the i-type semiconductor layers in the at least two different pin diodes exhibit different optical properties.

Embodiment 7: The detector according to the preceding embodiment, wherein the i-type semiconductor layers in the at least the two different pin diodes exhibit a different external quantum efficiency at at least one particular wavelength.

Embodiment 8: The detector according to any one of the preceding embodiments, wherein the i-type semiconductor layers in the at least two different pin diodes exhibit different types of the FiP effect.

Embodiment 9: The detector according to any one of the preceding embodiments, wherein each of the pin diodes comprises a material selected from the group consisting of: amorphous silicon (a-Si), an alloy comprising amorphous silicon, microcrystalline silicon (μc-Si), germanium (Ge), indium antimonide (InSb), indium gallium arsenide (InGaAs), indium arsenide (InAs), gallium nitride (GaN), gallium arsenide (GaAs), aluminum gallium phosphide (AlGaP), cadmium telluride (CdTe), mercury cadmium telluride (HgCdTe), copper indium sulfide (CIS), copper indium gallium selenide (CIGS), copper zinc tin sulfide (CZTS), copper zinc tin selenide (CZTSe), copper-zinc-tin sulfur-selenium chalcogenide (CZTSSe), an organic-inorganic halide perovskite, in particular, methylammonium lead iodide (CH3NH3PbI3), and solid solutions and/or doped variants thereof.

Embodiment 10: The detector according to the preceding embodiment, wherein the material is a hydrogenated material.

Embodiment 11: The detector according to the preceding embodiment, wherein one of the at least two pin diodes comprises amorphous silicon (a-Si:H) and the other of the at least two pin diodes comprises microcrystalline silicon (μc-Si:H).

Embodiment 12: The detector according to any one of the preceding embodiments, wherein at least one of the at least two electrodes is an optically transparent electrode.

Embodiment 13: The detector according to the preceding embodiment, wherein the optically transparent electrode comprises a transparent conducting oxide (TCO), in particular indium-doped tin oxide (ITO), fluorine-doped tin oxide (FTO), aluminum-doped zinc oxide (AZO), or a perovskite TCO, preferably SrVO₃, or CaVO₃, or, alternatively, metal nanowires, in particular Ag or Cu nanowires.

Embodiment 14: The detector according to any one of the two preceding embodiments, wherein, apart from at least one of the electrodes, at least one further electrode is an optically intransparent electrode.

Embodiment 15: The detector according to the preceding embodiment, wherein the optically intransparent electrode comprises a metal electrode or a graphene electrode.

Embodiment 16: The detector according to the preceding embodiment, wherein the metal electrode is one or more of a silver (Ag) electrode, a platinum (Pt) electrode, an aluminum (Al) electrode, or a gold (Au) electrode.

Embodiment 17: The detector according to the preceding embodiment, wherein the optically intransparent electrode comprises a uniform metal layer or is a split electrode arranged as a number of partial electrodes or in form of a metallic grid.

Embodiment 18: The detector according to the preceding embodiment, wherein at least one of the pin diodes comprises an organic material.

Embodiment 19: The detector according to the preceding embodiment, wherein the organic material comprises at least one conjugated aromatic molecule, preferably a highly conjugated aromatic molecule.

Embodiment 20: The detector according to the preceding embodiment, wherein the organic material comprises at least one dye and/or at least one pigment.

Embodiment 21: The detector according to any one of the two preceding embodiments, wherein the organic material comprises a compound selected from the group consisting of:

phthalocyanines, naphthalocyanines, subphthalocyanines, perylenes, anthracenes, pyrenes, oligo- and polythiophenes, fullerenes, indigoid dyes, bis-azo pigments, squarylium dyes, thiapyrilium dyes, azulenium dyes, dithioketo-pyrrolopyrroles, quinacridones, dibromoanthanthrone, polyvinylcarbazole, derivatives and combinations thereof.

Embodiment 22: The detector according to any one of the four preceding embodiments, wherein the organic material comprises an organic electron donor material and an organic electron acceptor material.

Embodiment 23: The detector according to the preceding embodiment, wherein the electron donor material and the electron acceptor material are comprised within a layer.

Embodiment 24: The detector according to the preceding embodiment, wherein the layer comprising the electron donor material and the electron acceptor material exhibits a thickness from 100 nm to 1000 nm.

Embodiment 25: The detector according to any one of the three preceding embodiments, wherein the electron donor material comprises an organic donor polymer.

Embodiment 26: The detector according to the preceding embodiment, wherein the donor polymer comprises a conjugated system, wherein the conjugated system is one or more of cyclic, acyclic, and linear.

Embodiment 27: The detector according to the preceding embodiment, wherein the donor polymer is one of poly(3-hexylthiophene-2,5.diyl) (P3HT), poly[3-(4-n-octyl)phenylthiophene] (POPT), poly[3-10-n-octyl-3-phenothiazine-vinylenethiophene-co-2,5-thiophene] (PTZV-PT), poly[4,8-bis[(2-ethylhexyl)oxy] benzo[1,2-b:4,5-b]dithiophene-2,6-diyl][3-fluoro-2-[(2-ethylhexyl)carbonyl]thieno[3,4-b]thiophenediyl] (PTB7), poly{thiophene-2,5-diyl-alt-[5,6-bis(dodecyloxy)benzo[c][1,2,5]thiadiazole]-4,7-diyl} (PBT-T1), poly[2,6-(4,4-bis-(2-ethylhexyl)-4H-cyclopenta[2,1-b;3,4-b]dithiophene)-alt-4,7(2,1,3-benzothiadiazole)] (PCPDTBT), poly(5,7-bis(4-decanyl-2-thienyl)-thieno(3,4-b)diathiazolethiophene-2,5) (PDDTT), poly[N-9′-heptadecanyl-2,7-carbazole-alt-5,5-(4′,7′-di-2-thienyl-2′,1′,3′-benzothiadiazole)] (PCDTBT), poly[(4,4′-bis(2-ethylhexyl)dithieno[3,2-b;2′,3′-d]silole)-2,6-diyl-alt-(2,1,3-benzothiadiazole)-4,7-diyl] (PSBTBT), poly[3-phenylhydrazone thiophene] (PPHT), poly[2-methoxy-5-(2-ethylhexyl-oxy)-1,4-phenylenevinylene] (MEH-PPV), poly[2-methoxy-5-(2′-ethylhexyloxy)-1,4-phenylene-1,2-ethenylene-2,5-dimethoxy-1,4-phenylene-1,2-ethenylene] (M3EH-PPV), poly[2-methoxy-5-(3′,7′-dimethyloctyloxy)-1,4-phenylenevinylene] (MDMO-PPV), poly[9,9-di-octylfluorene-co-bis-N,N-4-butylphenyl-bis-N,N-phenyl-1,4-phenylenediamine] (PFB), or a derivative, a modification, or a mixture thereof.

Embodiment 28: The detector according to any one of the six preceding embodiments, wherein the electron acceptor material is a fullerene-based electron acceptor material.

Embodiment 29: The detector according to the preceding embodiment, wherein the fullerene-based electron acceptor material comprises at least one of [6,6]-phenyl-C61-butyric acid methyl ester (PC60BM), [6,6]-Phenyl-C71-butyric acid methyl ester (PC70BM), [6,6]-phenyl C84 butyric acid methyl ester (PC84BM), an indene-C60 bisadduct (ICBA), or a derivative, a modification, or a mixture thereof.

Embodiment 30: The detector according to any one of the two preceding embodiments, wherein the fullerene-based electron acceptor material comprises a dimer comprising one or two 060 or C₇₀ moieties.

Embodiment 31: The detector according to the preceding embodiment, wherein the fullerene-based electron acceptor material comprises a diphenylmethanofullerene (DPM) moiety comprising one or two attached oligoether (OE) chains (C70-DPM-OE or C70-DPM-OE2, respectively).

Embodiment 32: The detector according to any one of the ten preceding embodiments, wherein the electron acceptor material is tetracyanoquinodimethane (TCNQ) or a perylene derivative.

Embodiment 33: The detector according to any one of the eleven preceding embodiments, wherein the electron acceptor material comprises an acceptor polymer.

Embodiment 34: The detector according to the preceding embodiment, wherein the acceptor polymer comprises a conjugated polymer based on one or more of a cyanated poly(phenylene-vinylene), a benzothiadiazole, a perylene, a perylenediimide, or a naphthalenediimide.

Embodiment 35: The detector according to the preceding embodiment, wherein the acceptor polymer is selected from one or more of a cyano-poly[phenylenevinylene] (CN-PPV), poly[5-(2-(ethylhexyloxy)-2-methoxycyanoterephthalyliden] (MEH-CN-PPV), poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV), poly[1,4-dioctyloxyl-p-2,5-dicyanophenylenevinylene] (DOCN-PPV), poly[9,9′-di-octylfluoreneco-benzothiadiazole] (PF8BT), or a derivative, a modification, or a mixture thereof.

Embodiment 36: The detector according to any one of the fourteen preceding embodiments, wherein the electron donor material and the electron acceptor material form a mixture.

Embodiment 37: The detector according to the preceding embodiment, wherein the mixture comprises the electron donor material and the electron acceptor material in a ratio from 1:100 to 100:1, more preferred from 1:10 to 10:1, in particular of from 1:2 to 2:1.

Embodiment 38: The detector according to any one of the sixteen preceding embodiments, wherein the electron donor material and the electron acceptor material comprise an interpenetrating network of donor and acceptor domains, interfacial areas between the donor and acceptor domains, and percolation pathways connecting the domains to the electrodes.

Embodiment 39: The detector according to any one of the preceding embodiments, wherein the n-type semiconductor layer comprises cadmium sulfide (CdS), zinc sulfide (ZnS), zinc oxide (ZnO), or zinc hydroxide (ZnOH).

Embodiment 40: The detector according to any one of the preceding embodiments, wherein the sensor region of the longitudinal optical sensor is exactly one continuous sensor region, wherein the longitudinal sensor signal is a uniform sensor signal for the entire sensor region.

Embodiment 41: The detector according to any one of the preceding embodiments, wherein the sensor region of the longitudinal optical sensor is formed by a surface of the respective device, wherein the surface faces towards the object or faces away from the object.

Embodiment 42: The detector according to any one of the preceding embodiments, wherein the optical detector is adapted to generate the longitudinal sensor signal by performing at least one current-voltage measurement and/or at least one voltage-current-measurement.

Embodiment 43: The detector according to any one of the preceding embodiments, wherein the evaluation device is designed to generate the at least one item of information on the longitudinal position of the object from at least one predefined relationship between the geometry of the illumination and a relative positioning of the object with respect to the detector, preferably taking account of a known power of the illumination and optionally taking account of a modulation frequency with which the illumination is modulated.

Embodiment 44: The detector according to any one of the preceding embodiments, wherein the detector furthermore has at least one modulation device for modulating the illumination.

Embodiment 45: The detector according to any one the preceding embodiment, wherein the light beam is a modulated light beam.

Embodiment 46: The detector according to the preceding embodiment, wherein the detector is designed to detect at least two longitudinal sensor signals in the case of different modulations, in particular at least two sensor signals at respectively different modulation frequencies, wherein the evaluation device is designed to generate the at least one item of information on the longitudinal position of the object by evaluating the at least two longitudinal sensor signals.

Embodiment 47: The detector according to any one of the preceding embodiments, wherein the longitudinal optical sensor is furthermore designed in such a way that the longitudinal sensor signal, given the same total power of the illumination, is dependent on a modulation frequency of a modulation of the illumination.

Embodiment 48: The detector according to the preceding embodiment, wherein the light beam is a non-modulated continuous-wave light beam.

Embodiment 49: The detector according to any one of the preceding embodiments, furthermore comprising at least one illumination source.

Embodiment 50: The detector according to the preceding embodiment, wherein the illumination source is selected from: an illumination source, which is at least partly connected to the object and/or is at least partly identical to the object; an illumination source which is designed to at least partly illuminate the object with a primary radiation.

Embodiment 51: The detector according to the preceding embodiment, wherein the light beam is generated by a reflection of the primary radiation on the object and/or by light emission by the object itself, stimulated by the primary radiation.

Embodiment 52: The detector according to the preceding embodiment, wherein the spectral sensitivities of at least one of the pin diodes is covered by the spectral range of the illumination source.

Embodiment 53: The detector according to any one of the preceding embodiments, wherein the at least one layer of at least one of the pin diodes is directly or indirectly applied to at least one substrate.

Embodiment 54: The detector according to the preceding embodiment, wherein the substrate is an insulating substrate.

Embodiment 55: The detector according to any one of the two preceding embodiments, wherein the substrate is at least partially transparent or translucent.

Embodiment 56: The detector according to the preceding embodiment, wherein the substrate comprises glass, quartz, or a suitable organic polymer.

Embodiment 57: The detector according to any one of the preceding embodiments, wherein the evaluation device is adapted to normalize the longitudinal sensor signals and to generate the information on the longitudinal position of the object independent from an intensity of the light beam.

Embodiment 58: The detector according to the preceding embodiment, wherein the evaluation device is adapted to recognize whether the light beam widens or narrows, by comparing the longitudinal sensor signals of different longitudinal sensors.

Embodiment 59: The detector according to any one of the preceding embodiments, wherein the evaluation device is adapted to generate the at least one item of information on the longitudinal position of the object by determining a diameter of the light beam from the at least one longitudinal sensor signal.

Embodiment 60: The detector according to the preceding embodiment, wherein the evaluation device is adapted to compare the diameter of the light beam with known beam properties of the light beam in order to determine the at least one item of information on the longitudinal position of the object, preferably from a known dependency of a beam diameter of the light beam on at least one propagation coordinate in a direction of propagation of the light beam and/or from a known Gaussian profile of the light beam.

Embodiment 61: The detector according to any one of the preceding embodiments, further comprising at least one transversal optical sensor, the transversal optical sensor being adapted to determine a transversal position of the light beam traveling from the object to the detector, the transversal position being a position in at least one dimension perpendicular to an optical axis of the detector, the transversal optical sensor being adapted to generate at least one transversal sensor signal, wherein the evaluation device is further designed to generate at least one item of information on a transversal position of the object by evaluating the transversal sensor signal.

Embodiment 62: The detector according to the preceding embodiment, wherein the transversal optical sensor has a split electrode comprising at least two partial electrodes.

Embodiment 63: The detector according to the preceding embodiment, wherein electrical currents through the partial electrodes are dependent on a position of the light beam in the sensor area.

Embodiment 64: The detector according to the preceding embodiment, wherein the transversal optical sensor is adapted to generate the transversal sensor signal in accordance with the electrical currents through the partial electrodes.

Embodiment 65: The detector according to any one of the two preceding embodiments, wherein the detector, preferably the transversal optical sensor and/or the evaluation device, is adapted to derive the information on the transversal position of the object from at least one ratio of the currents through the partial electrodes.

Embodiment 66: The detector according to any one of the four preceding embodiments, wherein the at least one transversal optical sensor is a transparent optical sensor.

Embodiment 67: The detector according to any one of the five preceding embodiments, wherein the transversal optical sensor and the longitudinal optical sensor are stacked along the optical axis such that a light beam travelling along the optical axis both impinges the transversal optical sensor and the at least two longitudinal optical sensors.

Embodiment 68: The detector according to the preceding embodiment, wherein the light beam subsequently passes through the transversal optical sensor and the at least one longitudinal optical sensor or vice versa.

Embodiment 69: The detector according to the preceding embodiment, wherein the light beam passes through the transversal optical sensor before impinging on one of the longitudinal optical sensors.

Embodiment 70: The detector according to any one of the nine preceding embodiments, wherein the transversal sensor signal is selected from the group consisting of a current and a voltage or any signal derived thereof.

Embodiment 71: The detector according to any one of the preceding embodiments, wherein the detector further comprises at least one imaging device.

Embodiment 72: The detector according to the preceding claim, wherein the imaging device is located in a position furthest away from the object.

Embodiment 73: The detector according to any one of the two preceding embodiments, wherein the light beam passes through the at least one longitudinal optical sensor before illuminating the imaging device.

Embodiment 74: The detector according to any one of the three preceding embodiments, wherein the imaging device comprises a camera.

Embodiment 75: The detector according to any one of the four preceding embodiments, wherein the imaging device comprises at least one of: an inorganic camera; a monochrome camera; a multichrome camera; a full-color camera; a pixelated inorganic chip; a pixelated organic camera; a CCD chip, preferably a multi-color CCD chip or a full-color CCD chip; a CMOS chip; an IR camera; an RGB camera.

Embodiment 76: An arrangement comprising at least two detectors according to any one of the preceding embodiments.

Embodiment 77: The arrangement according to any one of the two preceding embodiments, wherein the arrangement further comprises at least one illumination source.

Embodiment 78: A human-machine interface for exchanging at least one item of information between a user and a machine, in particular for inputting control commands, wherein the human-machine interface comprises at least one detector according to any one of the preceding embodiments relating to a detector, wherein the human-machine interface is designed to generate at least one item of geometrical information of the user by means of the detector wherein the human-machine interface is designed to assign to the geometrical information at least one item of information, in particular at least one control command.

Embodiment 79: The human-machine interface according to the preceding embodiment, wherein the at least one item of geometrical information of the user is selected from the group consisting of: a position of a body of the user; a position of at least one body part of the user; an orientation of a body of the user; an orientation of at least one body part of the user.

Embodiment 80: The human-machine interface according to any one of the two preceding embodiments, wherein the human-machine interface further comprises at least one beacon device connectable to the user, wherein the human-machine interface is adapted such that the detector may generate an information on the position of the at least one beacon device.

Embodiment 81: The human-machine interface according to the preceding embodiment, wherein the beacon device comprises at least one illumination source adapted to generate at least one light beam to be transmitted to the detector.

Embodiment 82: An entertainment device for carrying out at least one entertainment function, in particular a game, wherein the entertainment device comprises at least one human-machine interface according to any one of the preceding embodiments referring to a human-machine interface, wherein the entertainment device is designed to enable at least one item of information to be input by a player by means of the human-machine interface, wherein the entertainment device is designed to vary the entertainment function in accordance with the information.

Embodiment 83: A tracking system for tracking the position of at least one movable object, the tracking system comprising at least one detector according to any one of the preceding embodiments referring to a detector, the tracking system further comprising at least one track controller, wherein the track controller is adapted to track a series of positions of the object, each comprising at least one item of information on a position of the object at a specific point in time.

Embodiment 84: The tracking system according to the preceding embodiment, wherein the tracking system further comprises at least one beacon device connectable to the object, wherein the tracking system is adapted such that the detector may generate an information on the position of the object of the at least one beacon device.

Embodiment 85: A scanning system for determining at least one position of at least one object, the scanning system comprising at least one detector according to any one of the preceding embodiments relating to a detector, the scanning system further comprising at least one illumination source adapted to emit at least one light beam configured for an illumination of at least one dot located at at least one surface of the at least one object, wherein the scanning system is designed to generate at least one item of information about the distance between the at least one dot and the scanning system by using the at least one detector.

Embodiment 86: The scanning system according to the preceding embodiment, wherein the illumination source comprises at least one artificial illumination source, in particular at least one laser source and/or at least one incandescent lamp and/or at least one semiconductor light source.

Embodiment 87: The scanning system according to any one of the two preceding embodiments, wherein the illumination source emits a plurality of individual light beams, in particular an array of light beams exhibiting a respective pitch, in particular a regular pitch.

Embodiment 88: The scanning system according to any one of the three preceding embodiments, wherein the scanning system comprises at least one housing.

Embodiment 89: The scanning system according to the preceding embodiment, wherein the at least one item of information about the distance between the at least one dot and the scanning system distance is determined between the at least one dot and a specific point on the housing of the scanning system, in particular a front edge or a back edge of the housing.

Embodiment 90: The scanning system according to any one of the two preceding embodiments, wherein the housing comprises at least one of a display, a button, a fastening unit, a leveling unit.

Embodiment 91: A stereoscopic system comprising at least one tracking system according to any one of the embodiments which refer to the tracking system and at least one scanning system according to any one of the embodiments which refer to the scanning system, wherein the tracking system and the scanning system each comprise at least one optical sensor which are placed in a collimated arrangement in such a manner that they are aligned in an orientation parallel to the optical axis of the stereoscopic system and, concurrently, exhibit an individual displacement with respect to the orientation perpendicular to the optical axis of the stereoscopic system.

Embodiment 92: The stereoscopic system according to the preceding embodiment, wherein the tracking system and the scanning system each comprise at least one longitudinal optical sensor, wherein the sensor signals of the longitudinal optical sensors are combined for determining the item of information on the longitudinal position of the object.

Embodiment 93: The stereoscopic system according to the preceding embodiment, wherein the sensor signals of the longitudinal optical sensors are distinguishable with respect to each other by applying a different modulation frequency.

Embodiment 94: The stereoscopic system according to the preceding embodiment, wherein the stereoscopic system further comprises at least one transversal optical sensor, wherein the sensor signals of the transversal optical sensor are used for determining the item of information on the transversal position of the object.

Embodiment 95: The stereoscopic system according to the preceding embodiment, wherein a stereoscopic view of the object is obtained by combining the item of information on the longitudinal position of the object and the item of information on the transversal position of the object.

Embodiment 96: A camera for imaging at least one object, the camera comprising at least one detector according to any one of the preceding embodiments referring to a detector.

Embodiment 97: A method for an optical detection of at least one object, in particular by using a detector according to any one of the preceding embodiments relating to a detector, comprising the following steps:
generating at least one longitudinal sensor signal by using at least one longitudinal optical sensor, wherein the longitudinal optical sensor has at least two individual pin diodes arranged between at least two electrodes, wherein at least one of the pin diodes is designated as a sensor region for an incident light beam, wherein the sensor region is designated to generate at least one longitudinal sensor signal in a manner dependent on an illumination of the sensor region by the light beam, wherein the longitudinal sensor signal, given the same total power of the illumination, is dependent on a beam cross- section of the light beam in the sensor region; and
generating at least one item of information on a longitudinal position of the object by evaluating the longitudinal sensor signal of the longitudinal optical sensor.

Embodiment 98: A use of a detector according to any one of the preceding embodiments relating to a detector for a purpose of, preferably simultaneously, determining a position, in particular a depth of an object.

Embodiment 99: The use of a detector according to the previous embodiment, for a purpose of use, selected from the group consisting of: a distance measurement, in particular in traffic technology; a position measurement, in particular in traffic technology; an entertainment application; a security application; a human-machine interface application; a tracking application; a scanning application; a photography application; an imaging application or camera application; a mapping application for generating maps of at least one space; a homing or tracking beacon detector for vehicles; a distance and/or position measurement of objects with a thermal signature (hotter or colder than background); a stereoscopic vision application; a machine vision application; a robotic application.

### BRIEF DESCRIPTION OF THE FIGURES

Further optional details and features of the invention are evident from the description of preferred exemplary embodiments which follows in conjunction with the dependent claims. In this context, the particular features may be implemented alone or with features in combination. The invention is not restricted to the exemplary embodiments. The exemplary embodiments are shown schematically in the figures. Identical reference numerals in the individual figures refer to identical elements or elements with identical function, or elements which correspond to one another with regard to their functions.

Specifically, in the figures:

FIG. 1 shows an exemplary embodiment of a detector according to the present invention comprising a longitudinal optical sensor, wherein the longitudinal optical sensor has two individual pin diodes arranged between at least one first electrode and at least one second electrode, wherein at least one of the pin diodes is designed as the sensor region;

FIG. 2 shows an preferred embodiment of the longitudinal optical sensor having two individual pin diodes arranged between at least one first electrode and at least one second electrode, wherein at least one of the pin diodes is designed as the sensor region;

FIG. 3 shows experimental results demonstrating the negative FiP effect by using the longitudinal optical sensor according to FIG. 2;

FIG. 4 shows an exemplary embodiment of an optical detector, a detector system, a human-machine interface, an entertainment device, a tracking system and a camera according to the present invention.

### EXEMPLARY EMBODIMENTS

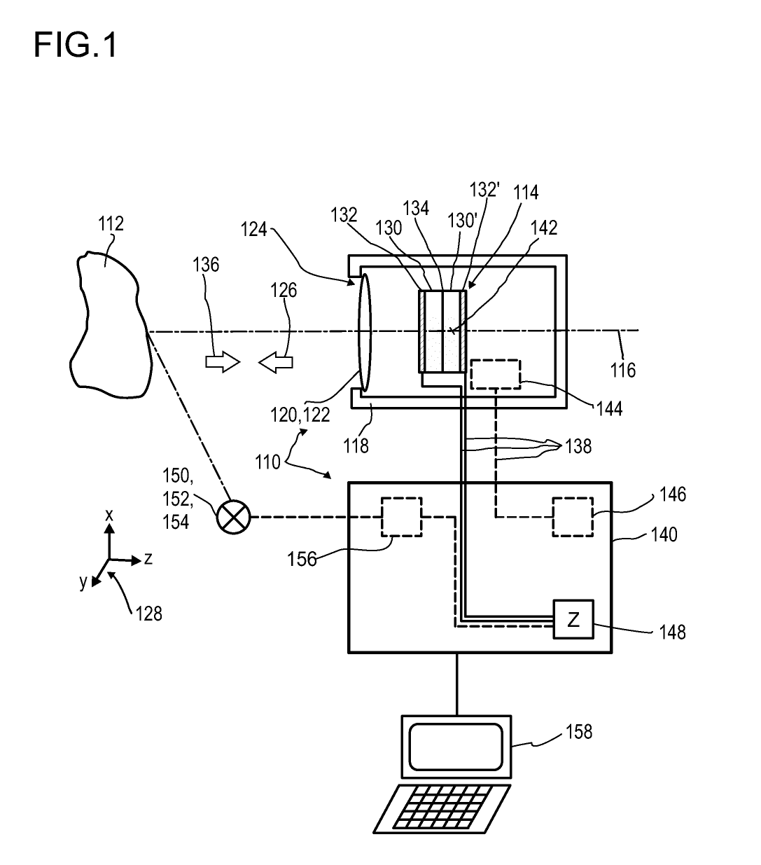

FIG. 1 illustrates, in a highly schematic fashion, an exemplary embodiment of an optical detector 110 according to the present invention, for determining a position of at least one object 112. The optical detector 110 may preferably be adapted to be used as an infrared detector, particularly for the NIR spectral range. However, other embodiments are feasible.

The optical detector 110 comprises at least one longitudinal optical sensor 114, which, in this particular embodiment, is arranged along an optical axis 116 of the detector 110. Specifically, the optical axis 116 may be an axis of symmetry and/or rotation of the setup of the optical sensors 114. The optical sensors 114 may be located inside a housing 118 of the detector 110. Further, at least one transfer device 120 may be comprised, preferably a refractive lens 122. An opening 124 in the housing 118, which may, particularly, be located concentrically with regard to the optical axis 116, preferably defines a direction of view 126 of the detector 110. A coordinate system 128 may be defined, in which a direction parallel or antiparallel to the optical axis 116 is defined as a longitudinal direction, whereas directions perpendicular to the optical axis 116 may be defined as transversal directions. In the coordinate system 128, symbolically depicted in FIG. 1, a longitudinal direction is denoted by z and transversal directions are denoted by x and y, respectively. However, other types of coordinate systems 128 are feasible.

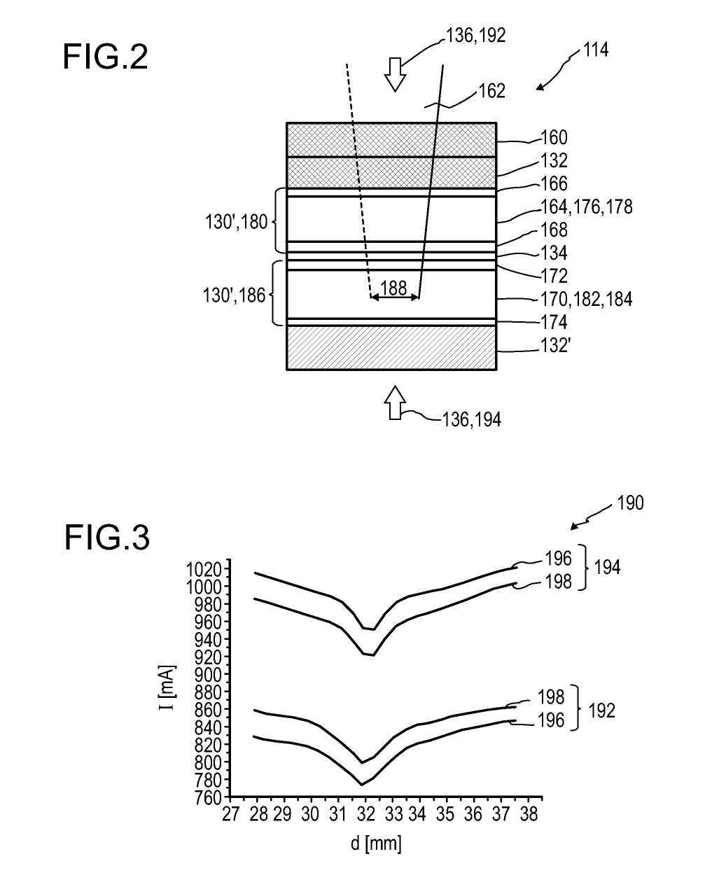

Further, the longitudinal optical sensor 114 has at least two individual pin diodes 130, 130′ being arranged, preferably in a stack-like fashion, between at least two electrodes 132, 132′. While two individual pin diodes 130, 130′ are schematically depicted in FIG. 1, the longitudinal optical sensor 114 may have more than two individual pin diodes 130, 130′, such as three, four or more individual pin diodes 130, 130′, for special purposes. Thus, the at least two individual pin diodes 130, 130′ commonly share the electrodes of the same polarity. As a result, no further electrodes may be arranged between the individual pin diodes 130, 130′. If applicable, at least one further pin diode (not depicted here) may be placed on any location between the two electrodes 130, 132′. Further, the stack may comprise additional layers, in particular, at least one insulating substrate on which one of the electrodes 130, 132′ could be placed. As will be further specified in FIG. 2, a recombination layer 134 may also be located between two adjacent individual pin diodes 130, 130′.

According to the present invention, at least one of the pin diodes 130, 130′ is designated as a sensor region for an incident light beam 136. Herein, the longitudinal optical sensor 114 is designed to generate at least one longitudinal sensor signal in a manner dependent on an illumination of a sensor region by the light beam 136. Thus, according to the FiP effect, the longitudinal sensor signal, given the same total power of the illumination, is dependent on a beam cross-section of the light beam 136 in the respective sensor region.

According to the present invention, all pin diodes 130, 130′ within the stack-like arrangement of the longitudinal optical sensor 114 might be employed as the sensor region. However, the pin diodes 130, 130′ may, preferably, exhibit different optical properties with respect to each other. As further specified in FIG. 2, the pin diodes 130, 130′ could exhibit different optical sensitivities, in particular different external quantum efficiencies, with respect to different wavelength ranges of the incident light beam 136. Further, the pin diodes 130, 130′ could exhibit different types of the FiP effect, i.e. they could produce different longitudinal sensor signals depending on the illumination of the sensor region by the incident light beam 136, whereby each of the pin diodes 130, 130′ may show the positive FiP effect, the negative FiP, or no FiP effect at all as long as one of the pin diodes 130, 130′ actually exhibits the FiP effect, irrespective whether it may be the positive FiP effect or the negative FiP effect. Alternatively or in addition, other kinds of differences between the pin diodes 130, 130′ in the longitudinal optical sensor 114 may also be feasible.

Via a longitudinal signal lead 138, the longitudinal sensor signal may be transmitted to an evaluation device 140, which will be explained in further detail below.

In a preferred embodiment, one of the pin diodes 130, 130′ may be located at a focal point 142 of the transfer device 120. Additionally or alternatively, in particular in embodiment in which the optical detector 110 may not comprise a transfer device 120, the longitudinal optical sensor 114 may be arranged in a movable fashion along the optical axis 116, such as by means of an actuator 144, which may be controllable by using an actuator control unit 146, which may be placed within the evaluation device 140. However, other kinds of setups may be feasible.

The evaluation device 140 is, generally, designed to generate at least one item of information on a position of the object 112 by evaluating the sensor signal of the transversal optical sensor 114. For this purpose, the evaluation device 140 may comprise one or more electronic devices and/or one or more software components, in order to evaluate the sensor signals, which are symbolically denoted by a longitudinal evaluation unit 148 (denoted by “z”). As will be explained below in more detail, the evaluation device 140 may be adapted to determine the at least one item of information on the longitudinal position of the object 112 by comparing more than one longitudinal sensor signals of the longitudinal optical sensor 114.

As explained above, the longitudinal sensor signal as provided by the longitudinal optical sensor 114 upon impingement by the light beam 136 depends on an electrically detectable property of a material in the sensor region. In order to determine a variation of the electrically detectable property of the material in the sensor region it may, as schematically depicted in FIG. 1, therefore be advantageous to measure a current, which may also be denominated a “photocurrent”, through the longitudinal optical sensor 114.

The light beam 136 for illumining the sensor region of the longitudinal optical sensor 114 may be generated by a light-emitting object 112. Alternatively or in addition, the light beam 136 may be generated by a separate illumination source 150, which may include an ambient light source and/or an artificial light source, such as a light-emitting diode 152, being adapted to illuminate the object 112 that the object 112 may be able to reflect at least a part of the light generated by the illumination source 150 in a manner that the light beam 136 may be configured to reach the sensor region of the longitudinal optical sensor 114, preferably by entering the housing 118 of the optical detector 110 through the opening 124 along the optical axis 116.

In a specific embodiment, the illumination source 150 may be a modulated light source 154, wherein one or more modulation properties of the illumination source 150 may be controlled by at least one optional modulation device 156. Alternatively or in addition, the modulation may be effected in a beam path between the illumination source 150 and the object 112 and/or between the object 112 and the longitudinal optical sensor 114. Further possibilities may be conceivable. In this specific embodiment, it may be advantageous taking into account one or more of the modulation properties, in particular the modulation frequency, when evaluating the sensor signal of the transversal optical sensor 114 for determining the at least one item of information on the position of the object 112.

Generally, the evaluation device 140 may be part of a data processing device 158 and/or may comprise one or more data processing devices 158. The evaluation device 140 may be fully or partially integrated into the housing 118 and/or may fully or partially be embodied as a separate device which is electrically connected in a wireless or wire-bound fashion to the longitudinal optical sensor 114. The evaluation device 140 may further comprise one or more additional components, such as one or more electronic hardware components and/or one or more software components, such as one or more measurement units and/or one or more evaluation units and/or one or more controlling units (not depicted here).

FIG. 2 shows a preferred embodiment of the longitudinal optical sensor 114. In accordance with the embodiment as shown in FIG. 1, the longitudinal optical sensor 114 comprises the individual pin diodes 130, 130′ which are arranged in the stack-like fashion between the two electrodes 132, 132′. However, arrangements with more than two individual pin diodes 130, 130′, such as three or four individual pin diodes 130, 130′, may also be feasible. As further schematically depicted in FIG. 2, the electrode 132 is located adjacently to as at least partially optically transparent substrate 160, in particular a transparent, a semi-transparent or a translucent substrate, which may, preferably, comprise a material selected from glass, quartz, or a suitable organic polymer. Consequently, the incident light beam 136 impinging the longitudinal optical sensor 114 can travel through the substrate 160 before it may reach the electrode 130.

Further, for facilitating the light beam 136 to arrive at the pin diodes 130, 130′ the electrode 130 located within the beam path 162 of the incident light beam 136, which may also be denominated as a “front electrode”, is, in this particular embodiment, selected to be at least partially optically transparent, in particular, to exhibit transparent, semi-transparent or translucent properties. For this purpose, the at least partially optically transparent electrode 130 may, preferably, comprise at least one transparent conductive oxide (TCO), in particular at least one of indium-doped tin oxide (ITO), fluorine-doped tin oxide (FTO), zinc oxide (ZnO), aluminum-doped zinc oxide (AZO), a perovskite TCO, such as SrVO3, or CaVO3, or, alternatively, metal nanowires, in particular Ag or Cu nanowires. However, other kinds of optically transparent materials which may be suited as electrode material may also be applicable for the electrode 130.

The electrode 132′ may also be accomplished in a similar manner as the electrode 132, i.e.

exhibiting at least partially optically transparent properties. However, since the electrode 132′ may be located outside the beam path 162 of the light beam 136 within the longitudinal optical sensor 114, it may, alternatively or in addition, be accomplished in an optically intransparent manner and, thus, also be denominated as a “back electrode”. Herein, the at least one optically intransparent electrode 132′ may, preferably, comprise a metal electrode, in particular one or more of a silver (Ag) electrode, a platinum (Pt) electrode, an aluminum (Al) electrode, or a gold (Au) electrode, or, alternatively, a graphene electrode. Preferably, the optically intransparent electrode 132′ may comprise a uniform metal layer. Alternatively, the optically intransparent electrode may be a split electrode being arranged as a number of partial electrodes or in form of a metallic grid.

In the preferred embodiment of FIG. 2, the two individual pin diodes 130, 130′ of the longitudinal optical sensor 114 may, preferably, exhibit a similar internal structure. Accordingly, the pin diode 130 comprises an i-type semiconductor layer 164, which is located between an n-type semiconductor layer 166 and a p-type semiconductor layer 168. Similarly, the pin diode 130′ comprises an i-type semiconductor layer 170, which is located between an n-type semiconductor layer 172 and a p-type semiconductor layer 174. As usually, while charge carriers in the n-type semiconducting layers 166, 172 are predominantly provided by electrons, the charge carriers in the p-type semiconducting layers 168, 174 are predominantly provided by holes. In contrast hereto, the i-type semiconducting layers 164, 170 may be considered as undoped intrinsic semiconductor regions. As schematically depicted in FIG. 2, the n-type semiconductor layer 166 adjoins the electrode 132 while the p-type semiconductor layer 174 adjoins the electrode 130′. However, other kinds of arrangements are possible, in particular, where both the n-type semiconductor layer 166 and the p-type semiconductor layer 168 as well as the n-type semiconductor layer 172 and the p-type semiconductor layer 174 change their locations. Further, in the preferred embodiment of FIG. 2, the i-type semiconductor layers 164, 170 may, preferably, exhibit a thickness exceeding the thickness of both the n-type semiconductor layers 166, 172 and the p-type semiconductor layers 168, 174. As a result, a depletion region which may exist within the i-type semiconductor layers 164, 170 may assume a large volume, thus, allowing a large number of electron-hole pairs to be generated by incident photons as comprised in the light beam 136.

Preferably, the pin diodes 130, 130′ of the longitudinal optical sensor 114 may comprise a kind of amorphous silicon which is, generally, known to exhibit a non-linear frequency response. As a result which will be shown in FIG. 3, the FiP effect may be observable in the longitudinal optical sensor 114 equipped with this kind of pin diodes 130, 130′. According to the present invention, the two individual pin diodes 130, 130′ as comprised within the longitudinal optical sensor 114 may exhibit different optical sensitivities, in particular different external quantum efficiencies, with respect to different wavelength ranges of the incident light beam 136. For this purpose, two different kinds of materials may be used for the two individual pin diodes 130, 130′.

Firstly, the i-type semiconducting layer 164 of the pin diode 130 may, thus, comprise undoped intrinsic amorphous silicon 176 (a-Si), preferably in a form of hydrogenated amorphous silicon 178 (a-Si:H), wherein, in the a-Si:H, the amorphous silicon is passivated by using hydrogen in a manner that a number of dangling bonds within the untreated amorphous silicon may be reduced by several orders of magnitude. Thus, the a-Si:H may comprise a low amount of defects, which makes it particular suitable for optical devices, such as for the longitudinal optical sensor 114 according to the present invention. As already mentioned above, the external quantum efficiency of the i-type semiconducting layer 164 of the pin diode 130 which comprises the undoped a-Si, preferably the undoped a-Si:H, exhibits a large value within the spectral range from 380 nm to 700 nm, i.e. within most parts of the visual spectrum. Thus, as long as the incident light beam 136 may have a wavelength within this spectral range from 380 nm to 700 nm, the pin diode 130, in particular the i-type semiconducting layer 164 of the pin diode 130 may be designated as the sensor region for an incident light beam 136.

However, the present invention allows more, i.e. that the i-type semiconducting layer 164 of the pin diode 130 comprising the undoped a-Si, preferably the undoped a-Si:H, may still be used for incident lights beams which may exhibit a wavelength outside the spectral range from 380 nm to 700 nm. In this particularly preferred event, the pin diode 130 may, however, not be used as the sensor region in the manner as described above but it may, nevertheless, work as a trap-holding semiconductor 180. Consequently, the pin diode 130 may, thus, allow receiving positive charge carriers that may be generated in the pin diode 130′ by the incident light beam 136, wherein the pin diode 130′ may exhibit sufficient external quantum efficiency within the desired wavelength range, in particular, in at least a partition of the NIR spectral range, preferably, from 760 nm to 1400 nm.

Thus, the pin diode 130′ may exhibit the similar arrangement as the pin diode 130, wherein the pin diode 130′ may comprise one of: a microcrystalline silicon 182 (μc-Si), preferably a hydrogenated microcrystalline silicon 184 (μc-Si:H). Again, in the μc-Si:H, the microcrystalline silicon is passivated by using hydrogen in a manner that a number of dangling bonds within the untreated microcrystalline silicon may be reduced by several orders of magnitude. Thus, also the μc-Si:H may comprise a low amount of defects, which makes it particular suitable for optical devices, such as the for longitudinal optical sensor 114 according to the present invention. Alternatively, an amorphous alloy of germanium and silicon (a-GeSi), preferably a hydrogenated amorphous germanium silicon alloy (a-GeSi:H), may be used.

Since the pin diode 130′ comprising pc-Si:H has a non-negligible quantum efficiency within the NIR region over a wavelength range approximately from 500 nm to 1100 nm, the pin diode 130′ may, thus, be designated as the sensor region 186 for an incident light beam 136 having a wavelength in the range approximately from 500 nm to 1100 nm. According to the present invention, the sensor region 186 in the pin diode 130′ is illuminated by the incident light beam 136. Given the same total power of the illumination, a longitudinal sensor signal as generated in the longitudinal optical sensor 114, therefore, depends on a beam cross-section 188 of the light beam 136 in the sensor region 186, also be denominated as a “spot size”. Herein, the longitudinal sensor signal may, preferably, be determined by applying an electrical signal, such as a voltage signal and/or a current signal. As a result, the longitudinal optical sensor 114, thus, principally allows determining the beam cross-section of the light beam 136 in the sensor region 186 from a recording of the longitudinal sensor signal.

As already mentioned above, the recombination layer 134 may be located between two adjacent individual pin diodes 130, 130′, in particular between the p-type semiconductor layer 168 of the pin diode 130 and the n-type semiconductor layer 172 of the pin diode 130′. Herein, the recombination layer 134 may, particularly, be introduced in order to provide a sufficient Ohmic contact between the two adjacent individual pin diodes 130, 130′ in a manner that as many holes as possible from one junction may be joined with as many electrons from the other junction. Thus, the recombination layer may, preferably, be transparent and exhibit a high resistivity in transversal direction in order to accomplish avoiding a distribution of charge charriers over the whole detector plane.

The embodiment according to FIG. 2 exhibits a comparatively simple and cost-efficient setup of the longitudinal optical sensor 114, in particular, for use within the NIR spectral range. However, other embodiments not depicted here may also be appropriate as the setup for the longitudinal optical sensor 114 according to the present invention. By way of example, the pin diode 130′ may, alternatively, comprise an amorphous alloy of silicon and carbon (a-SiC) or, preferably, a hydrogenated amorphous silicon carbon alloy (a-SiC:H), which exhibit a high external quantum efficiency within the UV wavelength range, preferably, over the complete UVA and UVB wavelength range from 280 nm to 400 nm. Moreover, other kinds of combinations applicable to the pin diodes 130, 130′ may also be feasible.

Further, the individual pin diodes 130, 130′ could exhibit different types of the FiP effect, i.e. different longitudinal sensor signals that may depend on the illumination of the sensor region 186 by the incident light beam 136. Herein, any or both of the pin diodes 130, 130′ can show the positive FiP effect, the negative FiP, or no FiP effect at all as long as at least one of the pin diodes 130, 130′ actually exhibits the FiP effect, irrespective whether it may be the positive FiP effect or the negative FiP effect. Alternatively or in addition, other kinds of differences between the pin diodes 130, 130′ as comprised in the longitudinal optical sensor 114 may also be feasible.

In FIG. 3, the occurrence of the above-mentioned negative FiP effect in the exemplary embodiments of FIGS. 1 and 2 is experimentally demonstrated. Herein, FIG. 3 shows so- called “FiP curves” 190 as the experimental results in the setup of the longitudinal optical sensor 114 according to FIG. 2, wherein the pin diode 130 comprises a-Si:H as the trap-holding semiconductor 180 and the pin diode 130′ comprises pc-Si:H which constitutes the sensor region 186. Herein, the setup of the optical detector 110 comprised a light-emitting diode (LED) 152 which was placed 80 cm in front of the refractive lens 122 and which was employed as the illumination source 150 for generating the light beam 136 with an optical wavelength of 850 nm which was adapted for illuminating the object 112 in the NIR spectral range.

During the experiment, the longitudinal optical sensor 114 was moved along the z-axis of the optical detector 110 by using the actuator 144 and the resulting photocurrent I in pA was measured. Herein, the focal point 142 of the refractive lens 122 was located at a distanced of about 32 mm from the refractive lens 122, whereby the refractive lens 122 and the light-emitting diode 152 serving as the illumination source 150 were placed at larger z-values. Moving the sensor along the z-axis of the optical detector 110 during the experiment resulted in a variation of the beam cross-section (spot size) 188 of the incident light beam 136 at the position of the sensor region 186, thus yielding a z-dependent photocurrent signal which can here viewed as the longitudinal sensor signal.

As illustrated in FIG. 3, the photocurrent of the longitudinal optical sensor 114 has been measured under four different kinds of experimental conditions. Herein, the sensor region 186 was either illuminated from a frontside 192 or from a backside 194 of the setup. Herein, the term “frontside” 192 indicates that the sensor region 186 was illuminated by the beam path 162 in the manner as schematically illustrated in FIG. 2. As a result, the incident light beam 136 first traveled through the pin diode 130 acting as the trap-holding semiconductor 180 before it reached the sensor region 186 in the pin diode 130′. In contrast hereto, the term “backside” 192 indicates that the sensor region 186 was illuminated by a different beam path (not depicted here) by which the incident light beam 136 first traveled through the sensor region 186 in the pin diode 130′ before it reached the trap-holding semiconductor 180 within the pin diode 130.

Herein, in the case in which the sensor region 186 is illuminated from the backside 194 the electrode 132′, which may also be denominated as the “back electrode”, is accomplished as an at least partially transparent electrode as described above in more detail whereas in the case in which the sensor region 186 is illuminated from the frontside 192 the optical properties of the electrode 132′ may be at least partially transparent or intransparent. Consequently, it may, additionally, be distinguished between a first setup in which the respective FiP curve 190 is recorded by using a backlight 196 as generated by the reflecting intransparent electrode 132′ or without backlight 198 in case the electrode 132′ exhibits at least partially transparent optical properties. In a similar manner, in the case of illuminating the sensor region 186 from the backside 194, the electrode 132, which may also be denominated as the “front electrode”, may also exhibit at least partially transparent or intransparent optical properties, thus, allowing a recording of the FiP curves 190 by using the backlight 196 or without backlight 198.

As illustrated in FIG. 3, the FiP curves 190 comprising the observable photocurrent which may be attributed as the longitudinal sensor signal varied with the varying distance of the longitudinal optical sensor 114 from the object 112 and comprises a distinct minimum in an event in which the object 112 was focused on the longitudinal optical sensor 114. Thus, the optical detector 110 according to the present invention may be arranged in a manner that it clearly exhibits the above-described negative FiP effect, i.e. the observation of a minimum of the longitudinal sensor signal under a condition in which the sensor region 130 is impinged by the light beam 136 with the smallest possible cross-section, which occurs in this setup when the sensor region 186 is located at the focal point 142 as effected by the refractive lens 122, i.e. here at a distance of approximately 32 mm from the refractive lens 122.

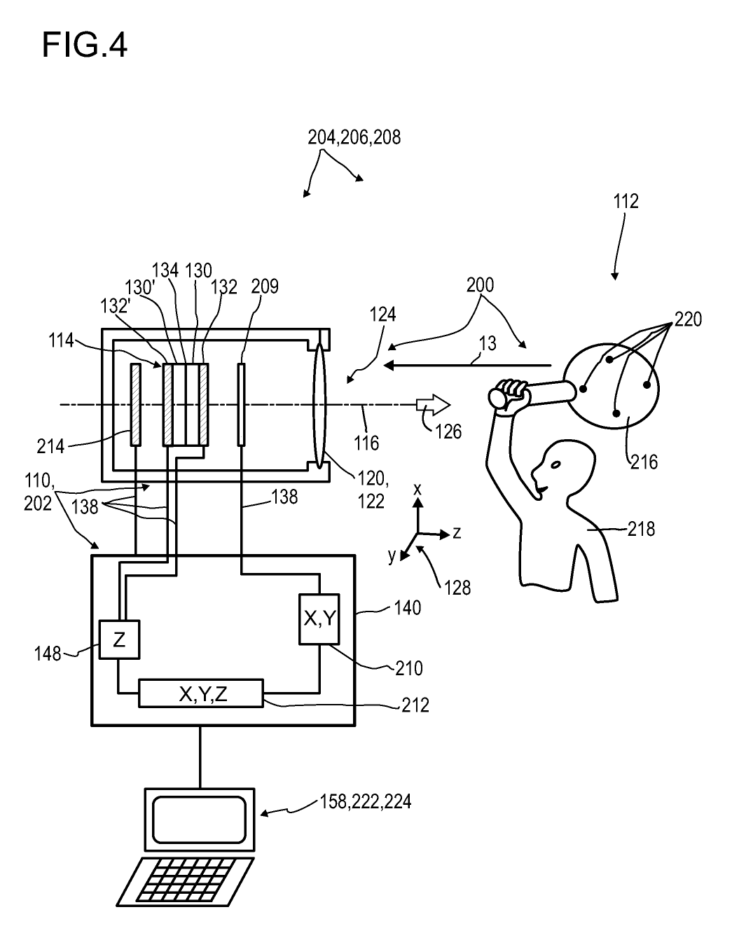

As an example, FIG. 4 shows an exemplary embodiment of a detector system 200, comprising at least one optical detector 110, such as the optical detector 110 as disclosed in one or more of the embodiments shown in FIG. 1 or 2. Herein, the optical detector 110 may be employed as a camera 202, specifically for 3D imaging, which may be made for acquiring images and/or image sequences, such as digital video clips. Further, FIG. 4 shows an exemplary embodiment of a human-machine interface 204, which comprises the at least one detector 110 and/or the at least one detector system 200, and, further, an exemplary embodiment of an entertainment device 206 comprising the human-machine interface 204. FIG. 4 further shows an embodiment of a tracking system 208 adapted for tracking a position of at least one object 112, which comprises the detector 110 and/or the detector system 200.

With regard to the optical detector 110 and to the detector system 200, reference may be made to the full disclosure of this application. Basically, all potential embodiments of the detector 110 may also be embodied in the embodiment shown in FIG. 4. The evaluation device 140 may be connected to each of the at least two longitudinal optical sensors 114, in particular, by the signal leads 138. By way of example, the signal leads 138 may be provided and/or one or more interfaces, which may be wireless interfaces and/or wire-bound interfaces. Further, the signal leads 138 may comprise one or more drivers and/or one or more measurement devices for generating sensor signals and/or for modifying sensor signals.

As described above, the optical detector 110 may comprise a single longitudinal optical sensor 114 or, as e.g. disclosed in WO 2014/097181 A1, a stack of longitudinal optical sensors 114, particularly in combination with one or more transversal optical sensors 209. As an example, one or more at least partially transparent transversal optical sensors 209 may be located on a side of the stack of longitudinal optical sensors 114 facing towards the object 112. Alternatively or additionally, one or more transversal optical sensors 209 may be located on a side of the stack of longitudinal optical sensors 114 facing away from the object 112. In this case the last of the transversal optical sensors 209 may be intransparent. Thus, in a case in which determining the x- and/or y-coordinate of the object in addition to the z-coordinate may be desired, it may be advantageous to employ, in addition to the at one longitudinal optical sensor 114 at least one transversal optical sensor 209 which may provide at least one transversal sensor signal. For potential embodiments of the transversal optical sensor, reference may be made to WO 2014/097181 A1. As described therein, a use of two or, preferably, three longitudinal optical sensors 114 may support the evaluation of the longitudinal sensor signals without any remaining ambiguity. However, embodiments which may only comprise a single longitudinal optical 114 sensor but no transversal optical sensor 209 may still be possible, such as in a case wherein only determining the depth, i.e. the z-coordinate, of the object may be desired. The at least one optional transversal optical sensor 209 may further be connected to the evaluation device 140, in particular, by the signal leads 138.

Further, the at least one transfer device 120 may be provided, in particular as the refractive lens 122 or convex mirror. The optical detector 110 may further comprise the at least one housing 118 which, as an example, may encase one or more of components 114, 209.

Further, the evaluation device 140 may fully or partially be integrated into the optical sensors 114, 209 and/or into other components of the optical detector 110. The evaluation device 140 may also be enclosed into housing 118 and/or into a separate housing. The evaluation device 140 may comprise one or more electronic devices and/or one or more software components, in order to evaluate the sensor signals, which are symbolically denoted by the longitudinal evaluation unit 148 (denoted by “z”) and a transversal evaluation unit 210 (denoted by “xy”) and. By combining results derived by these evolution units 154, 156, a position information 212, preferably a three-dimensional position information, may be generated (denoted by “x, y, z”).

Further, the optical detector 110 and/or to the detector system 200 may comprise an imaging device 214 which may be configured in various ways. Thus, as depicted in FIG. 4, the imaging device 214 can for example be part of the detector 110 within the detector housing 118. Herein, the imaging device signal may be transmitted by one or more imaging device signal leads 138 to the evaluation device 140 of the detector 110. Alternatively, the imaging device 214 may be separately located outside the detector housing 118. The imaging device 214 may be fully or partially transparent or intransparent. The imaging device 214 may be or may comprise an organic imaging device or an inorganic imaging device. Preferably, the imaging device 214 may comprise at least one matrix of pixels, wherein the matrix of pixels may particularly be selected from the group consisting of: an inorganic semiconductor sensor device such as a CCD chip and/or a CMOS chip; an organic semiconductor sensor device.

In the exemplary embodiment as shown in FIG. 4, the object 112 to be detected, as an example, may be designed as an article of sports equipment and/or may form a control element 216, the position and/or orientation of which may be manipulated by a user 218. Thus, generally, in the embodiment shown in FIG. 4 or in any other embodiment of the detector system 200, the human-machine interface 204, the entertainment device 206 or the tracking system 208, the object 112 itself may be part of the named devices and, specifically, may comprise the at least one control element 216, specifically, wherein the at least one control element 216 has one or more beacon devices 220, wherein a position and/or orientation of the control element 216 preferably may be manipulated by user 218. As an example, the object 112 may be or may comprise one or more of a bat, a racket, a club or any other article of sports equipment and/or fake sports equipment. Other types of objects 112 are possible. Further, the user 218 may be considered as the object 112, the position of which shall be detected. As an example, the user 218 may carry one or more of the beacon devices 220 attached directly or indirectly to his or her body.

The optical detector 110 may be adapted to determine at least one item on a longitudinal position of one or more of the beacon devices 220 and, optionally, at least one item of information regarding a transversal position thereof, and/or at least one other item of information regarding the longitudinal position of the object 112 and, optionally, at least one item of information regarding a transversal position of the object 112. Particularly, the optical detector 110 may be adapted for identifying colors and/or for imaging the object 112, such as different colors of the object 112, more particularly, the color of the beacon devices 220 which might comprise different colors. The opening 124 in the housing 118, which, preferably, may be located concentrically with regard to the optical axis 116 of the detector 110, may preferably define a direction of a view 126 of the optical detector 110.

The optical detector 110 may be adapted for determining the position of the at least one object 112. Additionally, the optical detector 110, specifically an embodiment including the camera 202, may be adapted for acquiring at least one image of the object 112, preferably a 3D-image. As outlined above, the determination of a position of the object 112 and/or a part thereof by using the optical detector 110 and/or the detector system 200 may be used for providing a human-machine interface 204, in order to provide at least one item of information to a machine 222. In the embodiments schematically depicted in FIG. 4, the machine 222 may be or may comprise at least one computer and/or a computer system comprising the data processing device 158. Other embodiments are feasible. The evaluation device 140 may be a computer and/or may comprise a computer and/or may fully or partially be embodied as a separate device and/or may fully or partially be integrated into the machine 222, particularly the computer. The same holds true for a track controller 224 of the tracking system 208, which may fully or partially form a part of the evaluation device 140 and/or the machine 222.

Similarly, as outlined above, the human-machine interface 204 may form part of the entertainment device 206. Thus, by means of the user 218 functioning as the object 112 and/or by means of the user 218 handling the object 112 and/or the control element 216 functioning as the object 112, the user 218 may input at least one item of information, such as at least one control command, into the machine 222, particularly the computer, thereby varying the entertainment function, such as controlling the course of a computer game.

### LIST OF REFERENCE NUMBERS

110 detector

112 object

114 longitudinal optical sensor

116 optical axis

118 housing

120 transfer device

122 refractive lens

124 opening

126 direction of view

128 coordinate system

130, 130′ pin diode

132, 132′ electrode

134 recombination layer

136 light beam

138 signal leads

140 evaluation device

142 focal point

144 actuator

146 actuator control unit

148 longitudinal evaluation unit

150 illumination source

152 light-emitting diode

154 modulated illumination source

156 modulation device

158 data processing device

160 substrate

162 beam path

164 i-type semiconductor layer

166 n-type semiconductor layer

168 p-type semiconductor layer

170 i-type semiconductor layer

172 n-type semiconductor layer

174 p-type semiconductor layer

176 amorphous silicon (a-Si)

178 hydrogenated amorphous silicon (a-Si:H)

180 trap-holding semiconductor

182 microcrystalline silicon 178 (μc-Si)

184 hydrogenated microcrystalline silicon 178 (μc-Si:H)

186 sensor region

188 beam cross-section (spot size)

190 FiP curve

192 frontside

194 backside

196 with backlight

198 without backlight

200 detector system

202 camera

204 human-machine interface

206 entertainment device

208 tracking system

209 transversal optical sensor

210 transversal evaluation unit

212 position information

214 imaging device

216 control element

218 user

220 beacon device

222 machine

224 track controller

1. A detector, suitable for an optical detection of at least one object and comprising:
at least one longitudinal optical sensor, the at least one longitudinal optical sensor having at least two individual pin diodes arranged between at least two electrodes, wherein at least one of the at least two individual pin diodes is designated as a sensor region for an incident light beam, wherein the sensor region is designed to generate at least one longitudinal sensor signal in a manner dependent on an illumination of the sensor region by the incident light beam, wherein the at least one longitudinal sensor signal, given the same total power of the illumination, is dependent on a beam cross-section of the incident light beam in the sensor region, and
at least one evaluation device, wherein the at least one evaluation device is designed to generate at least one item of information on a longitudinal position of the at least one object by evaluating the at least one longitudinal sensor signal.

2. The detector of claim 1, wherein each of the at least two individual pin diodes comprises an i-type semiconductor layer located between an n-type semiconductor layer and a p-type semiconductor layer, wherein the i-type semiconductor layer of at least one of the at least two individual pin diodes is designated as the sensor region.

3. The detector of claim 2, wherein at least two of the i-type semiconductor layers have different optical properties.

4. The detector of claim 1, wherein each of the at least two individual pin diodes comprises a material selected from the group consisting of: an amorphous silicon (a-Si), an alloy comprising amorphous silicon, a microcrystalline silicon (μc-Si), germanium (Ge), indium antimonide (InSb), indium gallium arsenide (InGaAs), indium arsenide (InAs), gallium nitride (GaN), gallium arsenide (GaAs), aluminum gallium phosphide (AlGaP), cadmium telluride (CdTe), mercury cadmium telluride (HgCdTe), copper indium sulfide (CIS), copper indium gallium selenide (CIGS), copper zinc tin sulfide (CZTS), copper zinc tin selenide (CZTSe), copper-zinc-tin sulfur-selenium chalcogenide (CZTSSe), an organic-inorganic halide perovskite, methylammonium lead iodide (CH3NH3PbI3), a solid solution thereof, and/or and a doped variant thereof.

5. The detector of claim 1, wherein at least one of the at least two individual pin diodes comprises an organic material, wherein the organic material comprises at least one selected from the group consisting of: a dye, a pigment. and a mixture comprising an electron donor material and an electron acceptor material.

6. The detector of claim 5, wherein the organic material comprises a compound selected from the group consisting of: a phthalocvanine, a naphthalocyanine, a subphthalocyanine, a perylene, an anthracene, a pyrene, art oligothiophene, a polythiophene, a fullerene, an indigoid dye, a bis-azo pigment, a squarvlium dye, a thiapyrilium dye, an azulenium dye, a dithioketo-pyrrolopyrrole, a quinacridone, a dibromoanthanthrone, a polyvinylcarbazole, a derivative thereof, and a combination thereof.

7. The detector of claim 6, wherein the electron donor material comprises one of: a poly(3-hexylthiophene-2,5.diyl) (P3HT), a poly[3-(4-noctyl) phenylthiophene] (POPT), a poly[3-10-n-octyl-3-phenothiazine-vinylenethiophene-co-2,5-thiophene] (PTZV-PT), a poly[4,8-bis[(2-ethylhexyl)oxy]benzo[1,2-b:4,5-b′]dithiophene-2,6-diyl][3-fluoro-2-[(2-ethylhexyl)carbonyl] thieno[3,4-b]thiophenediyl] (PTB7), a poly{thiophene-2,5-diyl-alt-[5,6-bis(dodecyloxy) benzo[c][1,2,5]thiadiazole]-4,7-diyl} (PBT-T1), a poly[2,6-(4,4-bis-(2-ethylhexyl)-4H-cyclopenta[2,1-b;3,4-b′]dithiophene)-alt-4,7(2,1,3-benzothiadiazole)] (PCPDTBT), a poly(5,7-bis(4-decanyl-2-thienyl)-thieno(3,4-b)diathiazolethiophene-2,5) (PDDTT), a poly[N-9′-heptadecanyl-2,7-carbazole-alt-5,5-(4′,7′-di-2-thienyl-2′,1′,3′-benzothiadiazole)] (PCDTBT), a poly[(4,4′-bis(2-ethylhexyl)dithieno[3,2-b;2′,3′-d]silole)-2,6-diyl-alt-(2,1,3-benzothiadazole)-4,7-diyl] (PSBTBT), a poly[3-phenylhydrazonethiophene] (PPHT), a poly[2-methoxy-5-(2-ethylhexyloxy)-1,4-phenylenevinylene] (MEH-PPV), a poly[2-methoxy-5-(2′-ethylhexyloxy)-1,4-phenylene-1,2-ethenylene-2,5-dimethoxy-1,4-phenylene-1,2-ethenylene] (M3EH-PPV), a poly[2-methoxy-5-(3′,7′-dimethyloctyloxy)-1,4-phenylenevinylene] (MDMO-PPV), a poly[9,9-di-octylfluorene-co-bis-N,N-4-butylphenyl-bis-N,N-phenyl-1,4-phenylenediamine] (PFB), or a derivative, a modification, or a mixture thereof, and
wherein the electron acceptor material comprises selected from one of: [6,6]-phenyl-C61-butyric acid methyl ester (PC60BM), [6,6]-Phenyl-C71-butyric acid methyl ester (PC70BM), [6,6]-phenyl C84 butyric acid methyl ester (PC84BM), an indene-C60 bis adduct (ICBA), a diphenylmethanofullerene (DPM) moiety comprising one or two attached oligoether (OE) chains (C70-DPM-OE or C70-DPM-OE2, respectively), a cyano-poly[phenylenevinylene] (CN-PPV), a poly[5-(2-(ethylhexyloxy)-2-methoxycyanoterephthalyliden] (MEH-CN-PPV), a poly[oxa-1,4-phenylene-1,2-(1-cyano)-ethylene-2,5-dioctyloxy-1,4-phenylene-1,2-(2-cyano)-ethylene-1,4-phenylene] (CN-ether-PPV), a poly[1,4-dioctyloxyl-p-2,5-dicyanophenylenevinylene] (DOCN-PPV), a poly[9,9′- dioctylfluoreneco-benzothiadiazole] (PF8BT), or a derivative, a modification, or a mixture thereof.

8. The detector of claim 1, further comprising:
at least one transversal optical sensor, the at least one transversal optical sensor being adapted to determine a transversal position of the incident light beam traveling from the at least one object to the detector, the transversal position being a position in at least one dimension perpendicular to an optical axis of the detector, the at least one transversal optical sensor being adapted to generate at least one transversal sensor signal,
wherein the at least one evaluation device is further designed to generate at least one item of information on a transversal position of the at least one object by evaluating the at least one transversal sensor signal.

9. A camera, wherein the camera is suitable for imaging at least one object and comprises at least one detector according to claim 1.

10. A human-machine interface, wherein the human-machine interface is suitable for exchanging at least one item of information between a user and a machine,
wherein the human-machine interface comprises at least one detector of claim 1,
wherein the human-machine interface is designed to generate at least one item of geometrical information of the user with the detector, and
wherein the human-machine interface is designed to assign at least one item of information to the at least one item of geometrical information.

11. An entertainment device, wherein the entertainment device is suitable for carrying out at least one entertainment function,
wherein the entertainment device comprises at least one human-machine interface of claim 10,
wherein the entertainment device is designed to enable at least one item of information to be input by a player with the human-machine interface, and
wherein the entertainment device is designed to vary the entertainment function in accordance with the at least one item of information.

12. A tracking system, wherein the tracking system is suitable for tracking the position of at least one movable object and comprises:
at least one detector of claim 1, and
at least one track controller,
wherein the at least one track controller is adapted to track a series of positions of the at least one movable object, each position comprising at least one item of information on at least a longitudinal position of the at least one movable object at a specific point in time.

13. A scanning system, wherein the scanning system is suitable for determining at least one position of at least one object and comprises:
at least one detector of claim 1, and
at least one illumination source adapted to emit at least one light beam configured for an illumination of at least one dot located at at least one surface of the at least one object,
wherein the scanning system is designed to generate at least one item of information about a distance between the at least one dot and the scanning system by using the at least one detector.

14. A stereoscopic system comprising at least one tracking system and at least one scanning system,
wherein the tracking system is suitable for tracking the position of at least one movable object and comprises:
at least one detector of claim 1, and
at least one track controller,
wherein the at least one track controller is adapted to track a series of positions of the at least one movable object, each position comprising at least one item of information on at least a longitudinal position of the at least one movable object at a specific point in time;
wherein the scanning system is suitable for detertnining at least one position of at least one object and comprises:
at least one detector of claim 1, and
at least one illumination source adapted to emit at least one light beam configured for an illumination of at least one dot located at at least one surface of the at least one object,
wherein the scanning system is designed to generate at least one item of information about a distance between the at least one dot and the scanning system by using the at least one detector: and
wherein the tracking system and the scanning system each comprise at least one longitudinal optical sensor which are located in a collimated arrangement in a manner such that they are aligned in an orientation parallel to an optical axis of the stereoscopic system and exhibit an individual displacement in an orientation perpendicular to the optical axis of the stereoscopic system.

15. A method for optically detecting at least one object, the method comprising:
generating at least one longitudinal sensor signal by using at least one longitudinal optical sensor, wherein the at least one longitudinal optical sensor has at least two individual pin diodes arranged between at least two electrodes, wherein at least one of the at least two individual pin diodes is designated as a sensor region for an incident light beam, wherein the sensor region is designed to generate at least one longitudinal sensor signal in a manner dependent on an illumination of the sensor region by the incident light beam, wherein the at least one longitudinal sensor signal, given the same total power of the illumination, is dependent on a beam cross-section of the incident light beam in the sensor region; and
generating at least one item of information on a longitudinal position of the at least one object by evaluating the at least one longitudinal sensor signal of the at least one longitudinal optical sensor.

16. (canceled)
